(19) United States
(12) Patent Application Publication
(10) Pub. No.: US 2024/0128346 A1
(43) Pub. Date: Apr. 18, 2024

(54) GATE-ALL-AROUND TRANSISTORS WITH DUAL PFET AND NFET CHANNELS

(71) Applicant: International Business Machines Corporation, Armonk, NY (US)

(72) Inventors: Julien Frougier, Albany, NY (US); Andrew M. Greene, Slingerlands, NY (US); Shogo Mochizuki, Mechanicville, NY (US); Ruilong Xie, Niskayuna, NY (US); Liqiao Qin, Albany, NY (US); Gen Tsutsui, Glenmont, NY (US); Nicolas Jean Loubet, GUILDERLAND, NY (US); Min Gyu Sung, Latham, NY (US); Chanro Park, Clifton Park, NY (US); Kangguo Cheng, Schenectady, NY (US); Heng Wu, Santa Clara, CA (US)

(21) Appl. No.: 17/964,529

(22) Filed: Oct. 12, 2022

(51) Int. Cl. H01L 29/423; H01L 29/06; H01L 29/775; H01L 29/786

(52) U.S. Cl. CPC H01L 29/42392; H01L 29/0649; H01L 29/0673; H01L 29/775; H01L 29/78696

(57) ABSTRACT

A semiconductor structure is provided that includes a pFET located in a pFET device region, the pFET includes a first functional gate structure and a plurality of pFET semiconductor channel material nanosheets, and an nFET located in the nFET device region, the nFET includes a second functional gate structure and a plurality of pFET semiconductor channel material nanosheets. The pFET semiconductor channel material nanosheets can be staggered relative to, or vertically aligned in a horizontal direction with, the nFET semiconductor channel material nanosheets. When staggered, a bottom dielectric isolation structure can be located in both the device regions, and the second functional gate structures has a bottommost surface that extends beneath a topmost surface of the bottom dielectric isolation structure. When horizontally aligned, a vertical dielectric pillar is located between the two device regions.

### BACKGROUND

The present application relates to semiconductor technology, and more particularly to semiconductor structures including dual pFET and nFET semiconductor channel materials for gate-all-around (i.e., nanosheet) devices.

A metal oxide semiconductor field effect transistor (MOSFET) is a transistor used for switching electronic signals. The MOSFET has a source region, a drain region, and a metal gate electrode. The metal gate electrode is electrically insulated from the main semiconductor n-channel or p-channel by a thin layer of insulating material, for example, silicon dioxide or high dielectric constant (high-k) dielectrics, which makes the input resistance of the MOSFET relatively high. The gate voltage controls whether the path from drain to source is an open circuit (“off”) or a resistive path (“on”).

N-type field effect transistors (nFETs) and p-type field effect transistors (pFETs) are two types of complementary MOSFETs. The nFET uses electrons as the current carriers and with n-doped source and drain junctions. The pFET uses holes as the current carriers and with p-doped source and drain junctions. In contemporary semiconductor device fabrication processes, a large number of nFETs and pFETs are fabricated on a single wafer.

As semiconductor devices scale to smaller dimensions, gate-all-around devices such as nanosheet devices provide advantages. For example, gate-all-around devices provide area efficiency. Gate-all-around devices further provide, for example, increased drive current within a given layout area.

### SUMMARY

A semiconductor structure is provided that includes a pFET located in a pFET device region, the pFET includes a first functional gate structure and a plurality of pFET semiconductor channel material nanosheets, and an nFET located in the nFET device region, the nFET includes a second functional gate structure and a plurality of pFET semiconductor channel material nanosheets. The pFET semiconductor channel material nanosheets can be staggered relative to, or vertically aligned in a horizontal direction with, the nFET semiconductor channel material nanosheets. When staggered, a bottom dielectric isolation structure can be located in both the device regions, and the second functional gate structure has a bottommost surface that extends beneath a topmost surface of the bottom dielectric isolation structure. When horizontally aligned, a vertical dielectric pillar is located between the two device regions.

In one aspect of the present application, a semiconductor substrate is provided. In one embodiment of the present application, the semiconductor structure includes a semiconductor substrate having a pFET device region and an nFET device region. A pFET is located in the pFET device region, wherein the pFET includes a first functional gate structure wrapped around a plurality of pFET semiconductor channel material nanosheets. An nFET is located in the nFET device region, wherein the nFET includes a second functional gate structure wrapped around a plurality of nFET semiconductor channel material nanosheets. In accordance with this embodiment of the present application, each pFET semiconductor channel material nanosheet of the plurality of pFET semiconductor channel material nanosheets is vertically offset from each nFET semiconductor channel material nanosheet of the plurality of nFET semiconductor channel material nanosheets. The structure of this embodiment further includes a bottom dielectric isolation structure located in both the pFET device region and the nFET device region, wherein the bottom dielectric isolation structure is located between the first functional gate structure and the semiconductor substrate and between the second functional gate structure and the semiconductor substrate. In accordance with this embodiment of the present application, the second functional gate structure has a bottommost surface that extends beneath a topmost surface of the bottom dielectric isolation structure. The bottom dielectric isolation structure can be a single layered structure or a bilayered structure.

In another embodiment of the present application, the semiconductor structure includes a semiconductor substrate having a pFET device region and an nFET device region. A pFET is located in the pFET device region, wherein the pFET includes a first functional gate structure wrapped around a plurality of pFET semiconductor channel material nanosheets. An nFET is located in the nFET device region, wherein the nFET includes a second functional gate structure wrapped around a plurality of nFET semiconductor channel material nanosheets. In this embodiment, each pFET semiconductor channel material nanosheet of the plurality of pFET semiconductor channel material nanosheets is substantially aligned in a horizontal direction to each nFET semiconductor channel material nanosheet of the plurality of nFET semiconductor channel material nanosheets. The structure further includes a vertical dielectric pillar located between the nFET device region and the pFET device region, wherein the vertical dielectric pillar is a continuous pillar that separates the first functional gate structure from the second functional gate structure and separates first source/drain regions of the pFET from second source/drain regions of the nFET.

In yet another embodiment of the present application, the semiconductor structure includes a semiconductor substrate having a pFET device region and an nFET device region. A pFET is located in the pFET device region, wherein the pFET includes a first functional gate structure wrapped around a plurality of pFET semiconductor channel material nanosheets. An nFET is located in the nFET device region, wherein the nFET includes a second functional gate structure wrapped around a plurality of nFET semiconductor channel material nanosheets. In this embodiment, each pFET semiconductor channel material nanosheet of the plurality of pFET semiconductor channel material nanosheets is substantially aligned in a horizontal direction to each nFET semiconductor channel material nanosheet of the plurality of nFET semiconductor channel material nanosheets. The structure of this embodiment further includes a vertical dielectric pillar located between the nFET device region and the pFET device region, and a shallow trench isolation structure present in the semiconductor substrate and located laterally adjacent to the vertical dielectric pillar, wherein the vertical dielectric pillar is a continuous pillar that has a topmost surface that is coplanar with a topmost surface of the semiconductor substrate and with a topmost surface of the shallow trench isolation structure.

### BRIEF DESCRIPTION OF THE DRAWINGS

FIG. 1 is top-down view of a device layout that can be employed in the present application, the device layout includes a pFET device region having two first patterned material stacks, and an nFET device region having two second patterned material stacks, and functional gate structures present in both device regions, FIG. 1 includes a cut X₁-X₁, a cut X₂-X₂, a cut Y₁-Y₁, and a cut Y₂-Y₂.

FIGS. 2A, 2B, 2C and 2D are cross sectional views through X₁-X₁, X₂-X₂, Y₁-Y₁, and Y₂-Y₂, respectively, of an exemplary structure that can be employed in the present application, the exemplary structure includes a semiconductor substrate having a pFET device region and an nFET device region, a placeholder material layer, a plurality of patterned material stacks of alternating nFET semiconductor channel material layers and pFET semiconductor channel material layers stacked one on top of the other, and a plurality of sacrificial gate structures located on a surface of each patterned material stack, wherein a bottommost nFET semiconductor channel material layer and a bottommost pFET semiconductor channel material layer of each patterned material stack are both sacrificial layers.

FIGS. 3A, 3B, 3C and 3D are cross sectional views of the exemplary structure shown in FIGS. 2A, 2B, 2C and 2D, respectively, after removing the placeholder material layer and forming a bilayer dielectric material structure on physically exposed surfaces of the structure and within the volume previously occupied by the placeholder material layer, wherein the bilayer dielectric material structure in the volume previously occupied by the placeholder material layer provides a bottom dielectric isolation bilayer structure beneath each patterned material stack.

FIGS. 4A, 4B, 4C and 4D are cross sectional views of the exemplary structure shown in FIGS. 3A, 3B, 3C and 3D, respectively, after etching the physically exposed portions of the bilayer dielectric material structure to provide an inner gate spacer and an outer gate spacer, converting each patterned material stack that is present in the pFET device region and the nFET device region into a nanosheet-containing stack of alternating nFET semiconductor channel material nanosheets and pFET semiconductor channel material nanosheets stacked one on top of the other, wherein a bottommost nFET semiconductor channel material nanosheet and a bottommost pFET semiconductor channel material nanosheet of each patterned material stack are both sacrificial nanosheets, forming inner spacers in each of the pFET device region and the nFET device region, and forming source/drain regions in each of the pFET device region and the n-FET device region.

FIGS. 5A, 5B, 5C and 5D are cross sectional views of the exemplary structure shown in FIGS. 4A, 4B, 4C and 4D, respectively, after forming an interlayer dielectric (ILD) material layer.

FIGS. 6A, 6B, 6C and 6D are cross sectional views of the exemplary structure shown in FIGS. 5A, 5B, 5C and 5D, respectively, after removing each sacrificial gate structure.

FIGS. 7A, 7B, 7C and 7D are cross sectional views of the exemplary structure shown in FIGS. 6A, 6B, 6C and 6D, respectively, after suspending each pFET semiconductor channel material nanosheet in each nanosheet-containing stack present in the pFET device region, and each nFET semiconductor channel material nanosheet in each nanosheet-containing stack present in the nFET device region, removing the inner gate spacer, trimming each suspended pFET semiconductor channel material nanosheet and each suspended nFET semiconductor channel material nanosheet and forming a first functional gate structure in the pFET device region and a second functional gate structure in the nFET device region, and forming a gate cut region between the first functional gate structure and the second functional gate structure.

FIGS. 8A, 8B, 8C and 8D are cross sectional views of the exemplary structure shown in FIGS. 7A, 7B, 7C and 7D, respectively, after forming gate contact structures and source/drain contact structures in both the pFET device region and the nFET device region.

FIGS. 9A, 9B, 9C and 9D are cross sectional views of another exemplary structure that can be formed utilizing the processing as mentioned in providing the structure shown in FIGS. 8A, 8B, 8C, and 8D, but without forming the gate cut region; in this embodiment the first functional gate structure and the second functional gate structure have a shared gate electrode.

FIGS. 10A, 10B, 10C and 10D are cross sectional views through X₁-X₁, X₂-X₂, Y₁-Y₁, and Y₂-Y₂, respectively, of an exemplary structure that can be employed in the present application, the exemplary structure includes a semiconductor substrate having a pFET device region and an nFET device region, a placeholder material layer, a plurality of patterned material stacks of alternating pFET semiconductor channel material layers and nFET semiconductor channel material layers stacked one on top of the other, and a plurality of sacrificial gate structures located on a surface of each patterned material stack, wherein a bottommost pFET semiconductor channel material layer of each patterned material stack is a sacrificial layer.

FIGS. 11A, 11B, 11C and 11D are cross sectional views of the exemplary structure shown in FIGS. 10A, 10B, 10C and 10D, respectively, after performing various processing steps in accordance with the present application.

FIGS. 12A, 12B, 12C and 12D are cross sectional views of the exemplary structure shown in FIGS. 10A, 10B, 10C and 10D, respectively, after performing various processing steps in accordance with the present application.

FIGS. 13A, 13B, 13C and 13D are cross sectional views of the exemplary structure shown in FIGS. 10A, 10B, 10C and 10D, respectively, after replacing the placeholder material layer with a bottom dielectric isolation bilayer structure including a second dielectric material layer sandwiched between top and bottom first dielectric material layers.

FIGS. 14A, 14B, 14C and 14D are cross sectional views of the exemplary structure shown in FIGS. 13A, 13B, 13C and 13D, respectively, after forming a gate dielectric spacer layer.

FIGS. 15A, 15B, 15C and 15D are cross sectional views of the exemplary structure shown in FIGS. 14A, 14B, 14C and 14D, respectively, after performing various processing steps in accordance with the present application.

FIGS. 16A, 16B, 16C and 16D are cross sectional views through X₁-X₁, X₂-X₂, Y₁-Y₁, and Y₂-Y₂, respectively, of an exemplary structure that can be employed in the present application, the exemplary structure includes a semiconductor substrate having a pFET device region and an nFET device region, a bottom dielectric isolation structure, a plurality of patterned material stacks of alternating pFET semiconductor channel material layers and an nFET semiconductor channel material layers stacked one on top of the other, and a plurality of sacrificial gate structures located on a surface of each patterned material stack, wherein a bottommost pFET semiconductor channel material layer of each patterned material stack is a sacrificial layer.

FIGS. 17A, 17B, 17C and 17D are cross sectional views of the exemplary structure shown in FIGS. 16A, 16B, 16C and 16D, respectively, after forming a gate dielectric spacer layer.

FIGS. 18A, 18B, 18C and 18D are cross sectional views of the exemplary structure shown in FIGS. 17A, 17B, 17C and 17D, respectively, after performing various processing steps in accordance with the present application.

FIGS. 19A, 19B, 19C and 19D are cross sectional views of the exemplary structure shown in FIGS. 17A, 17B, 17C and 17D, respectively, after performing various processing steps in accordance with the present application.

FIGS. 20A, 20B, 20C and 20D are cross sectional views through X₁-X₁, X₂-X₂, Y₁-Y₁, and Y₂-Y₂, respectively, of an exemplary structure that can be employed in the present application, the exemplary structure includes a semiconductor substrate having a pFET device region and an nFET device region, a placeholder dielectric material layer, and a first material stack of alternating pFET semiconductor channel material layers and nFET semiconductor channel material layers.

FIGS. 21A, 21B, 21C and 21D are cross sectional views of the exemplary structure shown in FIGS. 20A, 20B, 20C and 20D, respectively, after processing the pFET device region by removing the first material stack and forming a second material stack of alternating nFET semiconductor channel material layers and pFET semiconductor material layers, wherein the first and second material stacks are separated by a vertical dielectric material pillar.

FIGS. 22A, 22B, 22C and 22D are cross sectional views of the exemplary structure shown in FIGS. 21A, 21B, 21C and 21D, respectively, after patterning the first and second material stacks, forming a shallow trench isolation structure, and forming a plurality of sacrificial gate structures in the pFET device region and the nFET device region.

FIGS. 23A, 23B, 23C and 23D are cross sectional views of the exemplary structure shown in FIGS. 22A, 22B, 22C and 22D, respectively, after forming a gate dielectric spacer layer and a bottom dielectric isolation structure.

FIGS. 24A, 24B, 24C and 24D are cross sectional views of the exemplary structure shown in FIGS. 23A, 23B, 23C and 23D, respectively, after performing nanosheet stack formation processing steps in each of the pFET device region and the nFET device region.

FIGS. 25A, 25B, 25C and 25D are cross sectional views of the exemplary structure shown in FIGS. 24A, 24B, 24C and 24D, respectively, after suspending appropriate semiconductor channel material nanosheets in each of the pFET device region and the nFET device region, forming functional gate structures in each of the device regions, and forming various contact structures.

FIGS. 26A, 26B, 26C and 26D are cross sectional views of another structure that can be formed utilizing the structure shown in FIGS. 22A, 22B, 22C and 22D.

FIGS. 27A, 27B, 27C and 27D are cross sectional views through X₁-X₁, X₂-X₂, Y₁-Y₁, and Y₂-Y₂, respectively, of an exemplary structure that can be employed in the present application, the exemplary structure includes a semiconductor substrate having a pFET device region and an nFET device region, a first material stack of alternating nFET semiconductor channel material layers and pFET semiconductor channel material layers located in the pFET device region, and a second material stack of alternating pFET semiconductor channel material layers and nFET semiconductor channel material layers located in the nFET device region, wherein a vertical dielectric pillar separates two material stacks from each other.

FIGS. 28A, 28B, 28C and 28D are cross sectional views of the exemplary structure shown in FIGS. 27A, 27B, 27C and 27D, respectively, after performing nanosheet device processing steps as can be derived from the present application.

FIGS. 29A, 29B, 29C and 29D are cross sectional views through X₁-X₁, X₂-X₂, Y₁-Y₁, and Y₂-Y₂, respectively, of an exemplary structure that can be employed in the present application, the exemplary structure includes a semiconductor substrate having a pFET device region and an nFET device region, a placeholder material layer on the semiconductor substrate, a first patterned material stack of alternating nFET semiconductor channel material layers and pFET semiconductor channel material layers in the pFET device region, and a second patterned material stack of alternating pFET semiconductor channel material layers and nFET semiconductor channel materials in the nFET device region, wherein a vertical dielectric pillar separates two device regions from each other.

FIGS. 30A, 30B, 30C and 30D are cross sectional views of the exemplary structure shown in FIGS. 29A, 29B, 29C and 29D, respectively, after performing nanosheet device processing steps as can be derived from the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

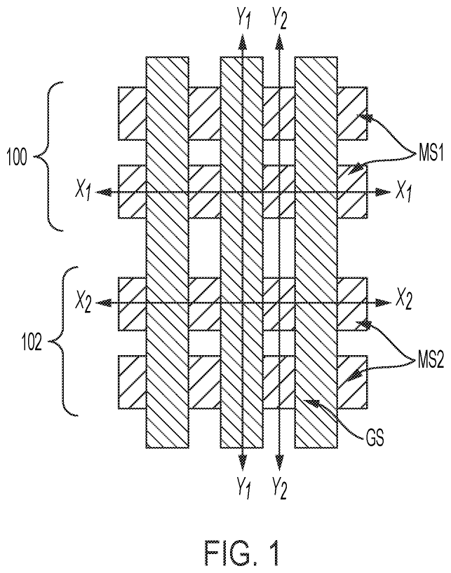

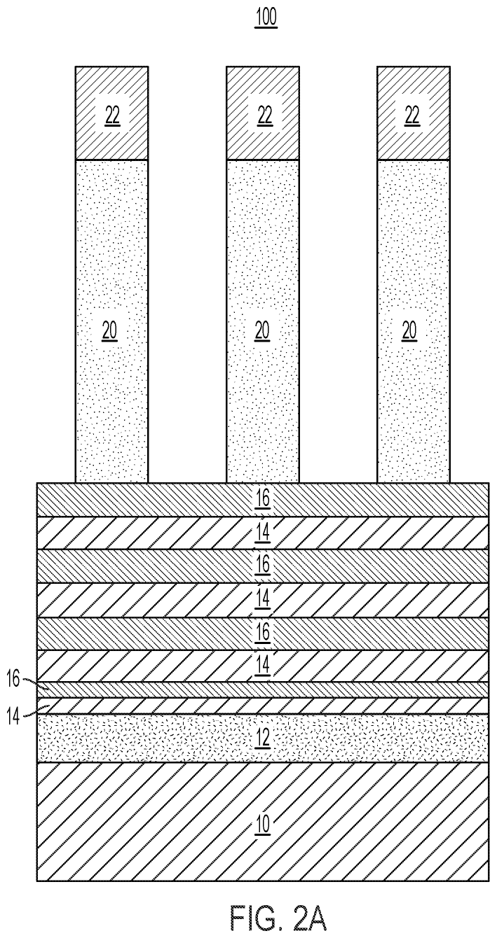

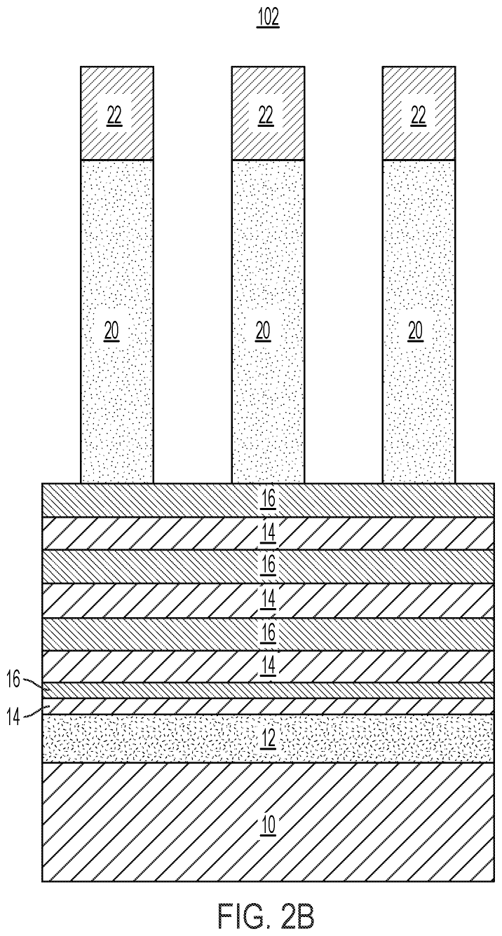

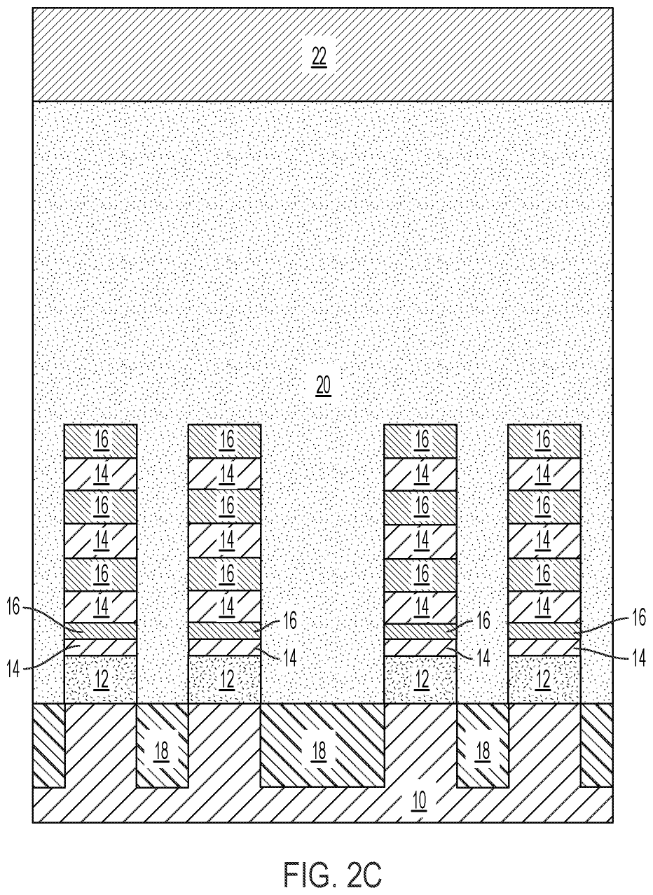

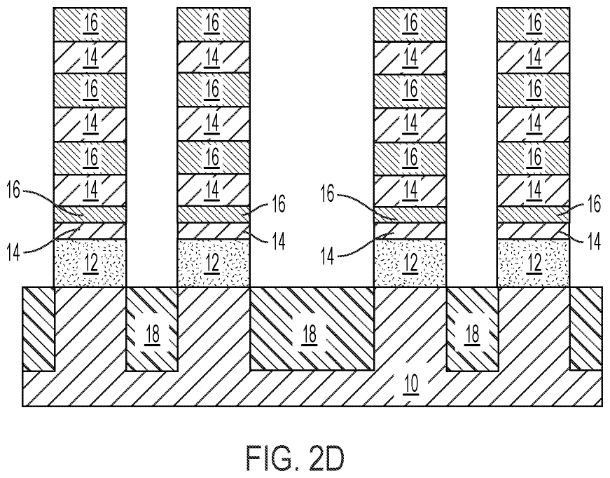

Referring now to FIG. 1, there is illustrated a top-down view of a device layout that can be employed in the present application. The illustrated device layout includes a pFET device region 100 having two first patterned material stacks MS1, and an nFET device region 102 having two second patterned material stacks MS2. The device layout illustrated in FIG. 1 also includes functional gate structures GS (three of which are shown by way of one example in FIG. 1). The functional gate structures GS are orientated parallel to each other and contact a surface of each of the first patterned material stacks MS1 in the pFET device region 100 and each of the second patterned material stacks MS2 in the nFET device region 102. FIG. 1 includes a cut X₁-X₁ which is along a lengthwise direction of one of the first patterned material stacks MS1 in the pFET device region 100 (i.e., pFET cross gate cross section), a cut X₂-X₂ which is along a lengthwise direction of one of the second patterned material stacks MS2 in the nFET device region 102 (i.e., an nFET cross gate cross section), a cut Y₁-Y₁ which is along a lengthwise direction of one functional gate structures GS (i.e., a cross fin gate region) a cut Y₂-Y₂ which is a source/drain area between a neighboring pair of functional gate structures and in both the pFET device region 100 and the n-FET device region 102 (i.e., a cross fin S/D region). In the present application each of FIGS. 2A, 3A, 4A, 5A, . . . 30A is through cross section X₁-X₁, each of FIGS. 2B, 3B, 4B, 5B, . . . 30B is through cross section X₂-X₂, each of FIGS. 2C, 3C, 4C, 5C, . . . 30C is through cross section Y₁-Y₁, and each of FIGS. 2D, 3D, 4D, 5D, . . . 30D is through cross section Y₂-Y₂.

Reference will now be made to FIGS. 2A-19D which illustrate a first embodiment of the present application in which a semiconductor structure is provided that includes a pFET located in a pFET device region, the pFET includes a first functional gate structure and a plurality of pFET semiconductor channel material nanosheets, and an nFET located in the nFET device region, the nFET includes a second functional gate structure and a plurality of pFET semiconductor channel material nanosheets. In this embodiment, the pFET semiconductor channel material nanosheets are staggered relative to the nFET semiconductor channel material nanosheets. In this embodiment, a bottom dielectric isolation structure (bilayer or single layered as will be defined herein below) is located in both the device regions, and the second functional gate structure has a bottommost surface that extends beneath a topmost surface of the bottom dielectric isolation bilayer structure.

Notably, and referring to FIGS. 2A, 2B, 2C and 2D, there are illustrated through cross sectional views through X₁-X₁, X₂-X₂, Y₁-Y₁, and Y₂-Y₂ of FIG. 1, respectively. The exemplary structure that can be employed in the present application includes a semiconductor substrate 10 having a pFET device region 100 (which is shown in FIG. 2A) and an nFET device region 102 (which is shown in FIG. 2B), a placeholder material layer 12 which is located on a surface of the semiconductor substrate 10, and a plurality of patterned material stacks 14/16 located on the placeholder material layer 12. The semiconductor substrate 10 can also include a shallow trench isolation structure 18 present therein. As is shown in FIG. 2C, the shallow trench isolation region 18 is present at the footprint and on each side of the patterned material stack 14/16. Each patterned material stack has a fin pattern and includes alternating nFET semiconductor channel material layers 14 and pFET semiconductor channel material layers 16 stacked one on top of the other. In this embodiment of the present application, a bottommost nFET semiconductor channel material layer 14 and a bottommost pFET semiconductor channel material layer 16 of each patterned material stack are both sacrificial layers The exemplary structure shown in FIGS. 2A-2D also includes a plurality of sacrificial gate structures 20 located on a surface of each patterned material stack 14/16. A hard mask cap 22 can be located on top of each sacrificial gate structure 20. In this embodiment, the patterned material stack, contains the same number of nFET semiconductor channel material layers 14 and pFET semiconductor channel material layers 16.

The semiconductor substrate 10 is composed of a semiconductor material having semiconducting properties. Examples of semiconductor materials that can be used to provide the semiconductor substrate include, but are not limited to, silicon (Si), a silicon germanium (SiGe) alloy, a silicon germanium carbide (SiGeC) alloy, germanium (Ge), III/V compound semiconductors or II/VI compound semiconductors. The semiconductor substrate 10 can be composed of one or more of these semiconductor materials. In one embodiment, a bulk substrate is used as semiconductor substrate 10. The term “bulk substrate” denotes a substrate that is entirely composed of one or more semiconductor materials. An example of a bulk semiconductor substrate is a Si substrate. In some embodiments, the semiconductor substrate 10 is a semiconductor-on-insulator (SOI) substrate. The SOI substrate has a bottom handle layer (which can be composed of one of the semiconductor materials), a buried dielectric layer (which can be composed of silicon dioxide and/or boron nitride) and a top semiconductor layer (which can be composed of one of the semiconductor materials mentioned above). An example of a SOI substrate is a substrate composed of Si/silicon dioxide/Si.

The placeholder material layer 12 is composed of a semiconductor material that is compositionally different from uppermost semiconductor material portion of the semiconductor substrate 10 as well as the semiconductor material that provides both the nFET semiconductor channel material layers 14 and the pFET semiconductor channel material layers 16. In one example, the placeholder material layer 12 is composed of a silicon germanium alloy having a germanium content of from 40 atomic percent to 75 atomic percent. Typically, the placeholder material layer 12 has a thickness from 5 nm to 20 nm.

Each nFET semiconductor channel material layer 14 is composed of a semiconductor material that can facilitate high electron mobility of the nFET that will be subsequently formed in the nFET device region. One such semiconductor material that can be used in providing each nFET semiconductor channel material layer 14 is silicon. Each pFET semiconductor channel material layer 16 is composed of a semiconductor material that can facilitate high electron mobility of the pFET that will be subsequently formed in the pFET device region. One such semiconductor material that can be used in providing each pFET semiconductor channel material layer 16 is a silicon germanium alloy having a germanium content of from 15 atomic percent to 40 atomic percent. It is noted that the semiconductor material that provides each nFET semiconductor channel material layer 14 is compositionally different from the semiconductor material that provides each pFET semiconductor channel material layer 16, and that the semiconductor materials that provide both the nFET semiconductor channel material layers 14 and the pFET semiconductor channel material layers 16 are compositionally different from the semiconductor material that provides the placeholder material layer 12.

In this embodiment of the present application, each nFET semiconductor channel material layer 14, except for the bottommost nFET semiconductor channel material layer 14 of the patterned material stacks, has a first thickness, while the bottommost nFET semiconductor channel material layer 14 of the patterned material stacks has a second thickness that is less than the first thickness. In one example, the first thickness can be from 5 nm to 12 nm, while the second thickness can be from 2 nm to 4 nm.

Likewise, and in this embodiment of the present application, each pFET semiconductor channel material layer 16, except for the bottommost pFET semiconductor channel material layer 16 of the patterned material stacks, has a third thickness, while the bottommost pFET semiconductor channel material layer 16 of the patterned material stacks has a fourth thickness that is less than the third thickness. In one example, the third thickness can be from 5 nm to 12 nm, while the fourth thickness can be from 2 nm to 4 nm. Typically, but not necessarily always, the first thickness equals the third thickness, and the second thickness equal the fourth thickness.

The shallow trench isolation structure 18 is composed of any trench dielectric material such as, for example, silicon oxide. In some embodiments, a trench dielectric material such as, for example, SiN, can be present along a sidewall and a bottom wall of the trench dielectric material. The shallow trench isolation structure 18 can have a topmost surface that is coplanar with a topmost surface of the non-etched portion of the semiconductor substrate 10.

Each sacrificial gate structure 20 includes at least a sacrificial gate material. In some embodiments, each sacrificial gate structure 20 can include a sacrificial gate dielectric material. The sacrificial gate dielectric material can be composed of a dielectric material such as, for example, silicon dioxide. The sacrificial gate material can include, but is not limited to, polysilicon, amorphous silicon, amorphous silicon germanium or amorphous germanium.

Each hard mask cap 22 can be composed of a dielectric hard mask material such as, for example, silicon nitride and/or silicon oxynitride. In the illustrated embodiment, each hard mask cap 22 has a sidewall that is vertically aligned to the sidewall of one of the sacrificial gate structures 20. In embodiments, the hard mask caps 22 can be omitted from the exemplary structure. Note that within the source/drain cross section shown in FIG. 2D, no sacrificial gate structure 22 or hard mask cap 22 is present.

The exemplary structure shown in FIGS. 2A-2D can be formed by first forming the placeholder material layer 12 on the semiconductor substrate 10. The placeholder material layer 12 can be formed by a deposition process such as, for example, chemical vapor deposition (CVD), plasma enhanced chemical vapor deposition (PECVD), or epitaxial growth. The terms “epitaxial growth” or “epitaxially growing” means the growth of a second semiconductor material on a growth surface of a first semiconductor material, in which the second semiconductor material being grown has the same crystalline characteristics as the first semiconductor material. In an epitaxial deposition process, the chemical reactants provided by the source gases are controlled and the system parameters are set so that the depositing atoms arrive at the growth surface of the first semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking.

Next, a blanket material stack of alternating blanket layers of an nFET semiconductor channel material and a pFET semiconductor channel material is formed. The blanket layers of nFET semiconductor channel material and pFET semiconductor channel material are stacked one on top of the other. This blanket material stack can be formed by one or more deposition processes including, for example, CVD, PECVD or epitaxial growth. Within the blanket material stack that bottommost blanket layer of nFET semiconductor material is formed to the second thickness and the remaining blanket layers of the nFET semiconductor material are formed to the first thickness, the bottommost blanket layer of pFET semiconductor material is formed to the fourth thickness, and the remaining blanket layers of pFET semiconductor material are formed to the third thickness. This blanket material stack can then be patterned by lithography and etching to provide the plurality of patterned material stacks 14/16 mentioned above. After forming the plurality of patterned material stacks 14/16, the shallow trench isolation structure 18 is formed utilizing techniques well-known to those skilled in the art. Next, a blanket layer of sacrificial gate structure material and a blanket layer of hard mask material are formed by deposition processes such as, for example, CVD, PECVD, physical vapor deposition (PVD) or atomic layer deposition (ALD). The blanket layers of hard mask material and sacrificial gate structure material are then patterned by lithography and etching to provide the hard masks 22 and the sacrificial gate structures 20 mentioned above.

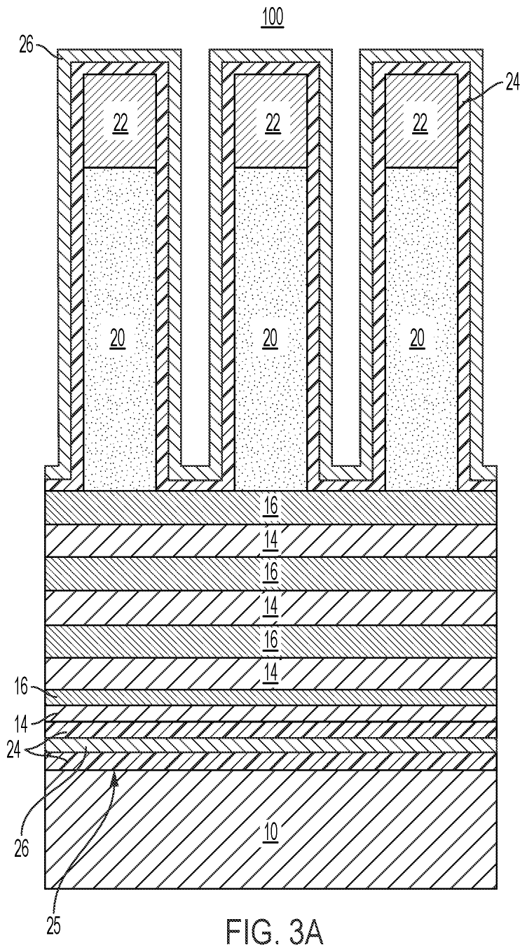

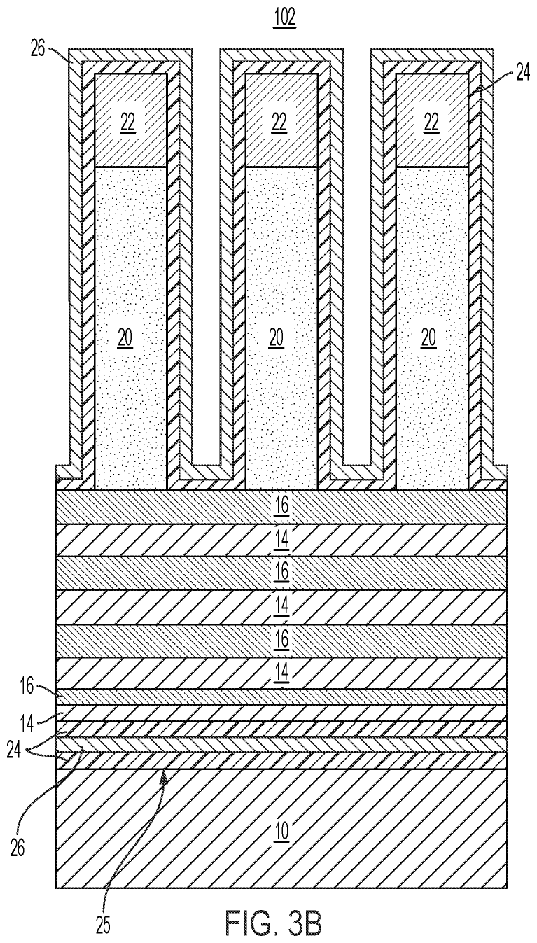

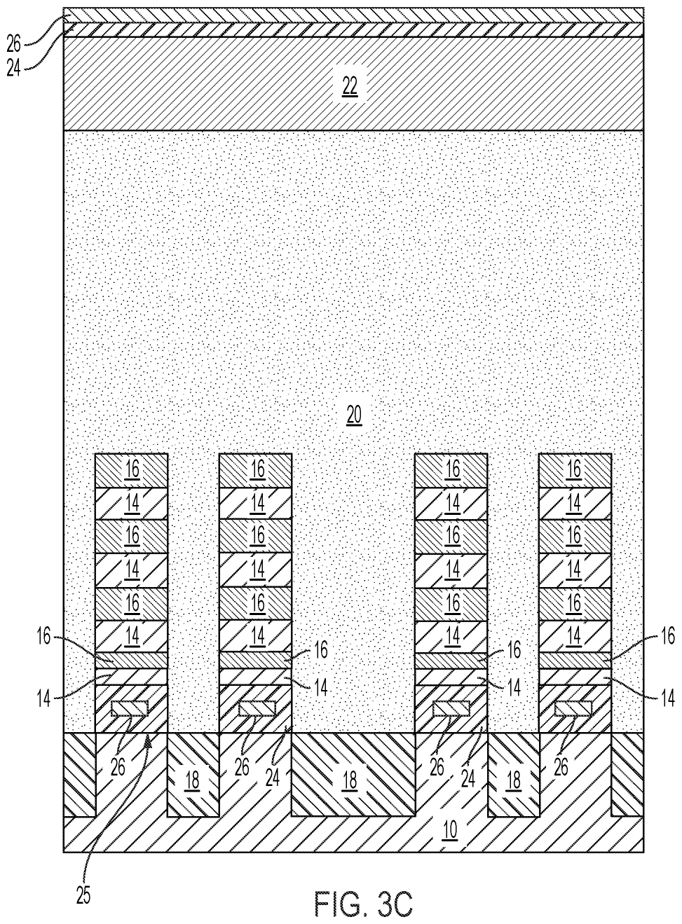

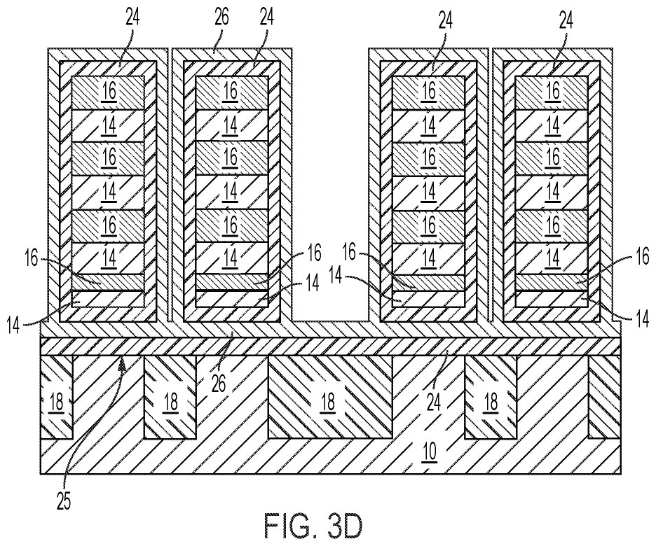

Referring now to FIGS. 3A, 3B, 3C and 3D, there are illustrated the exemplary structure shown in FIGS. 2A, 2B, 2C and 2D, respectively, after removing the placeholder material layer 12 and forming a bilayer dielectric material structure 24/26 on physically exposed surfaces of the structure and within the volume previously occupied by the placeholder material layer 12. The bilayer dielectric material structure 24/26 that is formed in the volume previously occupied by the placeholder material layer 12 provides a bottom dielectric isolation bilayer structure 25 beneath each patterned material stack 14/16.

The placeholder material layer 12 can be removed utilizing an etching process that is selective in removing the material that provides the placeholder material layer 12. After removing the placeholder material layer 12, a gap is formed between each patterned material stack 14/16. Each patterned material stack 14/16 is anchored by a sacrificial gate structure 20 thus the patterned material stacks 14/16 do not collapse upon the semiconductor substrate 10 after placeholder material removal.

The bilayer dielectric material structure 24/26 is then formed by first depositing a first (e.g., outer) dielectric material layer 24 composed of a first dielectric material, and then second depositing a second (i.e., inner) dielectric material layer 26 composed of a second dielectric material that is compositionally different from the first dielectric material. The first depositing and second depositing are both conformal deposition processes such as, for example, CVD, PECVD, or ALD. The first dielectric material can include, for example, a dielectric material oxide such as AlOₓ, while the second dielectric material can, for example, a low-k dielectric (dielectric constant of less than 4.0) such as, for example, SiOCN, SiON, SiOC or SiBCN. Within the gap, the second dielectric material layer 26 is formed between a top first dielectric material layer 24 and a bottom first dielectric material layer 24. The bottom first dielectric material layer 24 is formed on the semiconductor substrate 10 and the top first dielectric material layer 24 is formed on a physical exposed surface of the bottommost semiconductor channel material layer 14 of each patterned material stack 14/16.

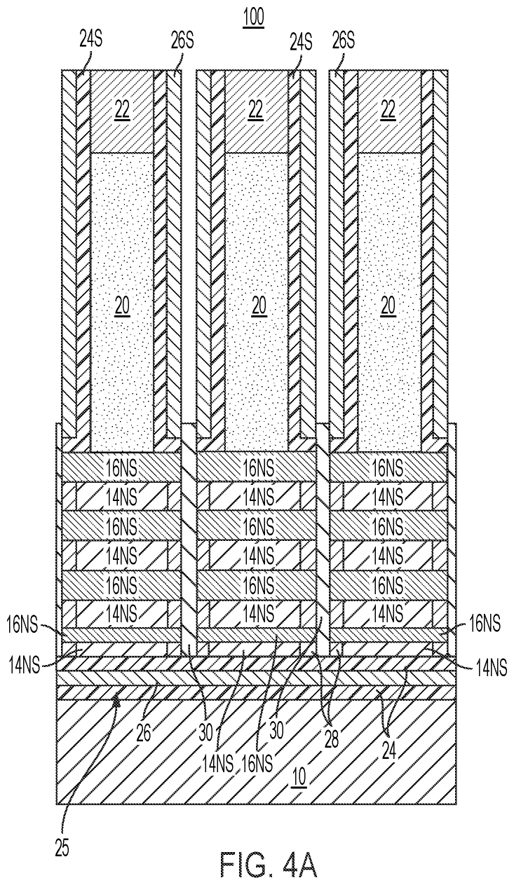

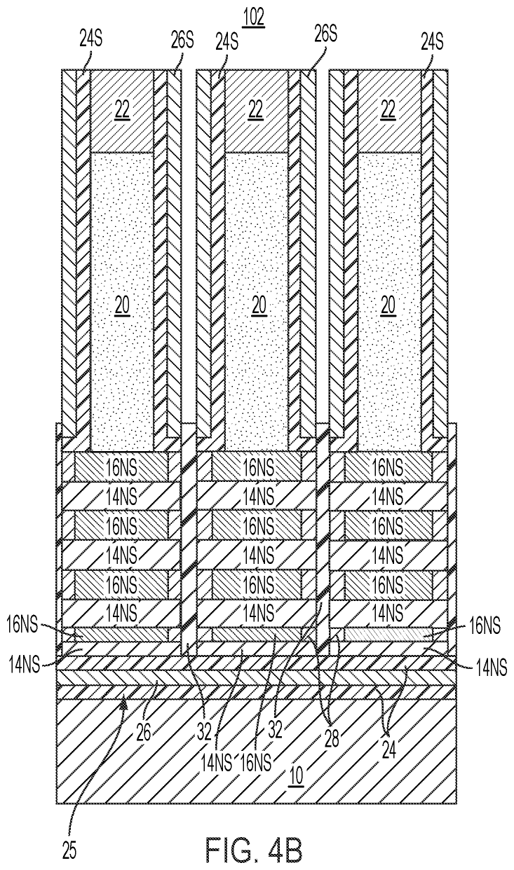

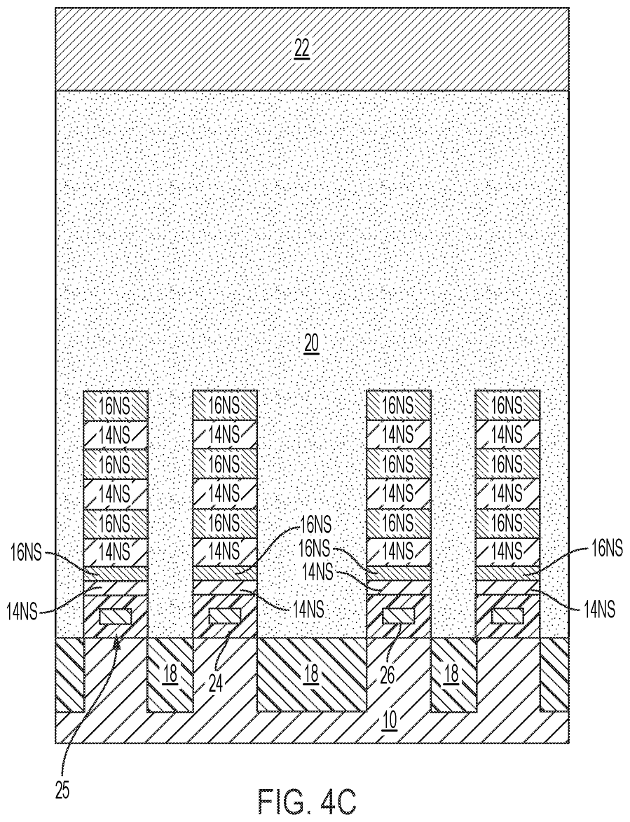

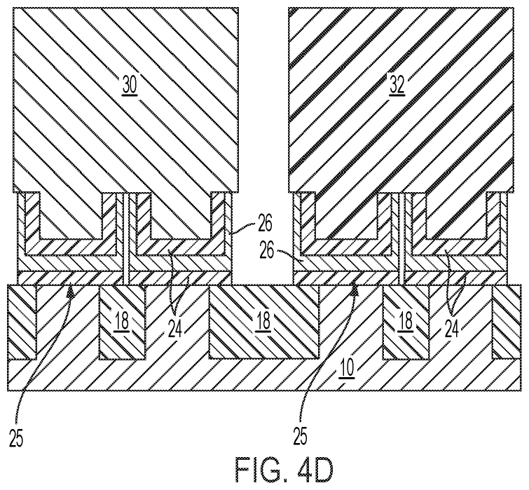

Referring now to FIGS. 4A, 4B, 4C and 4D, there are illustrated the exemplary structure shown in FIGS. 3A, 3B, 3C and 3D, respectively, after etching the physically exposed portions of the bilayer dielectric material structure 24/26 to provide an inner gate spacer 24S and an outer gate spacer 26S, converting each patterned material stack 14/16 that is present in the pFET device region and the nFET device region into a nanosheet-containing stack of alternating nFET semiconductor channel material nanosheets 14NS and pFET semiconductor channel material nanosheets 16NS stacked one on top of the other, wherein a bottommost nFET semiconductor channel material nanosheet 14NS and a bottommost pFET semiconductor channel material nanosheet 16NS of each patterned nanosheet-containing stack are both sacrificial nanosheets, forming inner spacers 28 in each of the pFET device region and the nFET device region, and forming source/drain regions in each of the pFET device region and the n-FET device region. Notably, first source/drain regions 30 are formed in the pFET device region and second source/drain regions 32 are formed in the pFET device region. Note that in the present application, the above processing is performed separately in each of the device regions. Thus, the pFET device region can be processed as described above (bilayer dielectric material structure etch, nanosheet-containing stack formation, inner spacer formation and first source/drain region formation) prior to, or after processing, the nFET device region as described above (bilayer dielectric material structure etch, nanosheet-containing stack formation, inner spacer formation and second source/drain region formation). Block mask technology can be used to process one of the device regions prior to processing the other.

Notably, and assuming an embodiment in which the pFET device region is processed first, a block mask is formed over the nFET device region and then the bilayer dielectric material structure is etched by a spacer etch (e.g., a reactive ion etch) so as to form the inner gate spacer 24S and the outer gate spacer 26S in the pFET device region. This etch removes physically exposed portions of the bilayer dielectric material structure from all horizontal surfaces including, for example, from atop each hard mask cap 22. The inner gate spacer 24S is present along a sidewall of each hard mask capped sacrificial gate structure in the pFET device region, and the outer gate spacer 26S is located laterally adjacent to the inner gate spacer 24S. Next, the patterned material stack in the pFET device region is etched utilizing each hard masked capped sacrificial gate structure and the inner and outer gate spacers 24S, 26S as a combined etch mask. The etch converts the patterned material stack in the pFET device region to a nanosheet-containing structure as defined above. Note that the nFET semiconductor channel material nanosheets 14NS and the pFET semiconductor channel material nanosheets 16NS are non-etched portions of nFET semiconductor channel material layers 14 and the pFET semiconductor channel material layers 16, respectively. Each nFET semiconductor channel material nanosheet 14NS and each pFET semiconductor channel material nanosheet 16NS have a width from 10 nm to 100 nm, and a length from 20 nm to 150 nm; this length is prior to forming the inner spacers 28.

Next inner spacers 28 are formed in the pFET device region (these inner spacers can be referred to as first inner spacers). The inner spacers 28 are formed by selectively recessing end portions of each nFET semiconductor channel material nanosheet 14NS relative to each pFET semiconductor channel material nanosheet 16NS. This selective etch (which includes a lateral etch) provides inner spacers gaps next to the recessed nFET semiconductor channel material nanosheet 14NS which are then filled with an inner dielectric spacer material such as, for example, SiN, SiBCN, SiOCN, SiON or SiOC. Filling includes conformal deposition of the inner dielectric spacer material followed by performing an isotropic etch back process.

Next, first source/drain regions 30 (or pFET device source/drain regions) are formed outwards from the physically exposed end wall of each pFET semiconductor channel material nanosheet 16NS. The first source/drain regions 30 are composed of a semiconductor material and a first dopant. As used herein, a “source/drain or S/D” region can be a source region or a drain region depending on subsequent wiring and application of voltages during operation of the field effect transistor (FET). As is known, source/drain regions are located on each side of a gate structure. The semiconductor material that provides the first source/drain regions 30 can include one of the semiconductor materials mentioned above for the semiconductor substrate 10. The semiconductor material that provides the first source/drain regions 30 can be compositionally the same as, or compositionally different from, each pFET semiconductor channel material nanosheet 16NS. The first dopant that is present in the first source/drain regions 30 is a p-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. The first source/drain regions 30 can be formed by epitaxial growth, followed by a recess etch to adjust the height of the first source/drain regions 30 (in embodiments, the recess etch can be omitted). This completes the process of the pFET device region.

The nFET device region can now be processed by first removing the block mask from the nFET device region and thereafter another block mask is formed on the previously processed pFET device region. The bilayer dielectric material structure in the nFET device region is then etched as defined above so as to form the inner gate spacer 24S and the outer gate spacer 26S in the nFET device region. Next, the patterned material stack in the nFET device region is etched utilizing each hard masked capped sacrificial gate structure and the inner and outer gate spacers 24S, 26S as a combined etch mask. The etch converts the patterned material stack in the nFET device region to a nanosheet-containing structure as defined above.

Next inner spacers 28 are formed in the nFET device region (these inner spacers can be referred to as second inner spacers). The inner spacers 28 are formed by selectively recessing end portions of each pFET semiconductor channel material nanosheet 16NS relative to each nFET semiconductor channel material nanosheet 14NS. This selective etch (which includes a lateral etch) provides inner spacers gaps next to the recessed pFET semiconductor channel material nanosheet 16NS which are then filled with an inner dielectric spacer material such as, for example, SiN, SiBCN, SiOCN, SiON or SiOC. Filling includes conformal deposition of the inner dielectric spacer material followed by performing an isotropic etch back process.

Next, second source/drain regions 32 (or nFET device source/drain regions) are then formed outwards from the physically exposed end wall of each nFET semiconductor channel material nanosheet 14NS. The second source/drain regions 32 are composed of a semiconductor material and a second dopant, which is of a different conductivity type than the first dopant. The semiconductor material that provides the second source/drain regions 32 can include one of the semiconductor materials mentioned above for the semiconductor substrate 10. The semiconductor material that provides the second source/drain regions 32 can be compositionally the same as, or compositionally different from, each nFET semiconductor channel material nanosheet 14NS. The second dopant that is present in the second source/drain regions 32 is a n-type dopant. N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. The second source/drain regions 32 can be formed by epitaxial growth and an optional etch back process. This completes the processing of the nFET device region thus the block mask can be removed from the pFET device region.

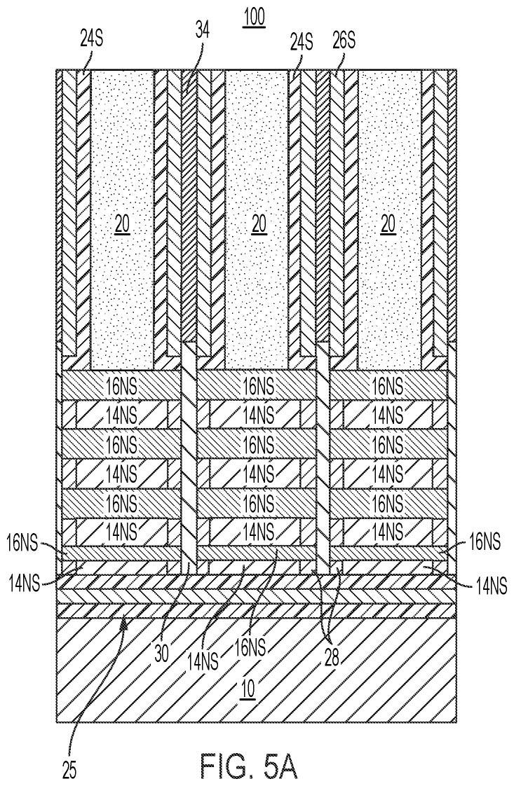

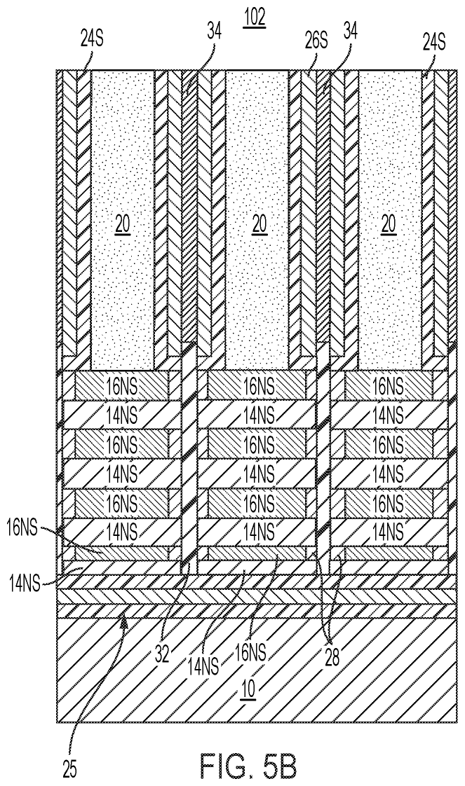

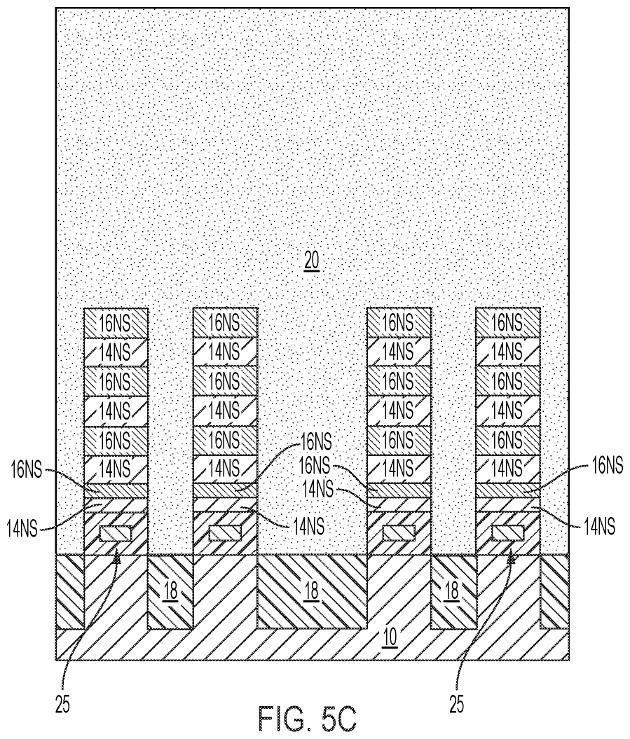

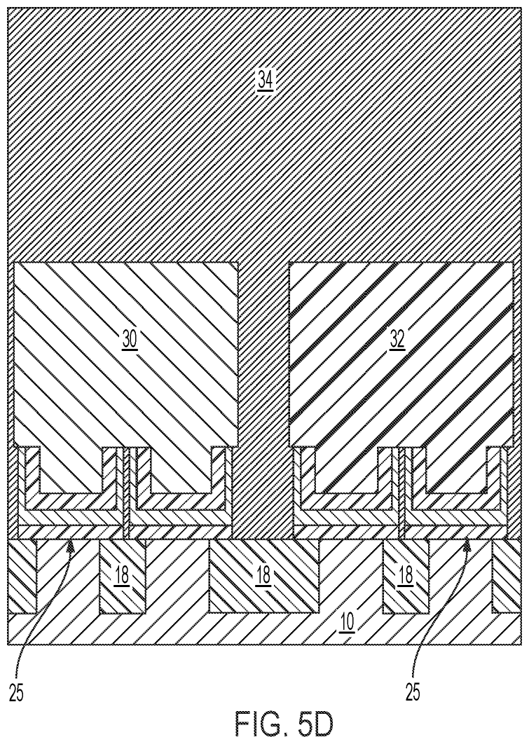

Referring now to FIGS. 5A, 5B, 5C and 5D, there are illustrated the exemplary structure shown in FIGS. 4A, 4B, 4C and 4D, respectively, after forming an interlayer dielectric (ILD) material layer 34. The ILD material layer 34 can be composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. All dielectric constants mentioned herein are measured relative to a vacuum unless otherwise is stated. The ILD material layer 34 can be formed by a deposition process (such as, for example, CVD, PECVD, ALD, or spin-on coating), followed by a planarization process such as, for example, chemical mechanical polishing (CMP). The planarization process removes each hard mask cap 22 as well as an upper portion of the inner gate spacers 24S and outer gate spacer 26S, stopping on a surface of each sacrificial gate structure 20. The ILD material layer 34 is formed on top of each first source/drain region 30 and each second source/drain region 32, and the ILD material layer 34 has a topmost surface that is coplanar with a topmost surface of each sacrificial gate structure 20.

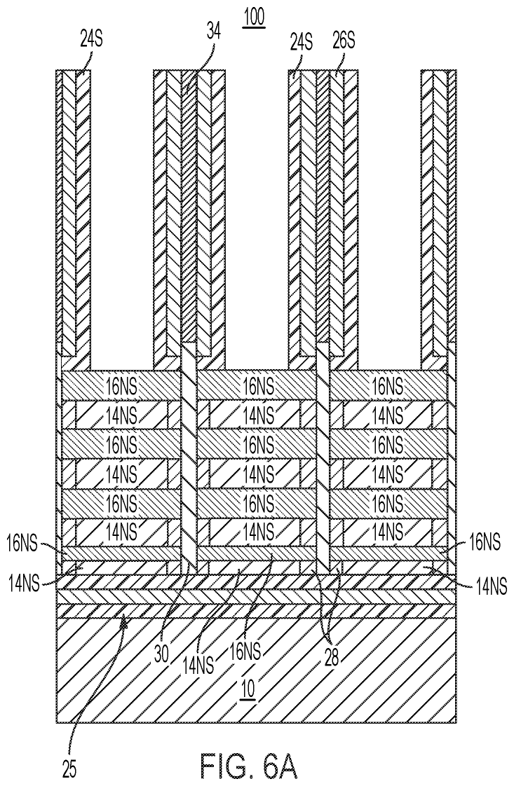

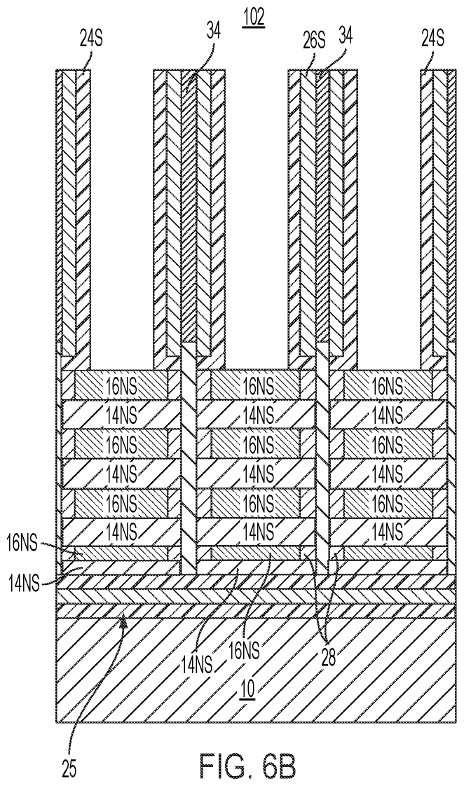

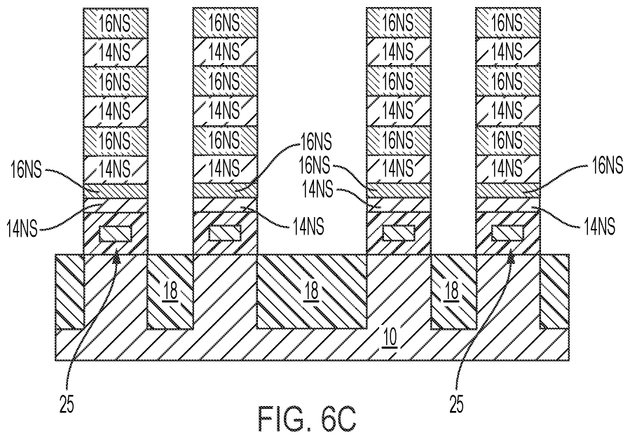

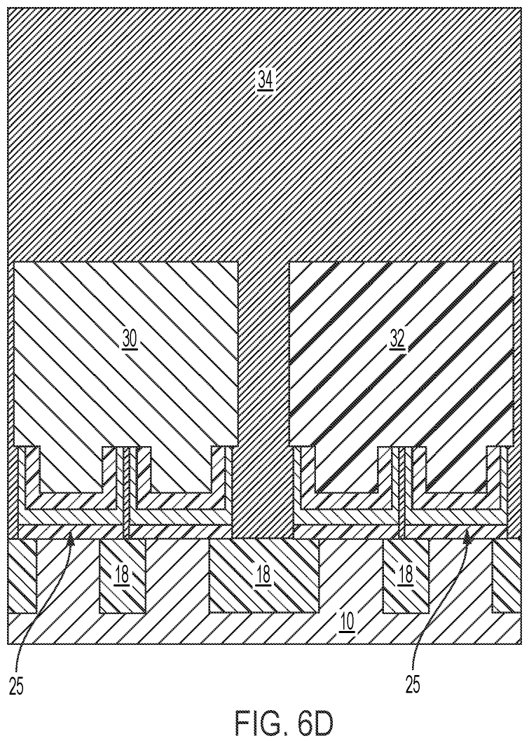

Referring now to FIGS. 6A, 6B, 6C and 6D, there are illustrated the exemplary structure shown in FIGS. 5A, 5B, 5C and 5D, respectively, after removing each sacrificial gate structure 20. The removal of each sacrificial gate structure 20, which occurs after ILD material layer 34 formation (See, the description for FIGS. 5A-5D above), includes an etching process that is selective in removing the material that provides the sacrificial gate structures 20. Typically, a single etch is used, but multiple etching can be used depending on the materials that are present in the sacrificial gate structures 20. The removal of the sacrificial gate structures 20 includes removing the sacrificial gate material and, if present, the sacrificial gate dielectric material. The removal of the sacrificial gate structures 20 in both the pFET device region and the nFET device regions reveals each nanosheet-containing stack that is present in the respective device regions.

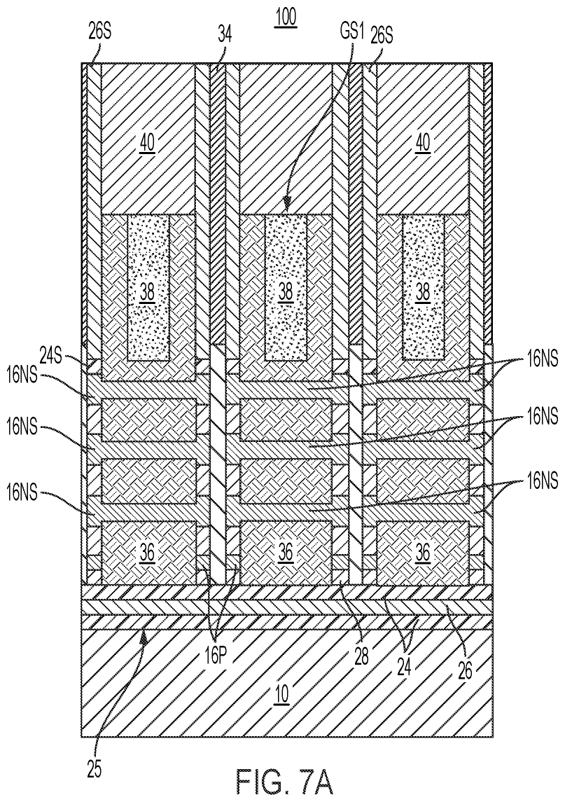

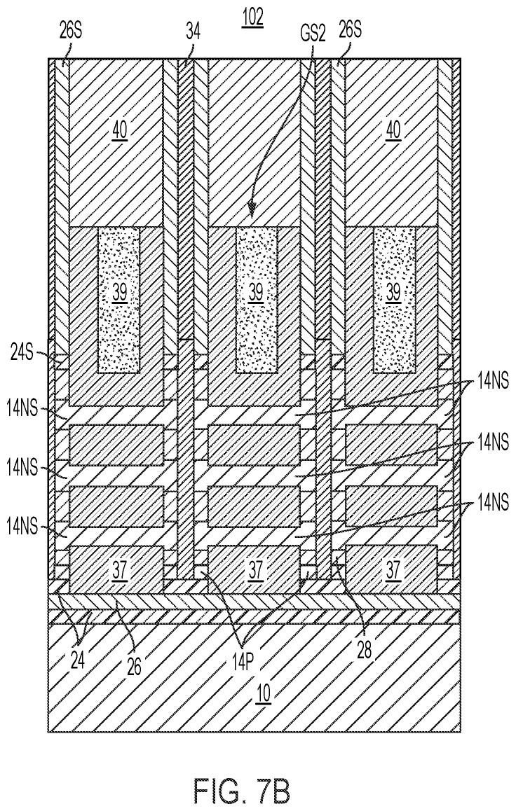

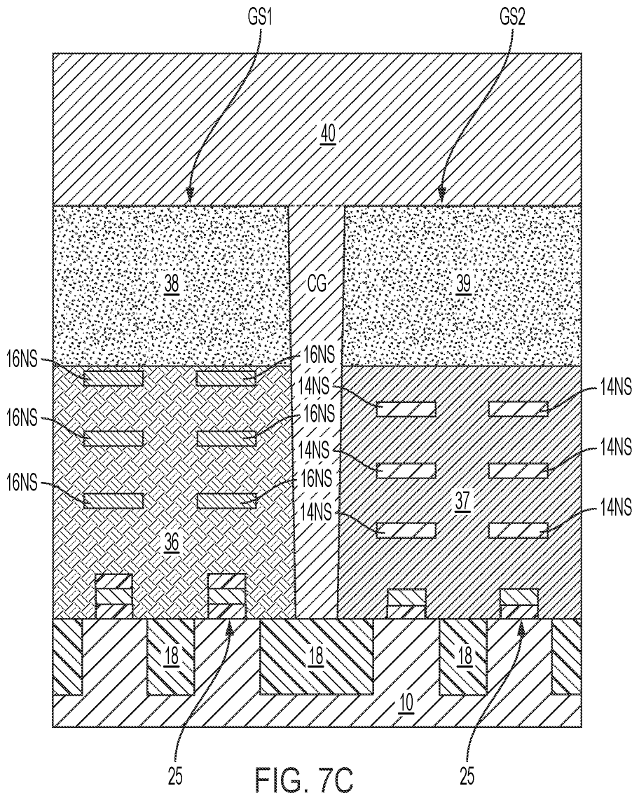

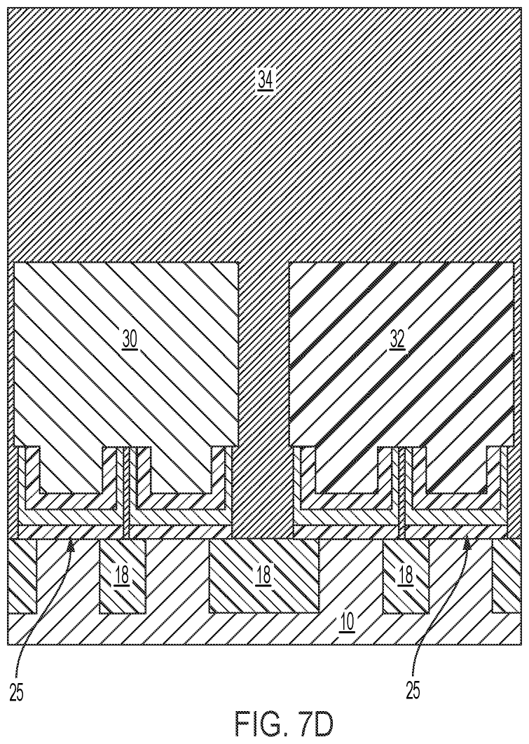

Referring now to FIGS. 7A, 7B, 7C and 7D, there are illustrated the exemplary structure shown in FIGS. 6A, 6B, 6C and 6D, respectively, after suspending each pFET semiconductor channel material nanosheet 16NS in each nanosheet-containing stack present in the pFET device region, and each nFET semiconductor channel material nanosheet 14NS in each nanosheet-containing stack present in the nFET device region, trimming each suspended pFET semiconductor channel material nanosheet 16NS and each suspended nFET semiconductor channel material nanosheet 14NS, removing the inner gate spacer 24S and forming a first functional gate structure GS1 in the pFET device region and a second functional gate structure GS2 in the nFET device region, and forming a gate cut region, GC, between the first functional gate structure GS1 and the second functional gate structure GS2. The trimming provides dumbbell shaped semiconductor channel material nanosheets, as depicted in FIGS. 7A and 7B, in which a middle section of each of the trimmed semiconductor channel material nanosheets is thinner than end portions of each nanosheet that is not subjected to thinning since they are protected by the inner spacers 28 and outer gate spacer 26S. Note that this step of the present application provides pFET semiconductor channel material nanosheet 16NS in in the pFET device region and nFET semiconductor channel material nanosheet 14NS in in the nFET device region that have a staggered, i.e., offset, relationship. Notably, the center of each pFET semiconductor channel material nanosheet 16NS is vertically offset from the center of each nFET semiconductor channel material nanosheet 14NS. Note that in the present application, the above processing is performed separately in each of the device regions. Thus, the pFET device region can be processed as described above (suspending each pFET semiconductor channel material nanosheet 16NS, removing the inner gate spacer 24S, trimming the suspended pFET channel material nanosheets 16NS) prior to, or after processing, the nFET device region as described above (suspending each nFET semiconductor channel material nanosheet 14NS, trimming the suspended nFET channel material nanosheets 14NS, removing the inner spacer 24S). Following, the first functional gate GS1 is formed in the pFET device region and the second functional gate structure GS2 is formed in the nFET device region. The removal of the inner spacer 24S prior to the trimming of the suspended pFET channel material nanosheets 16NS prevents removal of the top portion of the bottom dielectric isolation bilayer structure 25. Block mask technology can be used to process one of the device regions prior to processing the other. Note that the forming of the gate cut region, GC, is performed after processing both device regions.

Assuming processing of the pFET device region prior to processing the nFET device region, a block mask is formed over the nFET device region. Next, the inner gate spacer 24S is removed from the pFET device region utilizing a selective etching process that removes the inner gate spacer 24S. Note that a portion of the inner gate spacer 24S in the pFET device region and that this remaining portion is located between a portion of the outer gate spacer 26S and an end portion of the topmost pFET semiconductor channel material nanosheet 16NS. Next, each of the nFET semiconductor channel material nanosheets 14NS is removed suspending each pFET semiconductor channel material nanosheet 16NS. The removal of each of the nFET semiconductor channel material nanosheets 14NS is performed utilizing an isotropic etching process that is selective in removing the nFET semiconductor channel material nanosheets 14NS relative to the pFET semiconductor channel material nanosheets 16NS. Each suspended pFET semiconductor channel material nanosheet 16NS is then trimmed utilizing a trimming process such as, for example, repeated steps of oxidation and etching. Because the bottommost suspended pFET semiconductor channel material nanosheet 16NS is thinner than the other pFET semiconductor channel material nanosheets 16NS, this trimming steps removes the middle portion of the bottommost pFET semiconductor channel material nanosheet 16NS leaving behind only pFET semiconductor channel material nanosheet end portions 16P shown in FIG. 7A (each pFET semiconductor channel material nanosheet end portion 16P is sandwiched between two inner spacers 28). The entirety of each pFET semiconductor channel material nanosheet end portion 16P is located between the two sandwiching inner spacers 28 and the pFET semiconductor channel material nanosheet end portion 16P has an end wall that contacts GS1.

Next, the nFET device region is processed by removing the block mask that was previously formed over the nFET device region and forming a block mask in the previously processed pFET device region. Notably, and in the nFET device region, each of the pFET semiconductor channel material nanosheets 16NS is removed in the nFET device region suspending each nFET semiconductor channel material nanosheet 14NS. The removal of each of the pFET semiconductor channel material nanosheets 16NS is performed utilizing an isotropic etching process that is selective in removing the pFET semiconductor channel material nanosheets 16NS relative to the nFET semiconductor channel material nanosheets 14NS. Next, each suspended nFET semiconductor channel material nanosheet 14NS is trimmed utilizing a trimming process such as, for example, repeated steps of oxidation and etch. Note that the bottommost nFET semiconductor channel material nanosheet 14NS is not suspended. Because the bottommost nFET semiconductor channel material nanosheet 14NS is thinner than the other nFET semiconductor channel material nanosheets 16NS, this trimming steps removes the middle portion of the bottommost nFET semiconductor channel material nanosheet 14NS leaving behind only nFET semiconductor channel material nanosheet end portions 14P shown in FIG. 7B (each nFET semiconductor channel material nanosheet end portion 14P is located between a bottommost inner spacer 28 and the top first dielectric material layer 24 that provides the bottom dielectric isolation bilayer structure 25). The entirety of each nFET semiconductor channel material nanosheet end portion 14P is located beneath the bottommost inner spacer 28 and the nFET semiconductor channel material nanosheet end portion 14P has an end wall that contacts GS2. Next, the inner gate spacer 24S is removed from the nFET device region utilizing a selective isotropic etching process that removes the inner gate spacer 24S. During this removal step and since the top first dielectric material layer 24 of the bottom dielectric isolation bilayer structure 25 is physically exposed after the trimming step, the top first dielectric material layer 24 of the bottom dielectric isolation bilayer structure 25 is also removed to physically expose the second dielectric material layer 26 of the bottom dielectric isolation bilayer structure 25. Note that a portion of the inner gate spacer 24S in the nFET device region and that this remaining portion is located between a portion of the outer gate spacer 26S and a topmost inner spacer 28.

After processing both nFET device region, the block mask is removed from the pFET device region and GS1 and GS2 are formed. GS1 includes a first gate dielectric material not shown, a pFET work function metal layer 36, and a first gate electrode 38; in the present application the first gate dielectric material would wrap around the middle portion of each of the suspended pFET semiconductor channel material nanosheets 16NS and the pFET work function metal layer 36 would be located on the first gate dielectric material layer. In this embodiment, GS1 lands on a physically exposed portion of the topmost first dielectric material layer 24 of the bottom dielectric isolation bilayer structure 25 (See, FIG. 7A).

The first gate dielectric material is composed of a gate dielectric material such as, for example silicon oxide, or a dielectric material having a dielectric constant greater than 4.0 (such dielectric materials can be referred to as a high-k gate dielectric material). Illustrative examples of high-k gate dielectric materials include metal oxides such as, for example, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The high-k gate dielectric material can further include dopants such as lanthanum (La), aluminum (Al) and/or magnesium (Mg).

The pFET work function metal layer 36 can be used to set a threshold voltage of the pFET to a desired value. Notably, the pFET work function metal layer 36 can be selected to effectuate a p-type threshold voltage shift. In one embodiment, the work function of the pFET work function metal layer 36 ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof.

The first gate electrode 38 can include an electrically conductive metal-containing material including, but not limited to tungsten (W), titanium (Ti), tantalum (Ta), ruthenium (Ru), zirconium (Zr), cobalt (Co), copper (Cu), aluminum (Al), lead (Pb), platinum (Pt), tin (Sn), silver (Ag), or gold (Au), tantalum nitride (TaN), titanium nitride (TiN), tantalum carbide (TaC_{X}), titanium carbide (TiC), titanium aluminum carbide, tungsten silicide (WSi₂), tungsten nitride (WN), ruthenium oxide (RuO₂), cobalt silicide, or nickel silicide.

GS 2 includes a second gate dielectric material not shown, an nFET work function metal layer 37, and a second gate electrode 39; in the present application the second gate dielectric material would wrap around the middle portion of each of the suspended nFET semiconductor channel material nanosheets 14NS and the nFET work function metal layer 37 would be located on the second gate dielectric material layer. The second gate dielectric material layer includes one of the gate dielectric materials mentioned above for the first gate dielectric material layer. The gate dielectric material that provides the second gate dielectric material layer can be compositionally the same as, or compositionally different from, the gate dielectric material that provides the first gate dielectric material layer. In this embodiment, GS2 extends beneath the topmost surface of the bottom dielectric isolation bilayer structure 25; GS2 lands on the physically exposed second dielectric material layer 26 of the bottom dielectric isolation bilayer structure 25 (See, FIG. 7B).

The nFET work function metal layer 37 can be used to set a threshold voltage of the nFET to a desired value. Notably, the nFET work function metal layer 37 can be selected to effectuate an n-type threshold voltage shift N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof.

The second gate electrode 39 can include one of the electrically conductive metal-containing materials mentioned above for the first gate electrode 38. The electrically conductive metal-containing material that provides the second gate electrode 39 can be compositionally the same as, or compositionally different from, the electrically conductive metal-containing material that provides the first gate electrode 38.

GS1 can be formed by deposition of the gate dielectric material layer, the pFET work function metal layer 36 and the first gate electrode 36, followed by a planarization process. GS2 can be formed utilizing the same technique as GC1 above. In some embodiments, GS1 and GS2 can be formed by first forming the gate dielectric material layer in both the pFET device region and the nFET device region. Next, the pFET work function metal layer 36 and the nFET work function metal layer 37 are formed in the appropriate device region, and thereafter the gate electrode material is formed in the different device regions.

After processing both the pFET device region and the nFET device region to include GS1, and GS2, respectively, a recess etch can be used to reduce the height of GS1 and GS2, a gate cut can be performed (via gate cut lithography and etching) to provide gate cut region GC and thereafter a dielectric material layer 40 is formed on top of the recessed GS1 and recessed GS2 and within the gate cut region GC. The dielectric material layer 40 can include any dielectric material such as, for example, one of the ILD dielectric materials mentioned above, silicon nitride or silicon oxynitride.

In embodiments of the present application, the bottom dielectric isolation structure 25 in a gate region of the nFET has a first thickness, and the bottom dielectric isolation structure in a source/drain region of the nFET has a second thickness that differs from the first thickness.

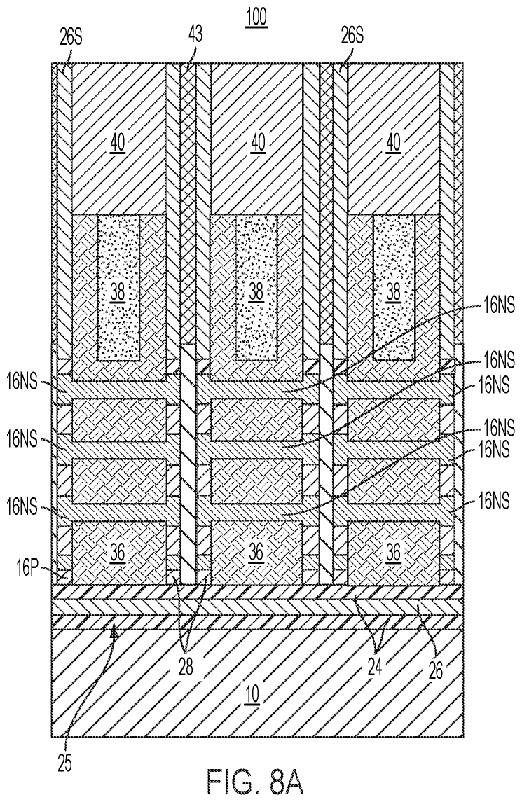

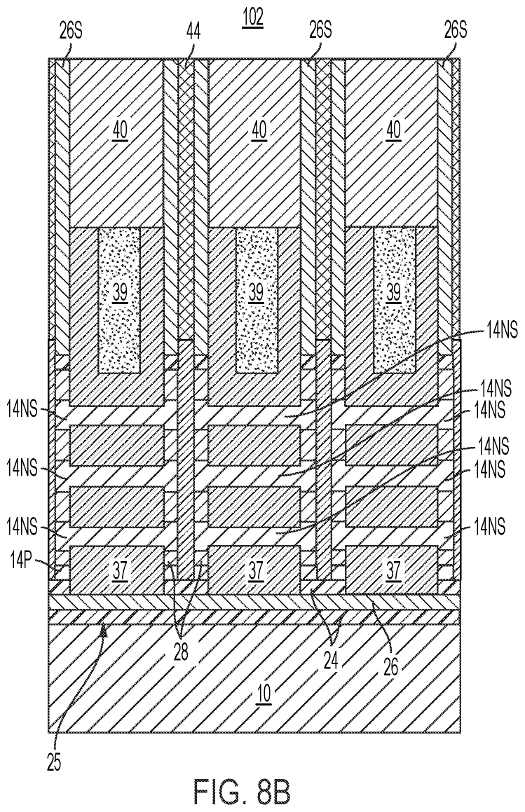

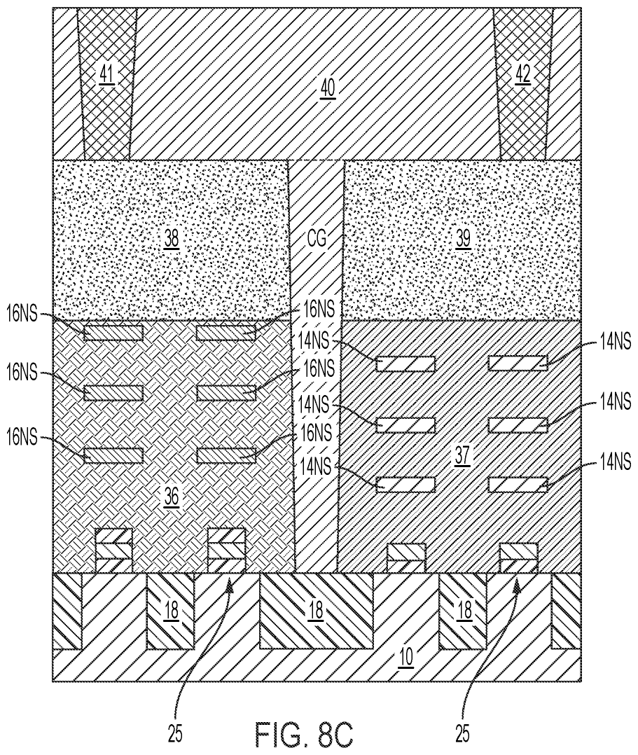

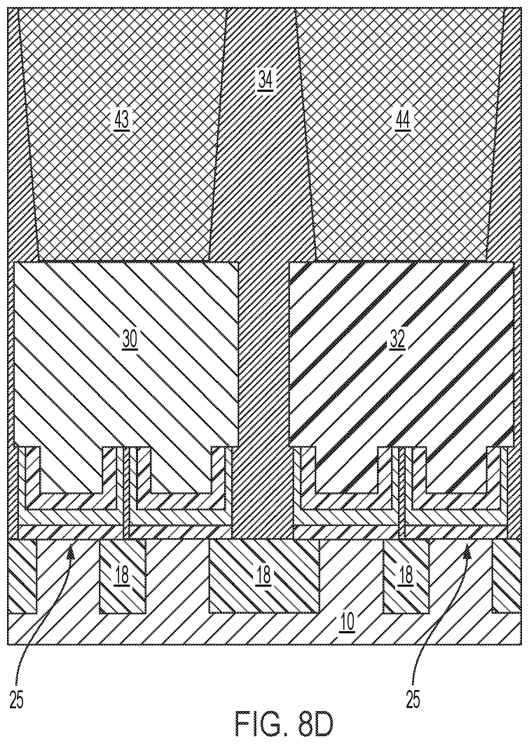

Referring now to FIGS. 8A, 8B, 8C and 8D, there are illustrated the exemplary structure shown in FIGS. 7A, 7B, 7C and 7D, respectively, after forming gate contact structures 41, 42 and source/drain contact structures 43, 44 in both the pFET device region and the nFET device region. In the present application, the gate contact structure that contacts GS1 is referred to as a first gate contact structure 41, the gate contact structure that contacts GS2 is referred to as a second gate contact structure 42, the source/drain structure that contacts the first source/drain region 30 is referred to as a first source/drain contact structure 43, and the source/drain contact structure that contacts the second source/drain region 32 is referred to as a second source/drain contact structure 44.

The gate contact structures 41, 42 and the source/drain contact structures 43, 44 include at least a contact conductor material such as, for example, W, Cu, Al, Co, Ru, Mo, Os, Ir, Rh or an alloy thereof. In embodiments, gate contact structures 41, 42 and the source/drain contact structures 43, 44 can also include a silicide liner such as TiSi, NiSi, NiPtSi, etc., and an adhesion metal liner, such as TiN. Each gate contact structures 41, 42 and the source/drain contact structures 43, 44 can be formed by forming a contact opening in the dielectric material layer 40 and the ILD material 34 by lithography and etching. The contact conductor material can be formed in the contact openings by any suitable deposition method such as, for example, ALD, CVD, PVD or plating. In some embodiments (not shown), a metal semiconductor alloy region can be formed in each of the contact openings prior to forming the contact conductor material. The metal semiconductor alloy region can be composed of a silicide or germicide. In one or more embodiments of the present application, the metal semiconductor alloy region can be formed by first depositing a metal layer (not shown) in the trenches. The metal layer can include a metal such as Ni, Co, Pt, W, Ti, Ta, a rare earth metal (e.g., Er, Yt, La), an alloy thereof, or any combination thereof. The metal layer can be deposited by ALD, CVD, PVD or ALD. The thickness of the metal layer can be from 2 nm to 10 nm, although lesser and greater thicknesses can also be employed. A diffusion barrier (not shown) such as, for example, TiN or TaN, can then be formed over the metal layer. An anneal process can be subsequently performed at an elevated temperature to induce reaction of the semiconductor material of the source/drain regions to provide the metal semiconductor alloy region. The unreacted portion of the metal layer, and, if present, the diffusion barrier, are then removed, for example, by an etch process (or a plurality of etching processes). In one embodiment, the etching process can be a wet etch that removes the metal in the metal layer selective to the metal semiconductor alloy in the metal semiconductor alloy regions. Each gate contact structure 41, 42 and each source/drain contact structure 43, 44 can further include one or more source/drain contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. The contact liner can be formed utilizing a conformal deposition process including CVD or ALD. The contact liner that is formed can have a thickness ranging from 1 nm to 5 nm, although lesser and greater thicknesses can also be employed.

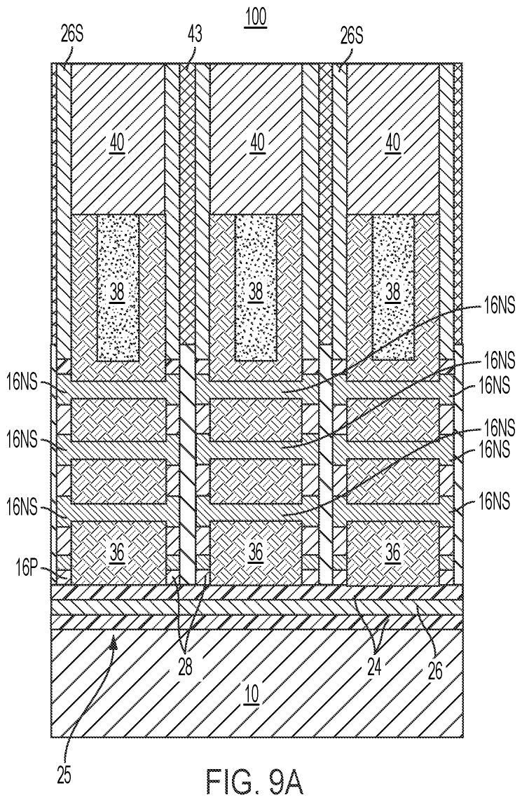

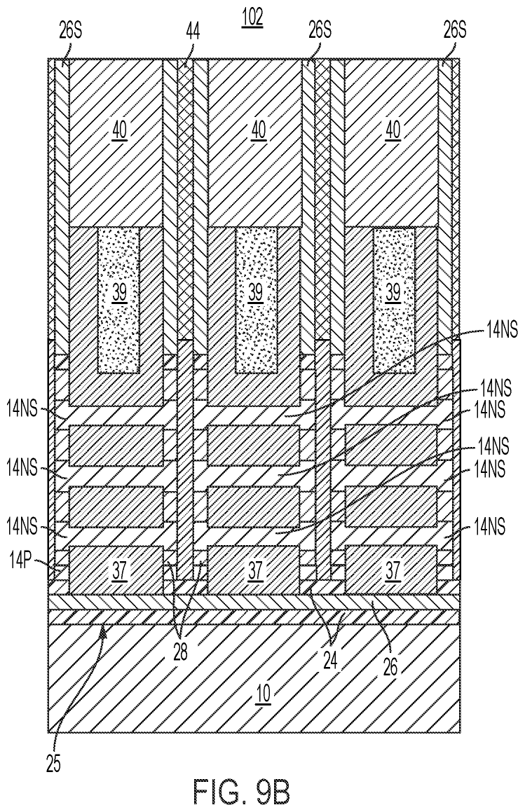

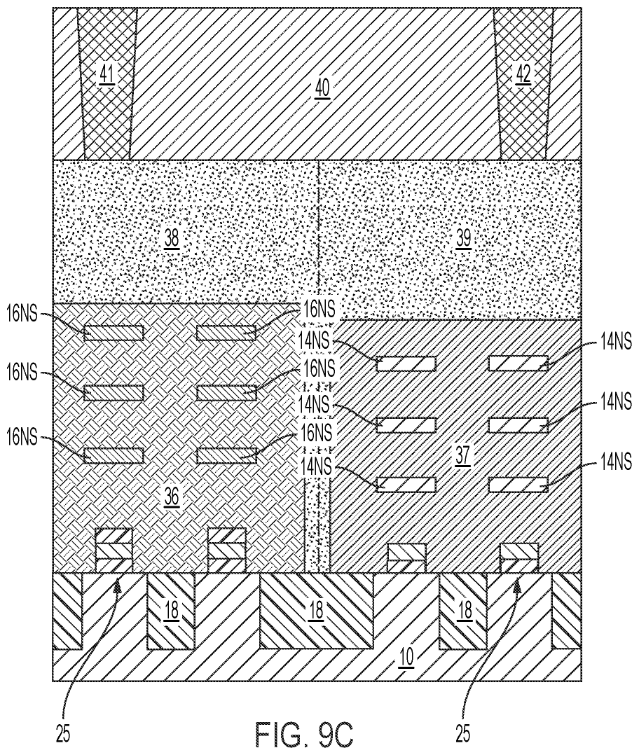

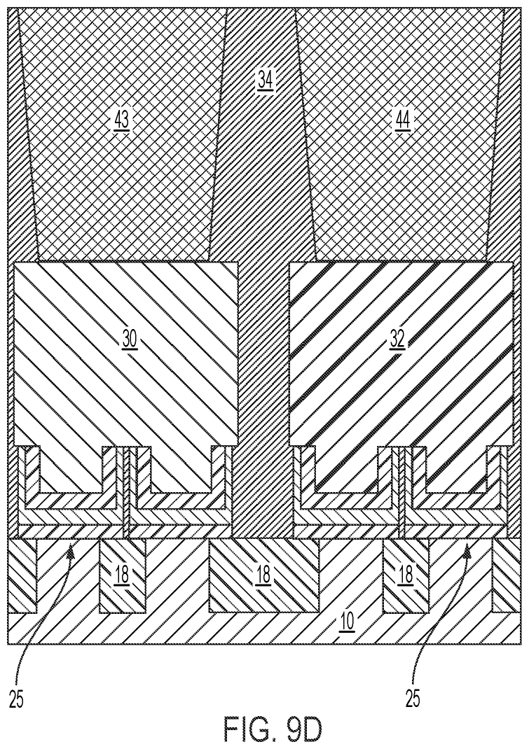

Referring now to FIGS. 9A, 9B, 9C and 9D, there are illustrated another exemplary structure that can be formed utilizing the processing as mentioned in providing the structure shown in FIGS. 8A, 8B, 8C, and 8D, but without forming the gate cut region; in this embodiment the first functional gate structure GS1 and the second functional gate structure GS2 have a shared gate electrode; notably the first gate electrode 38 and the second gate electrode 39 are not physically separated from each other. In FIG. 9C, a dotted line is illustrated to denote a hypothetic boundary (i.e., interface) between the first and second electrodes 38, 39. This boundary would not exist if the first and second gate electrodes are composed of a same gate electrode material, e.g., W.

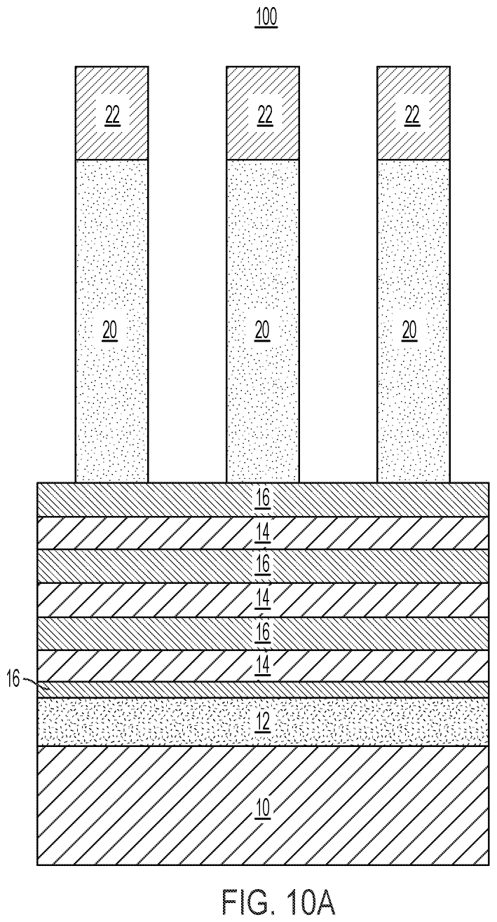

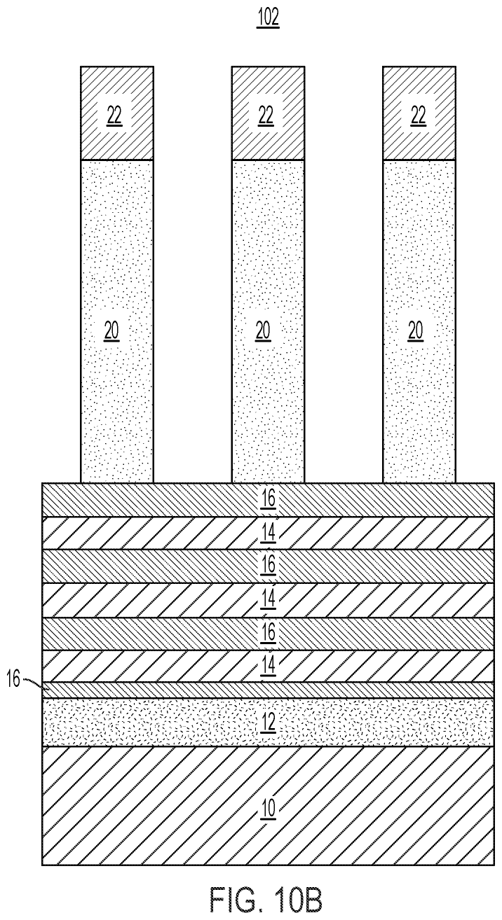

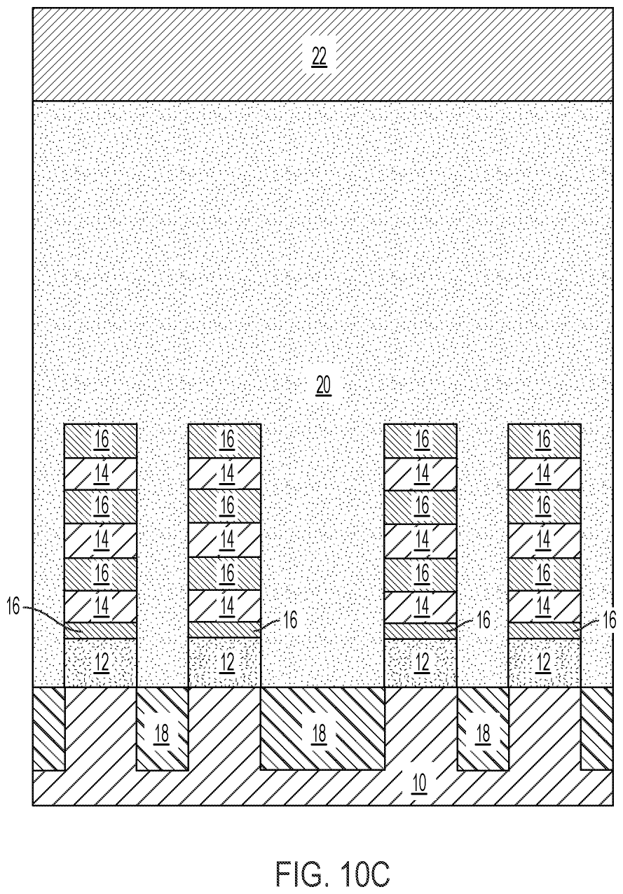

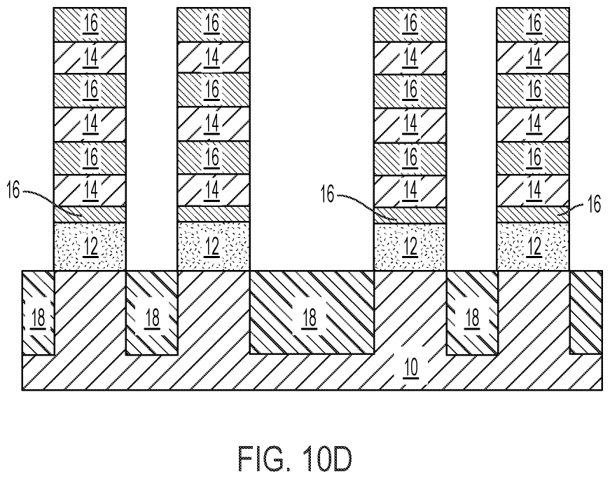

Referring now to another embodiment of the present application which begins by providing the exemplary structure that is shown in FIGS. 10A, 10B, 10C and 10D. This exemplary structure includes semiconductor substrate 10 having a pFET device region 100 and an nFET device region 102, placeholder material layer 12, a plurality of patterned material stacks of alternating pFET semiconductor channel material layers 16 and nFET semiconductor channel material layers 14 stacked one on top of the other, and a plurality of sacrificial gate structures 20 located on a surface of each patterned material stack, wherein a bottommost pFET semiconductor channel material layer 16 of each patterned material stack is a sacrificial layer. Hard mask cap 22 can be present on top of each of the sacrificial gate structures 20. The elements/components of the exemplary structure shown in FIGS. 10A, 10B, 10C and 10D are the same as those described above for the exemplary structure shown in FIGS. 2A, 2B, 2C and 2D. In this embodiment, the patterned material stack however differs from the patterned material stack shown in FIGS. 2A, 2B, 2C and 2D in that the patterned material stack of this embodiment includes pFET semiconductor channel material layers 16 and nFET semiconductor channel material layer 14 stacked one on top of the other, while in the previously exemplary structure the patterned material stack included nFET semiconductor channel material layers 14 and pFET semiconductor channel material layer 16 stacked one on top of the other In the exemplary structure illustrated in FIGS. 10A, 10B, 10C and 10D, the material stack includes ‘n+1’ pFET semiconductor channel material layers 16 and ‘n’ nFET semiconductor material layers 14, wherein n is an integer starting from one, such that each nFET semiconductor channel material layer 14 is sandwiched between a top and bottom pFET semiconductor channel material layer 16. Also note that in the patterned material stack of this embodiment, only the bottommost pFET semiconductor channel material layer 16 is sacrificial, while in the previous patterned material stack shown in FIGS. 2A, 2B, 2C and 2D, the bottommost nFET and pFET semiconductor channel material layers were both sacrificial. In addition to including materials used in the previously described patterned material stack, the patterned material stack of this embodiment of the present application can be formed utilizing the technique mentioned above in forming the patterned material stack shown in FIGS. 2A, 2B, 2C and 2D.

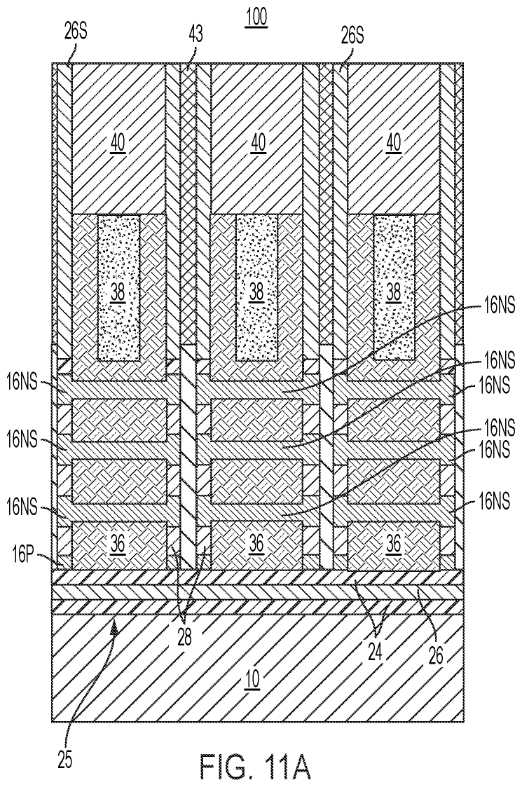

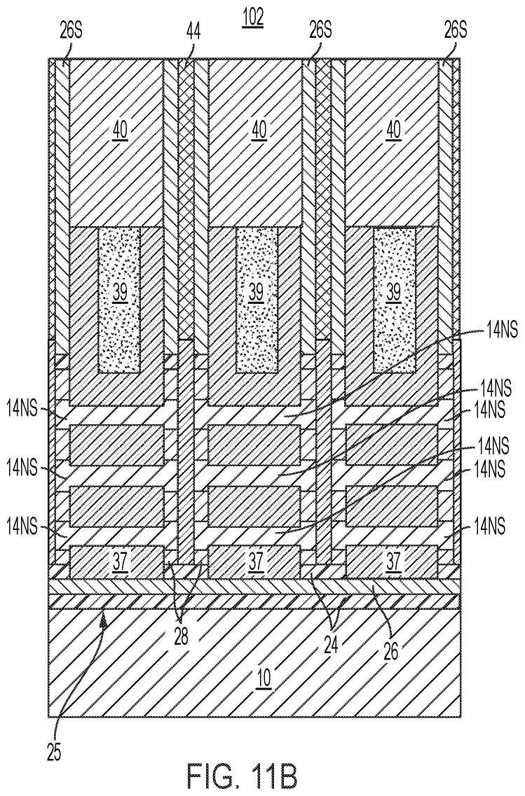

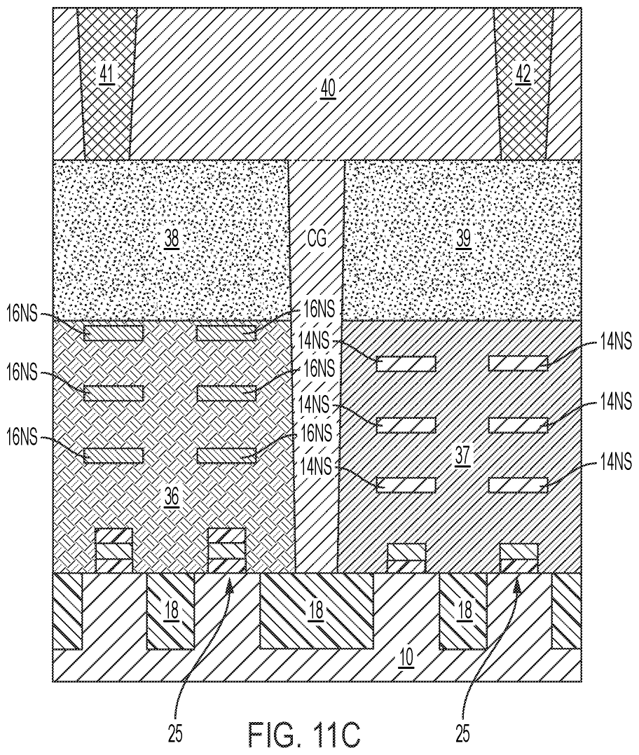

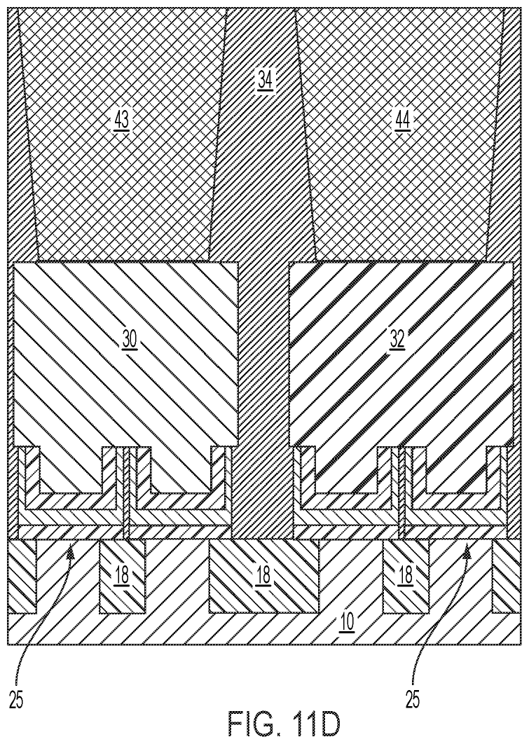

Referring now to FIGS. 11A, 11B, 11C and 11D, there are illustrated the exemplary structure shown in FIGS. 10A, 10B, 10C and 10D, respectively, after performing various processing steps in accordance with the present application. The various processing steps used in this embodiment of the present application have been described above with respect to FIGS. 3A-8D and can be derived therefrom. It is noted that the structure shown in FIGS. 11A, 11B, 11C and 11D is similar to the structure illustrated in FIGS. 8A, 8B, 8C and 8D except that the structure shown in FIGS. 11A, 11B, 11C and 11D lacks the nFET semiconductor channel material nanosheet end portion 14P in the nFET device region (Compare FIG. 11B with FIG. 8B).

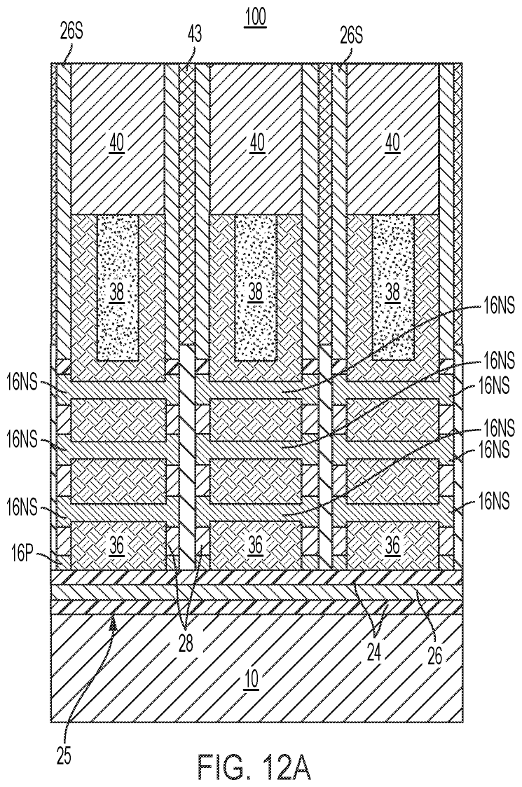

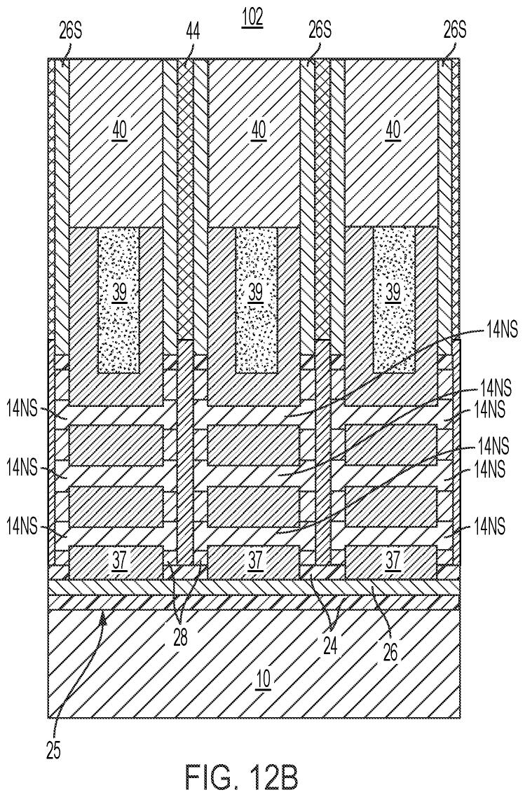

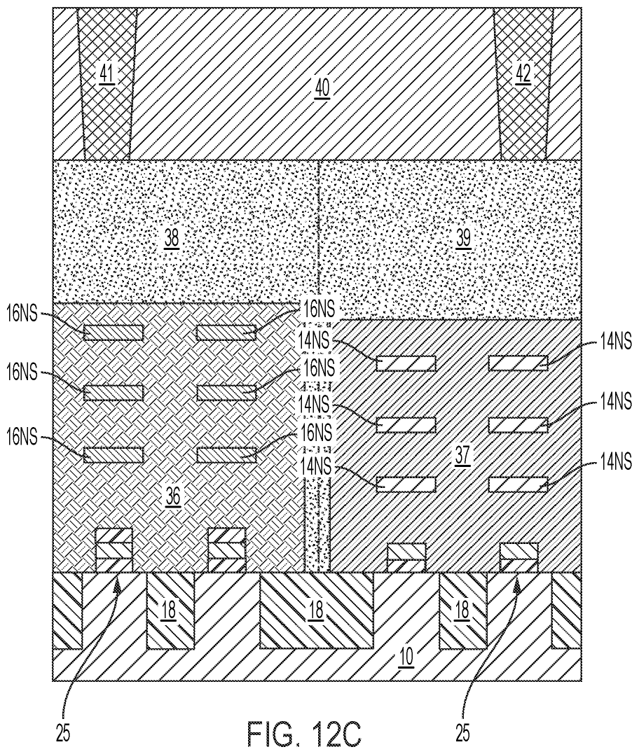

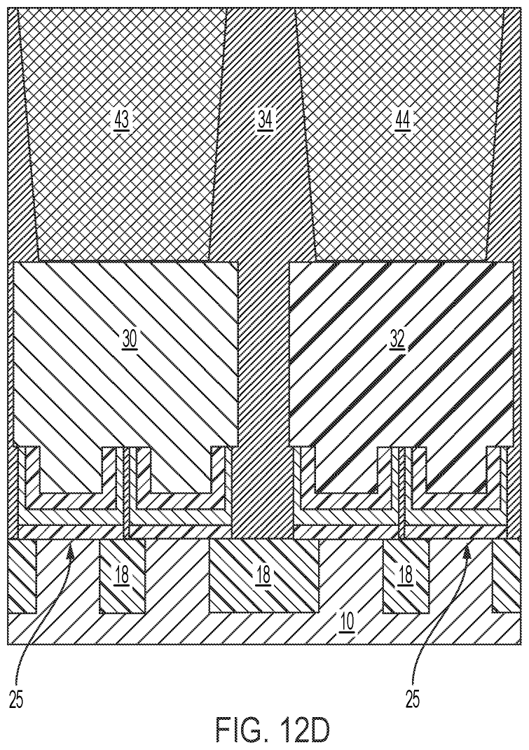

Referring now to FIGS. 12A, 12B, 12C and 12D, there are illustrated the exemplary structure shown in FIGS. 10A, 10B, 10C and 10D, respectively, after performing various processing steps in accordance with the present application. The various processing steps used in this embodiment of the present application have been described above with respect to FIGS. 3A-7D and 9A-9D and can be derived therefrom. It is noted that the structure shown in FIGS. 12A, 12B, 12C and 12D is similar to the structure illustrated in FIGS. 9A, 9B, 9C and 9D except that the illustrated structure lacks the nFET semiconductor channel material nanosheet end portion 14P in the nFET device region (Compare FIG. 12B with FIG. 9B).

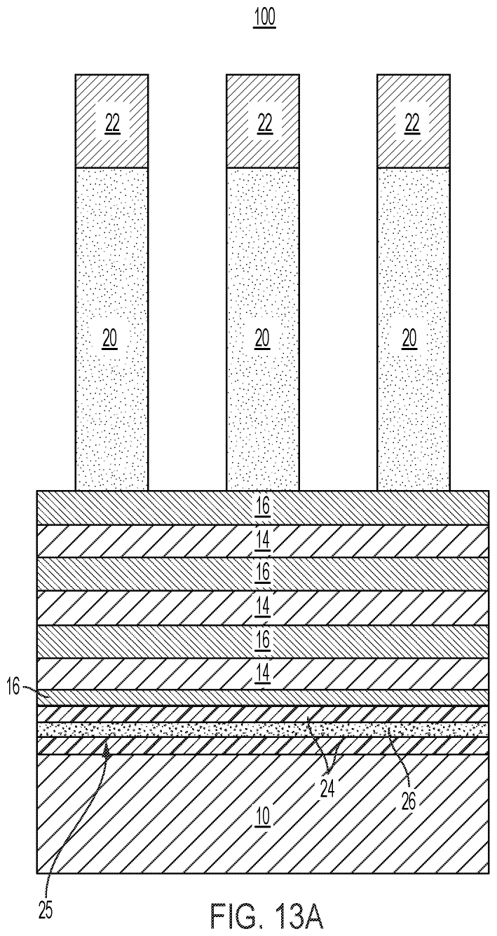

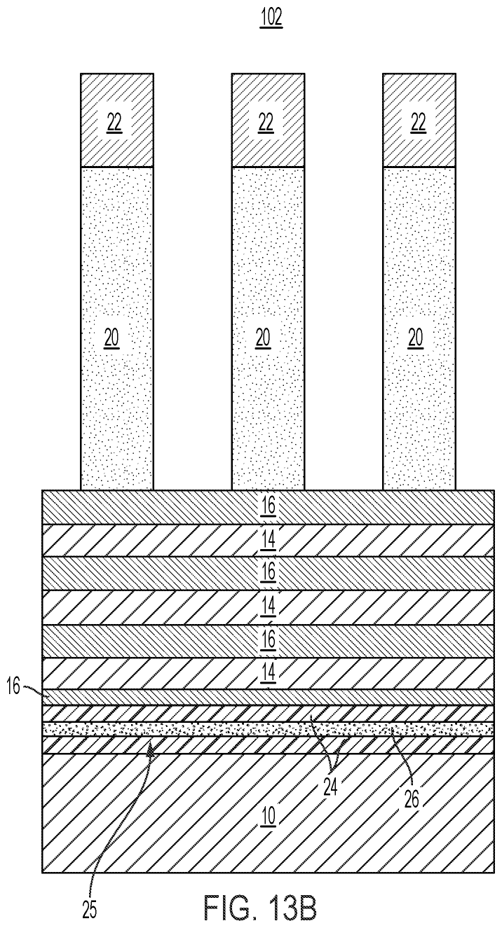

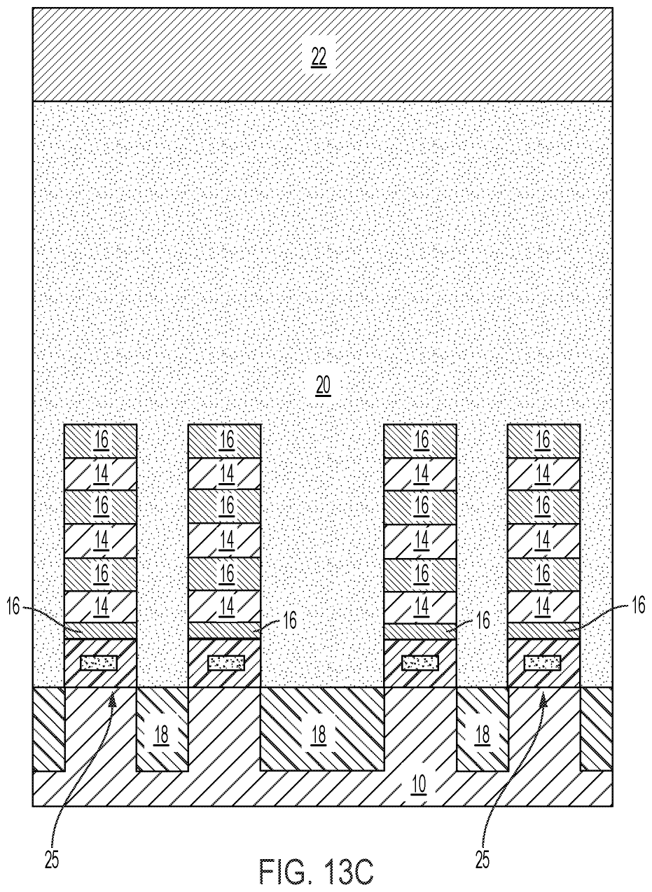

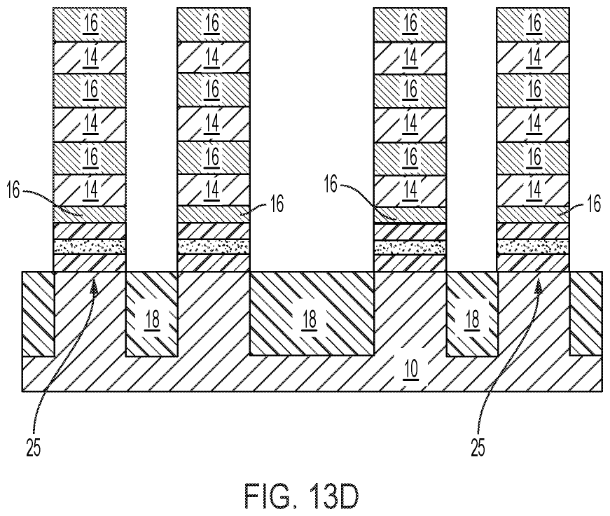

Referring now to FIGS. 13A, 13B, 13C and 13D (which represent another embodiment), there is illustrated the exemplary structure shown in FIGS. 10A, 10B, 10C and 10D, respectively, after replacing the placeholder material layer 12 with a bottom dielectric isolation bilayer structure 25 including a second dielectric material layer 24 sandwiched between top and bottom first dielectric material layers 24. The replacing of the placeholder material layer 12 includes an etch that is selective in removing the placeholder material layer 12. A gap is formed by this selective etch. A bilayer dielectric material structure 24/26, as described above, is then formed on physically exposed surfaces of the structure and within the volume previously occupied by the placeholder material layer 12. An etch is then used to remove the bilayer dielectric material structure 24/26 that is formed outside of the gap.

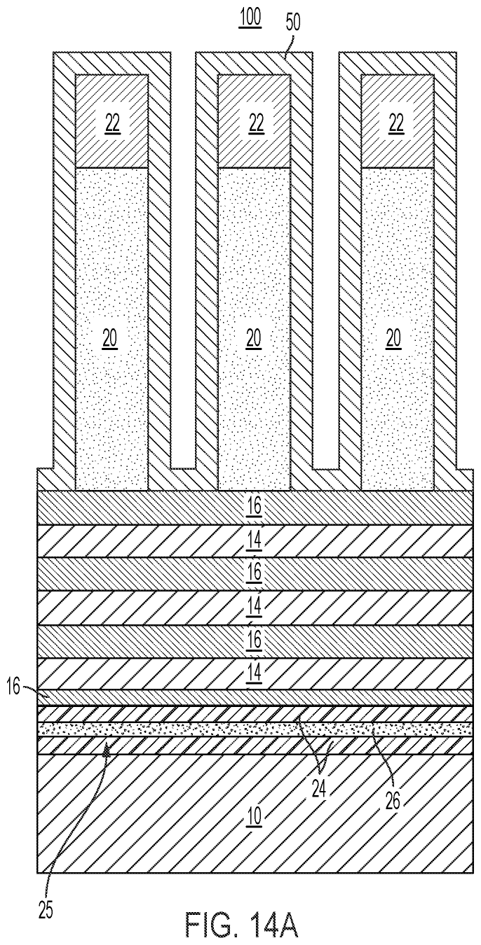

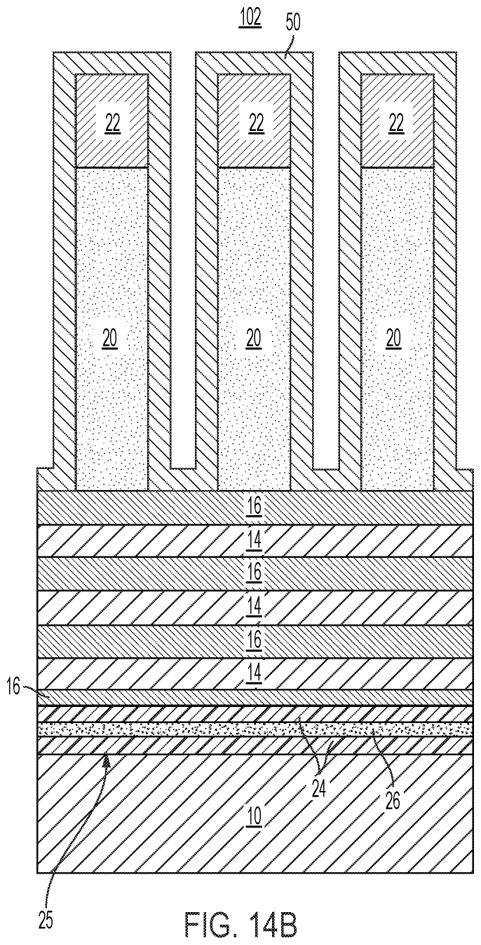

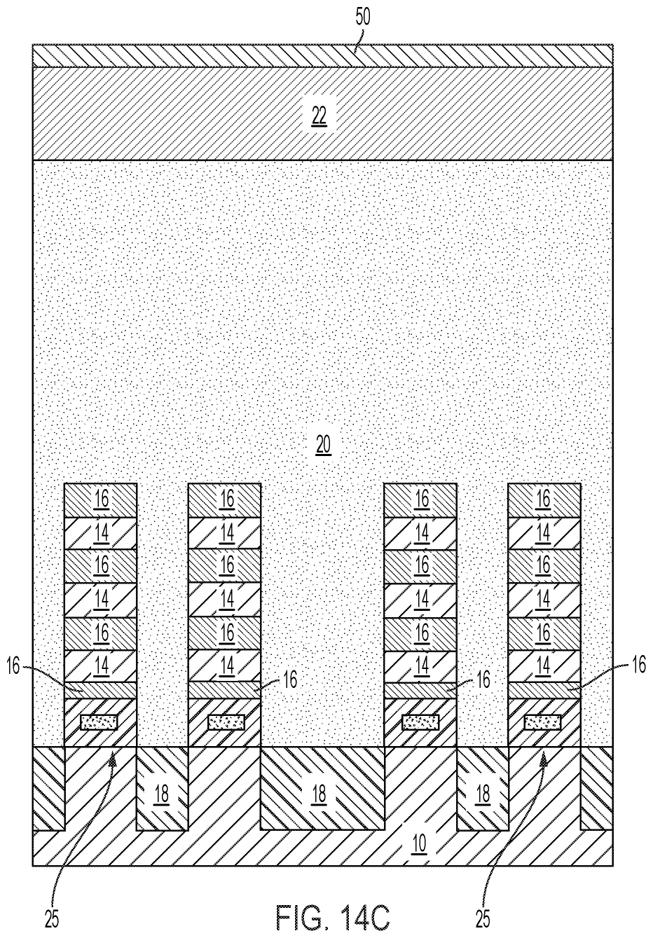

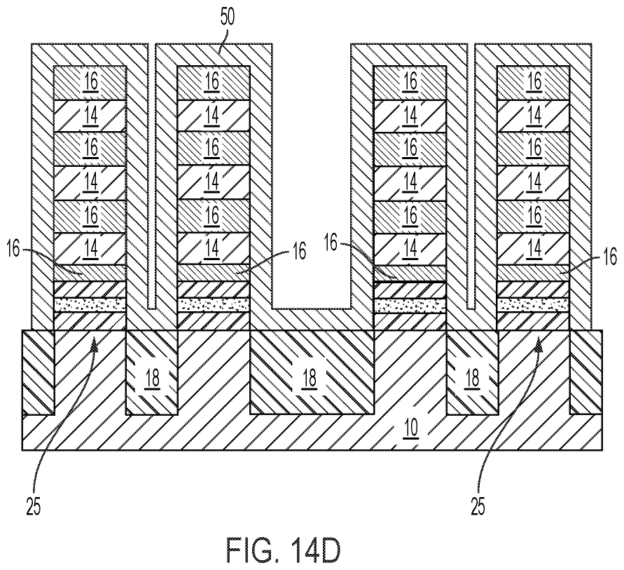

Referring now to FIGS. 14A, 14B, 14C and 14D, there are illustrated the exemplary structure shown in FIGS. 13A, 13B, 13C and 13D, respectively, after forming a gate dielectric spacer layer 50. Gate dielectric spacer layer 50 is composed of a gate spacer dielectric material; the gate spacer dielectric material that provides gate dielectric spacer layer 50 is compositionally different from the dielectric material that provides the first dielectric material layer 24. Examples of gate spacer dielectric materials that can be used in providing the gate dielectric spacer layer 50 include, but are not limited to, SiN, SiBCN, SiOCN or SiOC. The gate dielectric spacer layer 50 can be formed by a deposition process such as, for example, CVD, PECVD, or ALD.

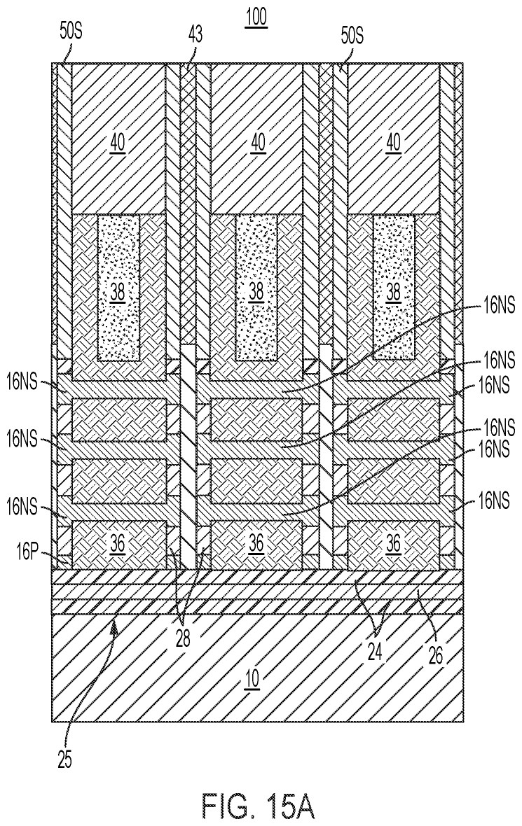

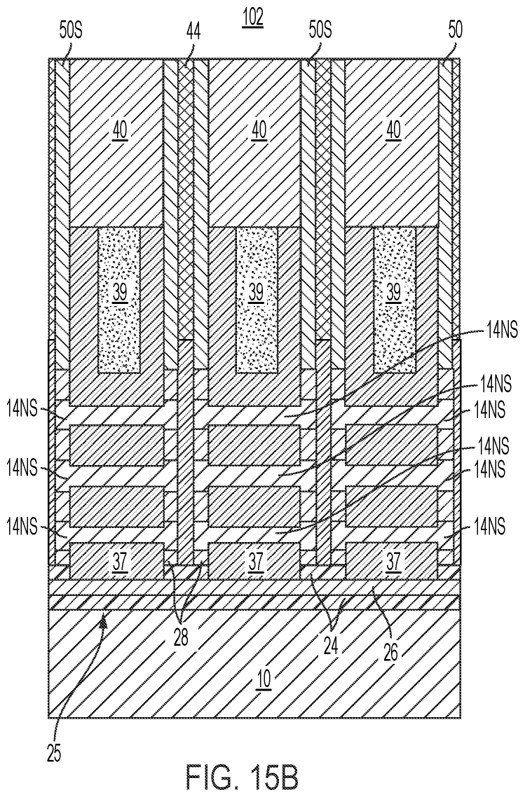

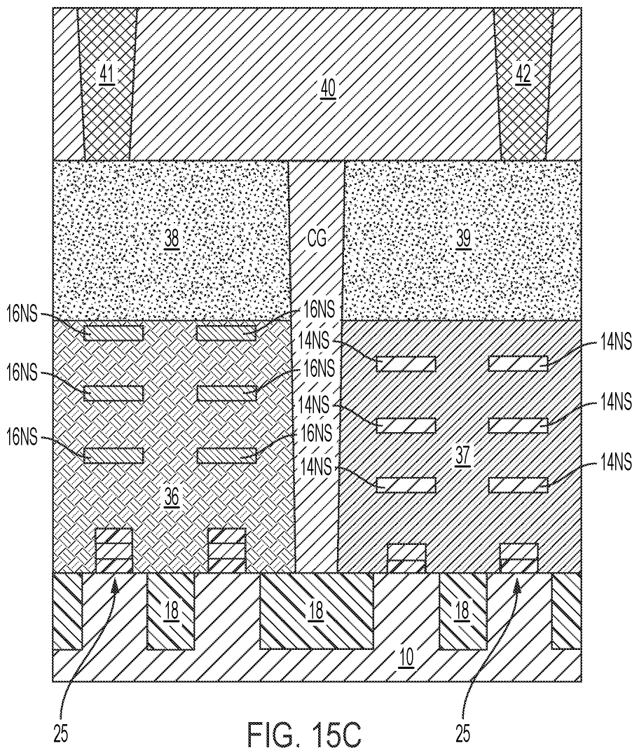

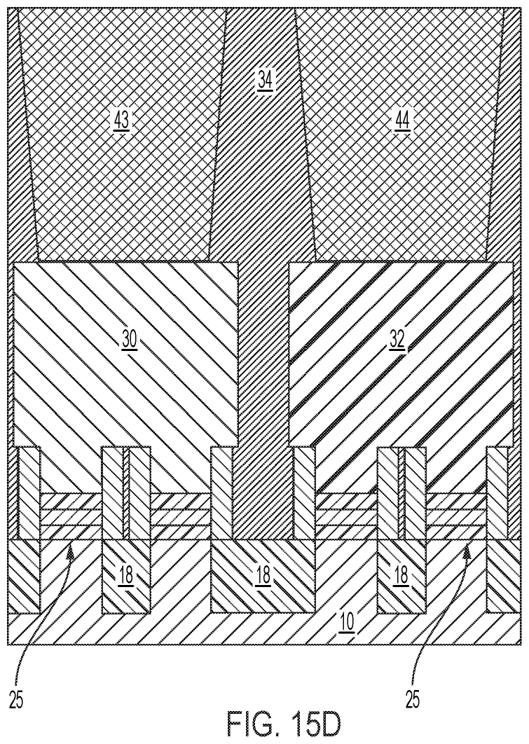

Referring to FIGS. 15A, 15B, 15C and 15D, there is illustrated the exemplary structure shown in FIGS. 14A, 14B, 14C and 14D, respectively, after performing various processing steps in accordance with the present application. The various processing steps used in this embodiment of the present application have been described above with respect to FIGS. 3A-8D and can be derived therefrom. It is noted that the structure shown in FIGS. 15A-15D is similar to the structure illustrated in FIGS. 8A-8D except that the structure shown in FIGS. 14A, 14B, 14C and 14D the gate dielectric spacers 50 are present instead of outer gate spacer 26S and that within the source/drain cross section (FIG. 15D), the gate dielectric spacers 50 is located laterally adjacent to the bottom dielectric isolation bilayer structure 25. Also note that no FET semiconductor channel material nanosheet end portion 14P is present in the nFET device region (Compare FIG. 15B with FIG. 8B). It should be noted that although a gate cut region is depicted, the present application contemplates an embodiment in which the shared gate electrodes (as defined above) are obtained from the structure shown in FIGS. 14A, 14B, 14C and 14D.

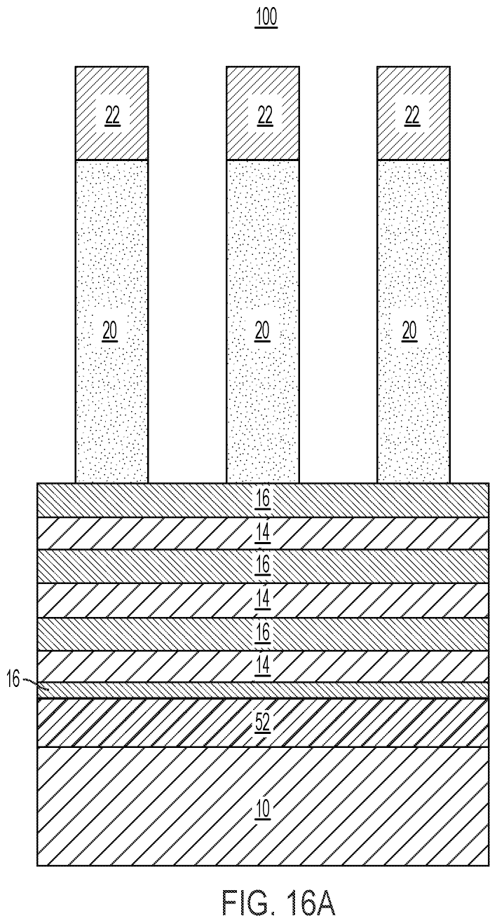

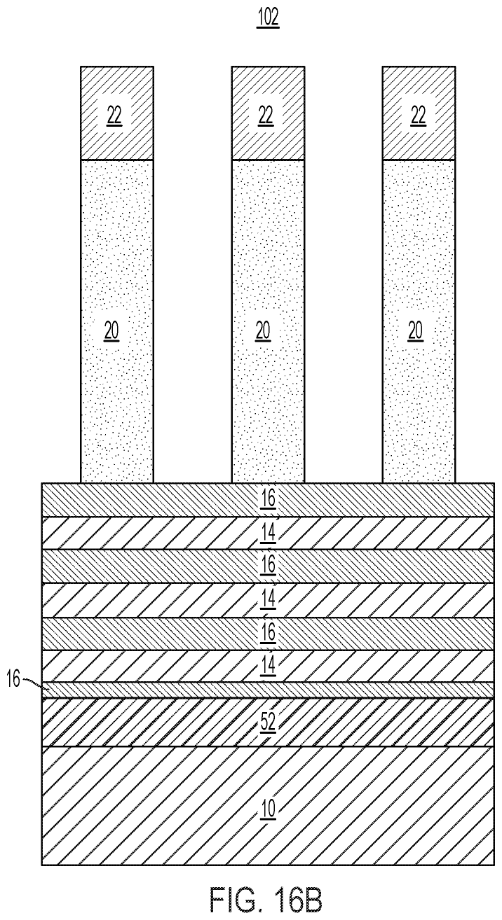

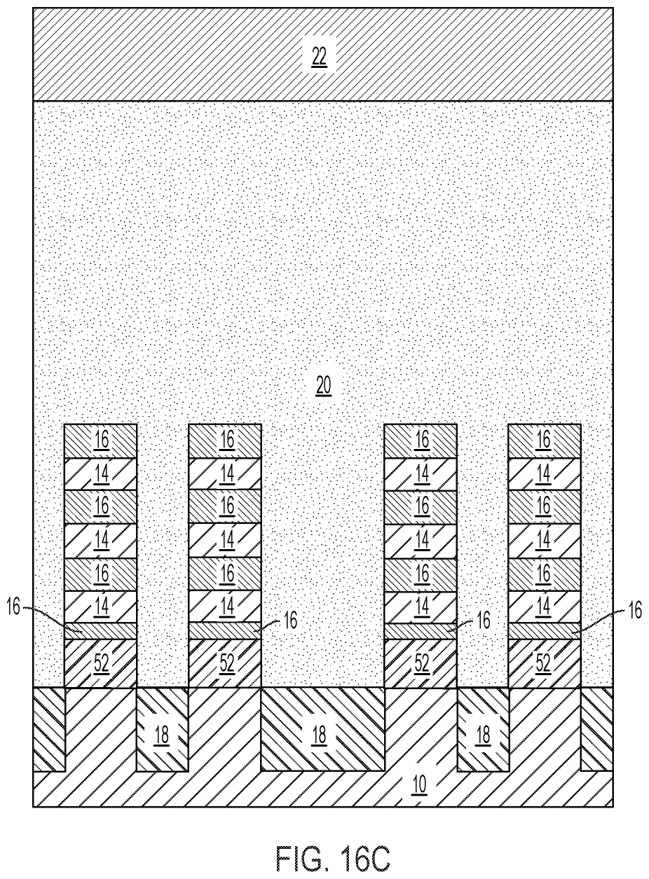

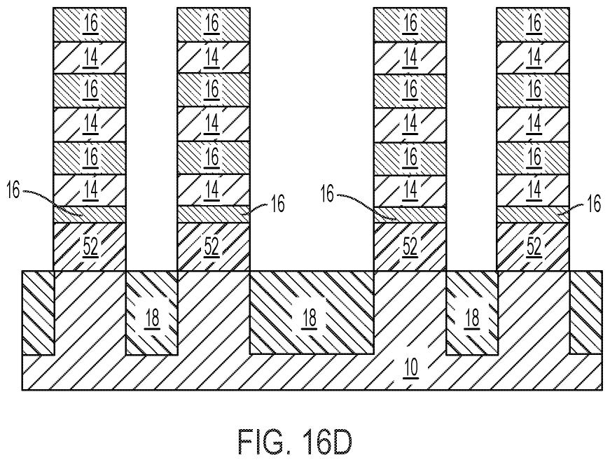

Referring now FIGS. 16A, 16B, 16C and 16D, there are illustrated another exemplary structure that can be employed in the present application. This exemplary structure includes semiconductor substrate 10 having a pFET device region 100 and an nFET device region 102, a bottom dielectric isolation structure 52, a plurality of patterned material stacks of alternating pFET semiconductor channel material layers 16 and an nFET semiconductor channel material layers 14 stacked one on top of the other, wherein a bottommost pFET semiconductor channel material layer 16 of each patterned material stack is a sacrificial layer, and a plurality of sacrificial gate structures 20 located on a surface of each patterned material stack. A hard mask cap 22 can be located on each sacrificial gate structure 20.

The exemplary structure illustrated in FIGS. 16A, 16B, 16C and 16D can be formed by first providing the exemplary structure shown in FIGS. 10A, 10B, 10C and 10D. Next, the placeholder dielectric material layer in FIGS. 10A-10D is replaced with a bottom dielectric isolation structure 52; bottom dielectric isolation structure 52 is a single layered structure. The replacing of the placeholder material layer 12 includes an etch that is selective in removing the placeholder material layer 12. A gap is formed by this selective etch. A bottom dielectric isolation material layer is then formed on physically exposed surfaces of the structure and within the volume previously occupied by the placeholder material layer 12. An etch is then used to remove the bottom dielectric isolation material layer that is formed outside of the gap. The bottom dielectric isolation material layer is composed of a dielectric material such as, for example, SiN, SiBCN, SiON, SiOCN or SiOC.

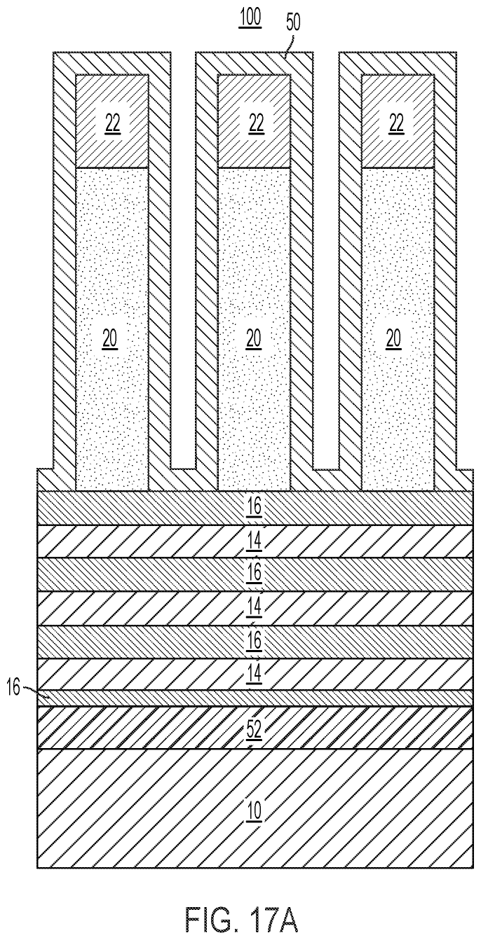

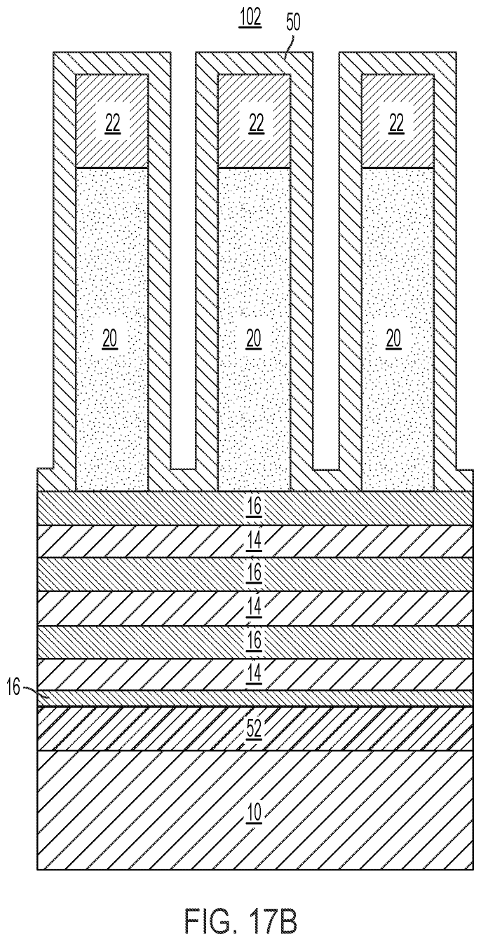

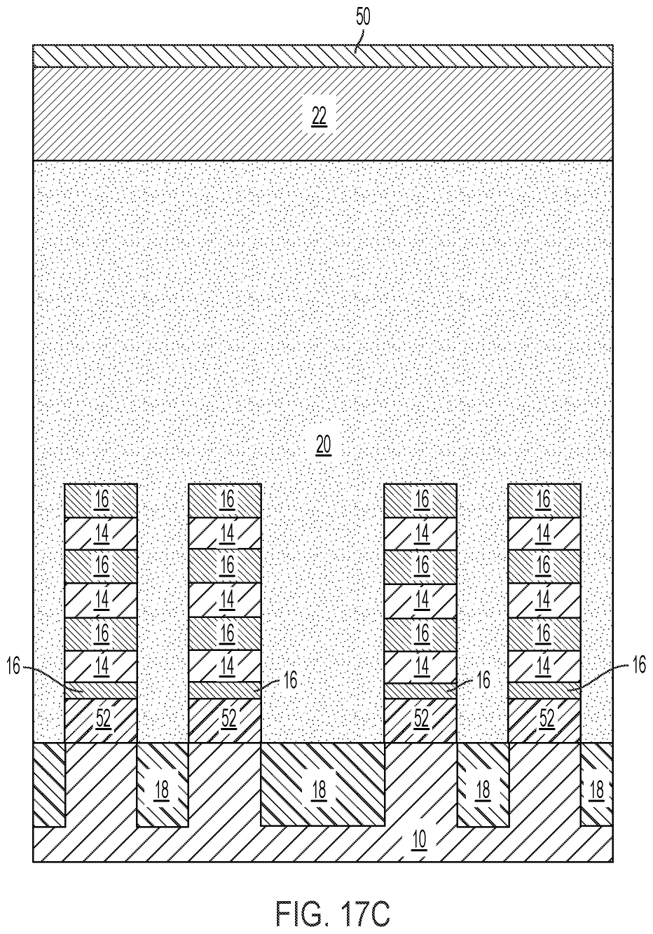

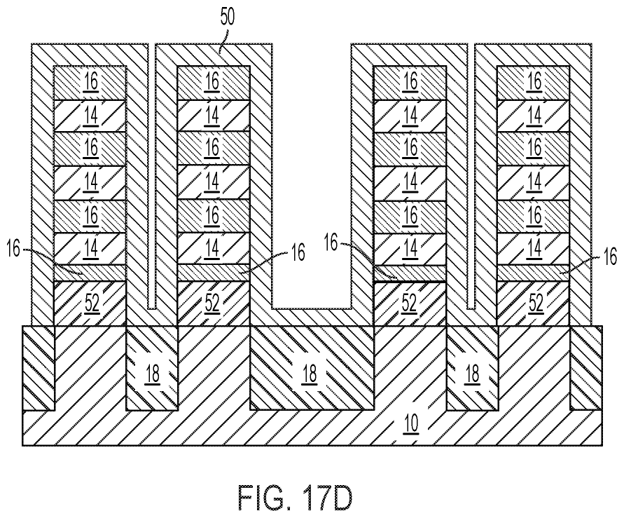

Referring now to FIGS. 17A, 17B, 17C and 17D, there are illustrated the exemplary structure shown in FIGS. 16A, 16B, 16C and 16D, respectively, after forming a gate dielectric spacer layer 50. The gate dielectric spacer layer 50 of this embodiment is the same as in one of the previous embodiments of the present application. Thus, the materials mentioned above for the gate dielectric spacer layer 50, as well as the technique used in forming the same, apply here for this embodiment of the present application.

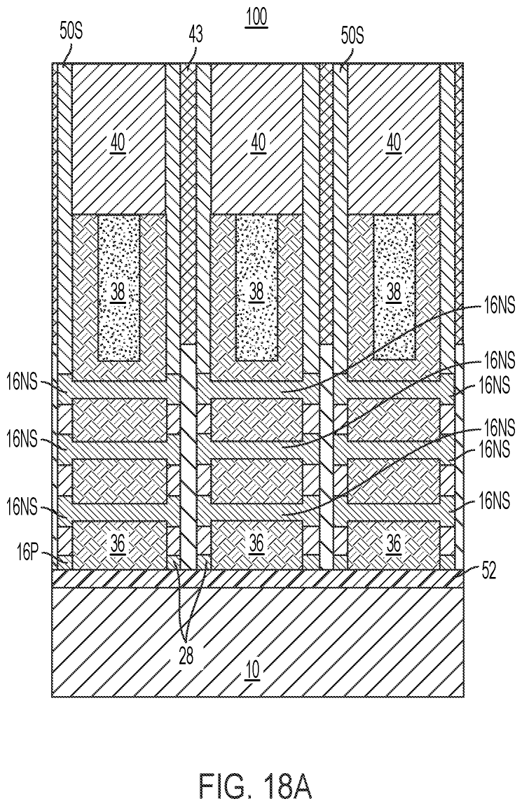

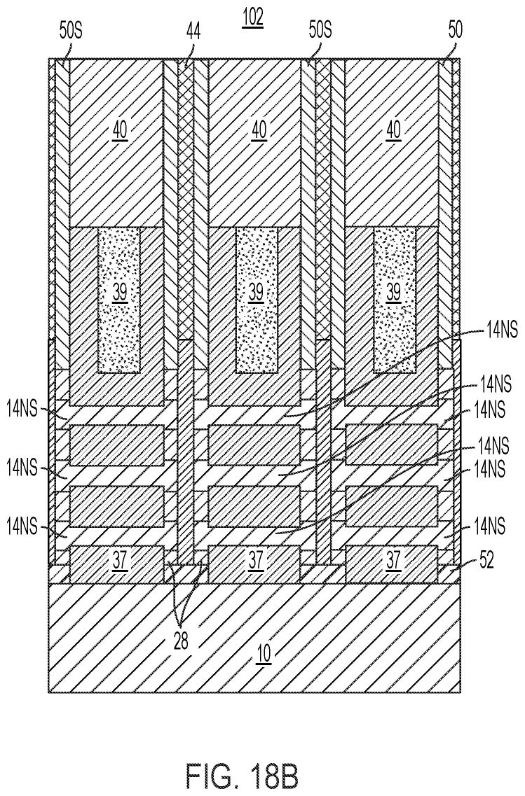

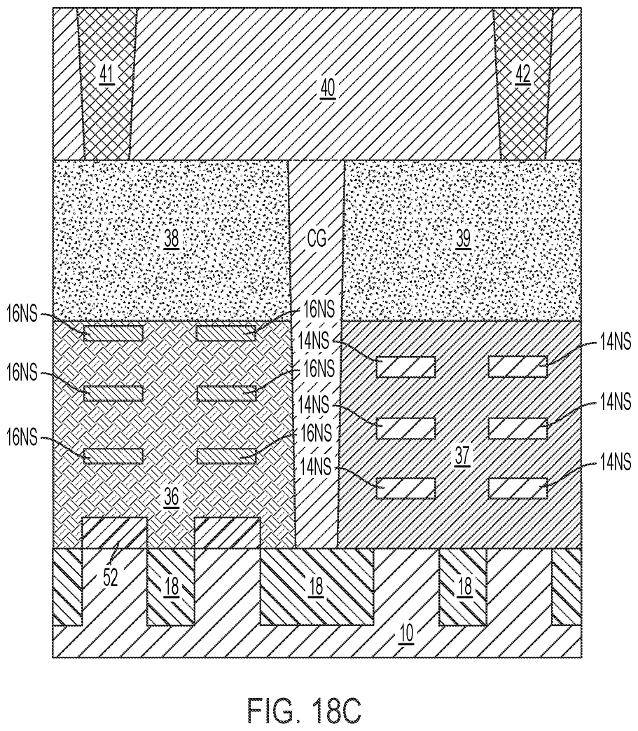

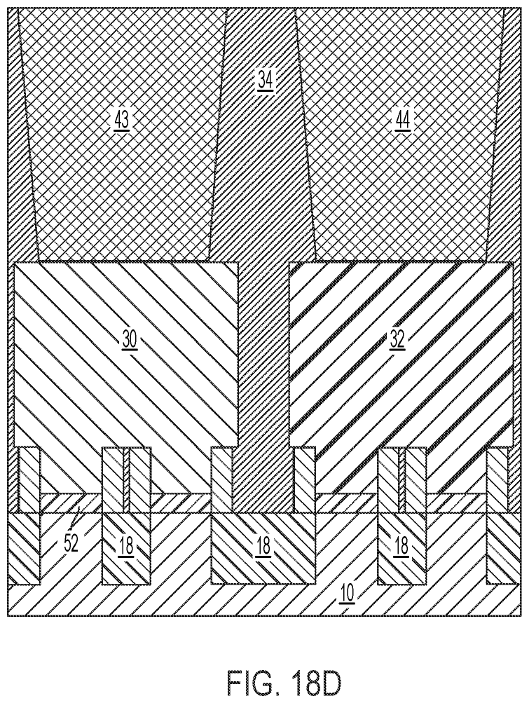

Referring now to FIGS. 18A, 18B, 18C and 18D, there are illustrated the exemplary structure shown in FIGS. 17A, 17B, 17C and 17D, respectively, after performing various processing steps in accordance with the present application. The various processing steps used in this embodiment of the present application have been described above with respect to FIGS. 3A-8D and can be derived therefrom. Note that in this embodiment a portion of the bottom dielectric isolation structure 52 is removed from the nFET device region such that GS2 lands on a surface of semiconductor substrate 10. It is noted that this embodiment can be modified to include a shared gate electrode rather than the gate cut region.

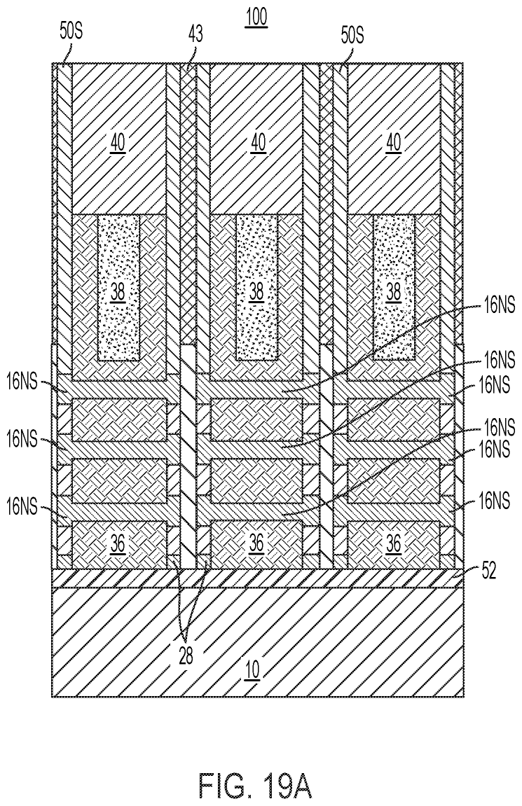

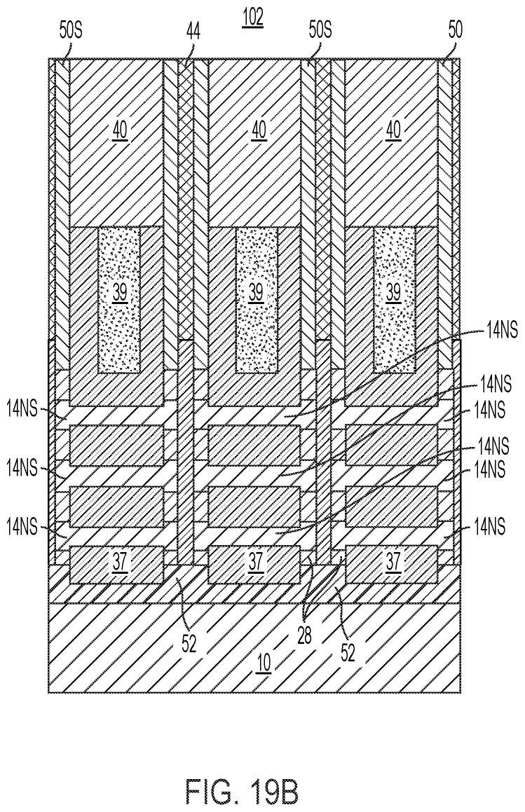

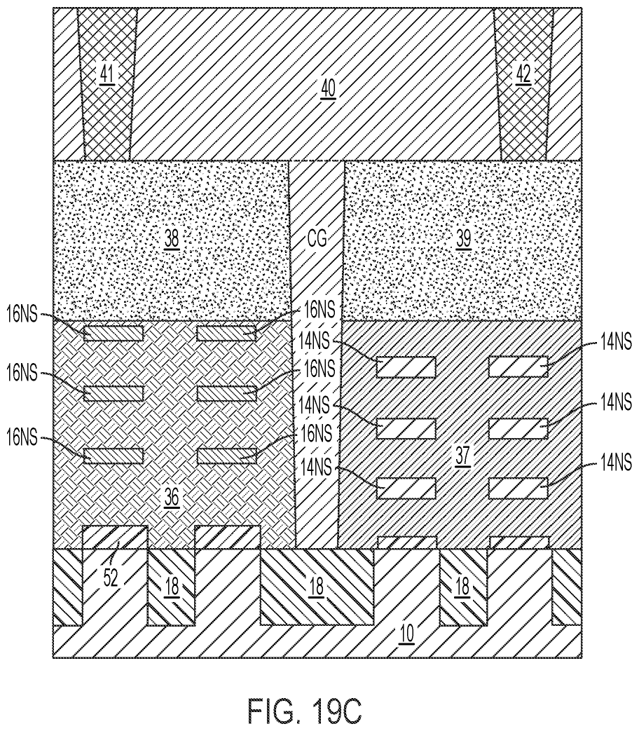

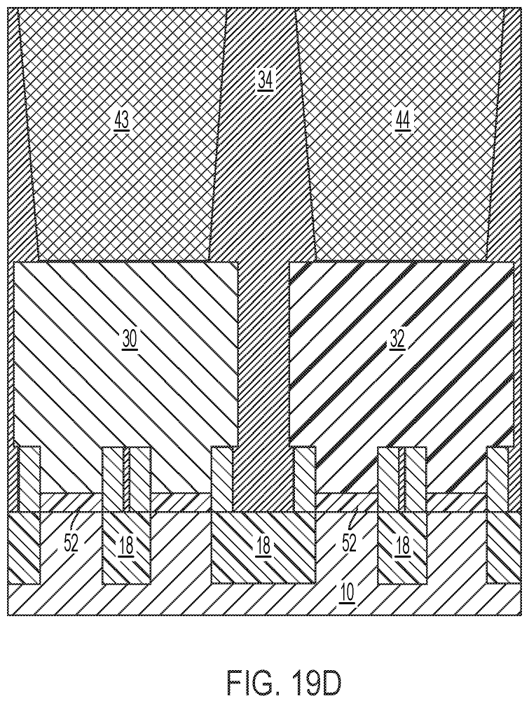

Referring now to FIGS. 19A, 19B, 19C and 19D, there are illustrated the exemplary structure shown in FIGS. 17A, 17B, 17C and 17D, respectively, after performing various processing steps in accordance with the present application. The various processing steps used in this embodiment of the present application have been described above with respect to FIGS. 3A-8D and can be derived therefrom. Note that in this embodiment a portion of the bottom dielectric isolation structure 52 is recessed in the nFET device region such that GS2 lands on a recessed surface of the bottom dielectric isolation structure 52. It is noted that this embodiment can be modified to include a shared gate electrode rather than the gate cut region.

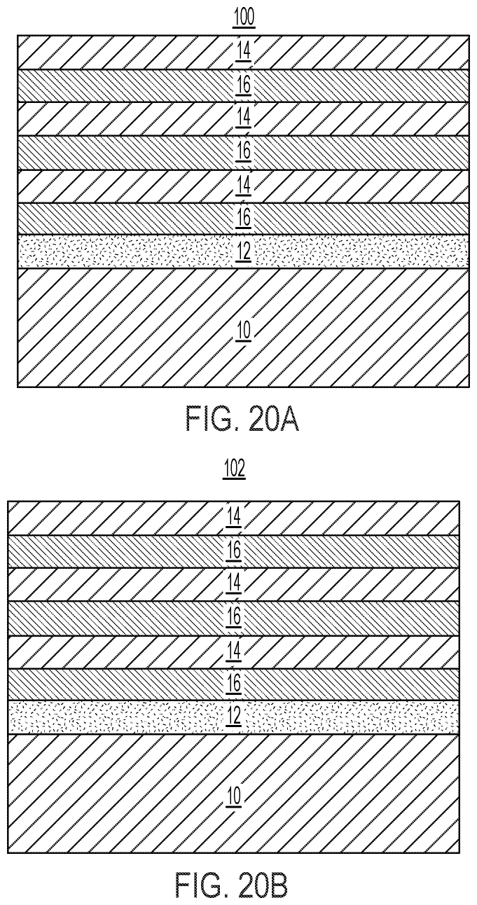

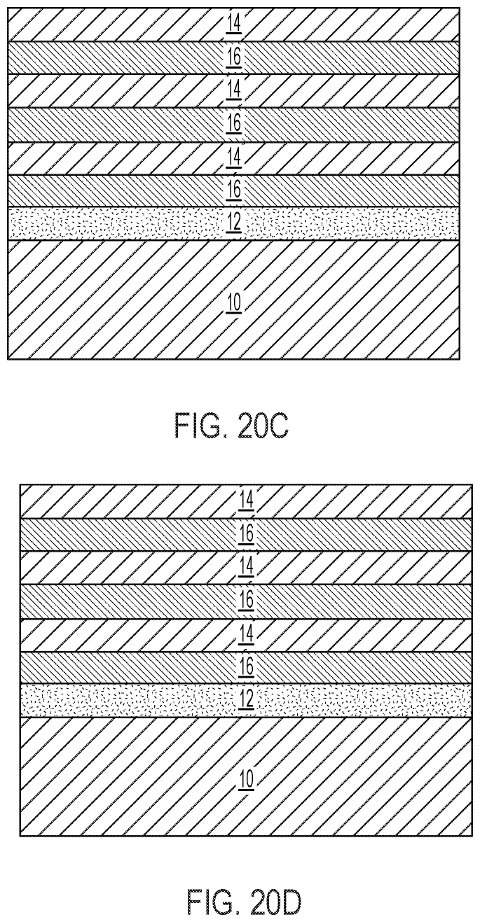

Reference is now made to the remaining drawings, i.e., FIGS. 20A-30D, which illustrate a semiconductor structure in accordance with another embodiment of the present application. Notably, and in this embodiment, a semiconductor structure is provided that includes a pFET located in a pFET device region, the pFET includes a first functional gate structure and a plurality of pFET semiconductor channel material nanosheets, and an nFET located in the nFET device region, the nFET includes a second functional gate structure and a plurality of pFET semiconductor channel material nanosheets. The pFET semiconductor channel material nanosheets are vertically aligned in a horizontal direction with the nFET semiconductor channel material nanosheets. In this embodiment, a vertical dielectric pillar is located between the two device regions. The vertical dielectric pillar is continuous in the gate region and in the area including the source/drain regions of both device the pFET and the nFET. The sourer/drain regions of the pFET and nFET can directly contact the vertical dielectric pillar, or they can be separated from the vertical dielectric pillar by a gate dielectric spacer.

Referring now to FIGS. 20A, 20B, 20C and 20D, there are illustrated an exemplary structure that can be employed in the present application, the exemplary structure includes semiconductor substrate 10 having a pFET device region 100 and an nFET device region 102, placeholder dielectric material layer 12, and a first material stack of alternating pFET semiconductor channel material layers 16 and nFET semiconductor channel material layers 14. This exemplary structure can be derived from the processing steps mentioned above in forming the material stack that was used in providing the patterned material stack illustrated in FIGS. 2A-2D, above.

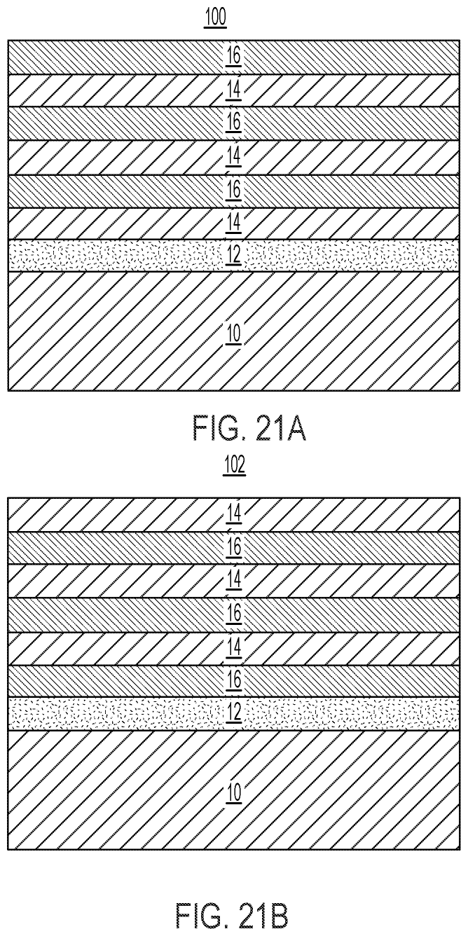

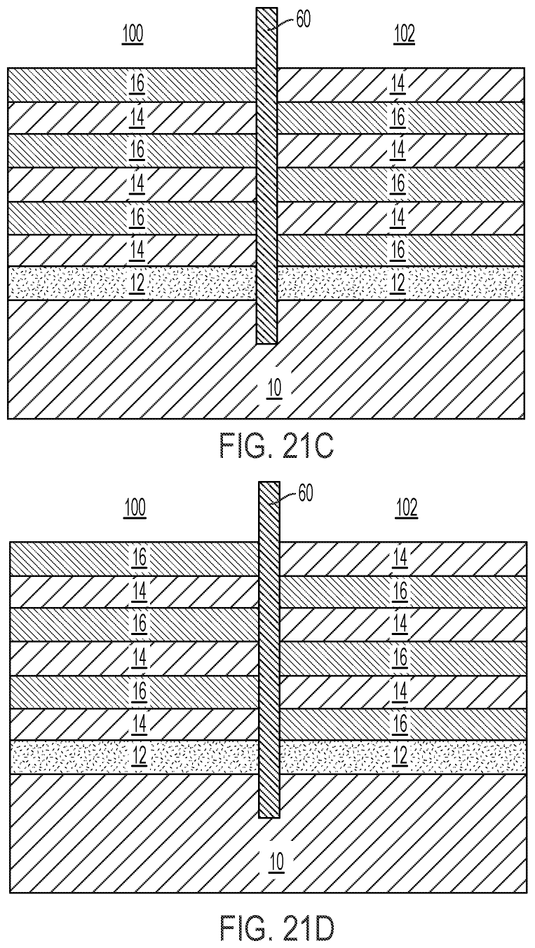

Referring now to FIGS. 21A, 21B, 21C and 21D, there are illustrated the exemplary structure shown in FIGS. 20A, 20B, 20C and 20D, respectively, after processing the pFET device region by removing the first material stack and forming a second material stack of alternating nFET semiconductor channel material layers 14 and pFET semiconductor material layers 16, wherein the first and second material stacks are separated by a vertical dielectric material pillar 60. This exemplary structure can be formed by first forming a block mask over the nFET device region. Then, and with the block mask in place, the first material stack and the placeholder material layer 12 are etch; note that this etch can also remove an upper portion of the semiconductor substrate 10. The etch can include a single etch or more than one etch can be used. The etch can include, for example, a reactive ion etch, selective wet etch, or a combination of both. The vertical dielectric material pillar 60 is then formed by conformal deposition of a dielectric material layer, followed by a directional etch removing the dielectric from horizontal surfaces. Epitaxial growth or another like deposition process is then used to reform any portion of the semiconductor substrate 10 that was previously removed as well as the placeholder material layer 12 and the second material stack in the pFET device region. The dielectric material that provides the vertical dielectric pillar 60 includes a low k dielectric material as defined above, including but not limited to, SiOC, SiON, SiOCN, SiCN, SiBCN, or SiC, Next, the block mask is removed providing the structure shown in FIGS. 21A-21D; note that the vertical dielectric material pillar 60 extends above the topmost surface of both the first and second material stacks. In this embodiment, the first material stack can be referred to as an nFET device region material stack, while the second material stack may be referred to as a pFET device region material stack. The vertical dielectric material pillar 60 is self-aligned between the first material stack and the second material stack.

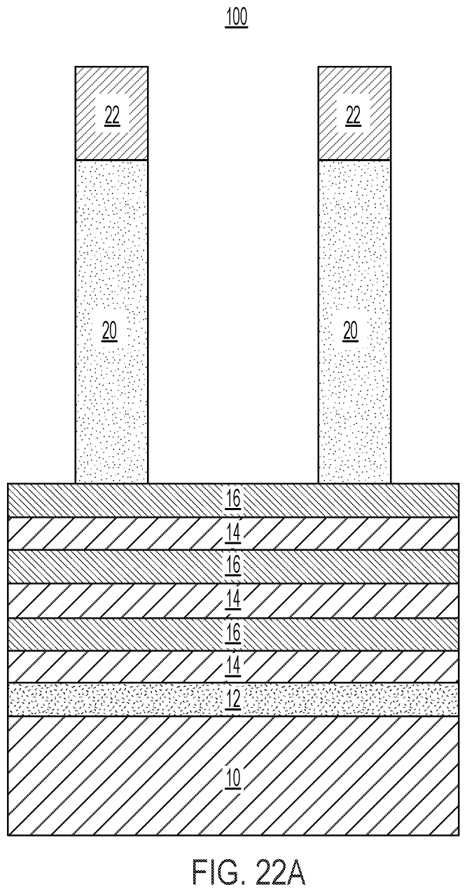

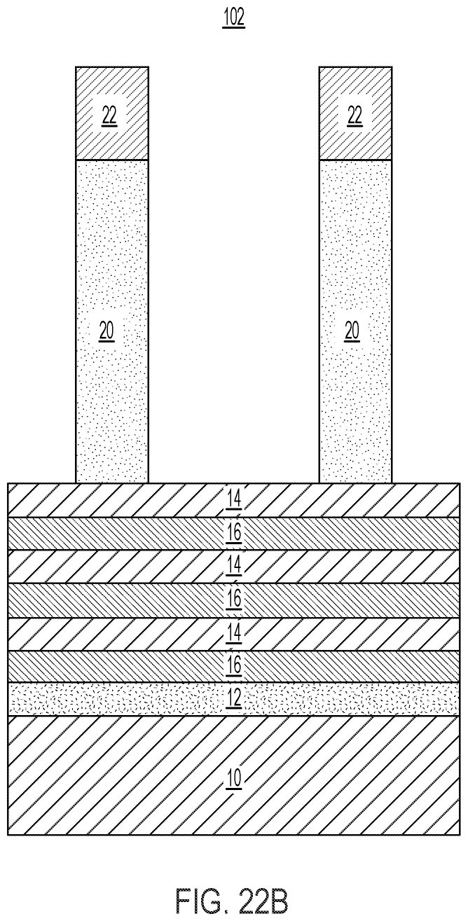

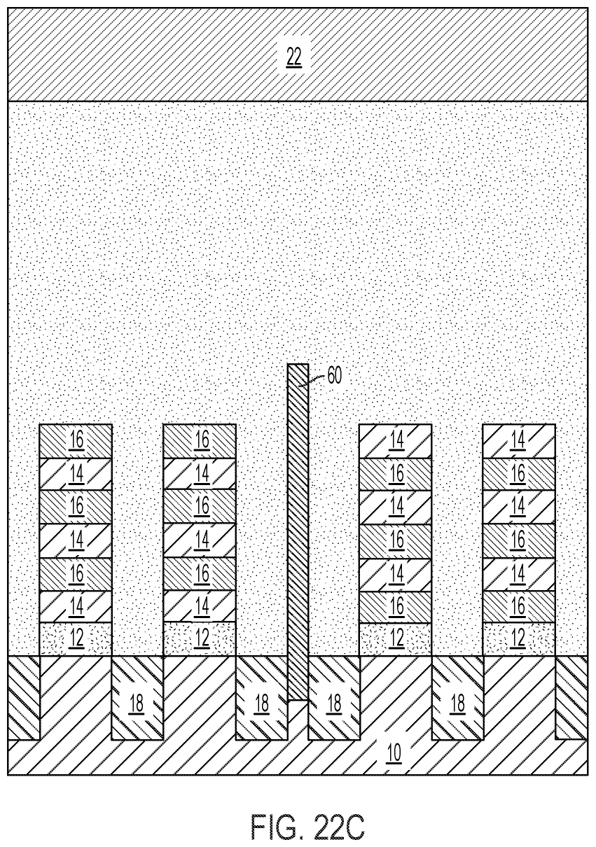

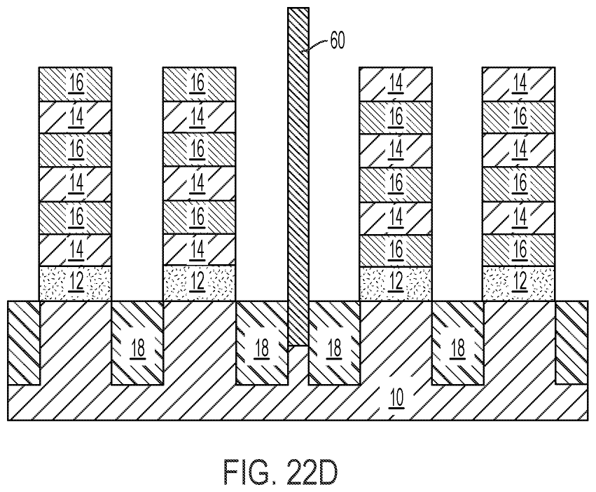

Referring now to FIGS. 22A, 22B, 22C and 22D, there are illustrated the exemplary structure shown in FIGS. 21A, 21B, 21C and 21D, respectively, after patterning the first and second material stacks, forming a shallow trench isolation structure 18, forming a plurality of sacrificial gate structures 20 in the pFET device region and the nFET device region. These steps of this embodiment of the present application are the same as that described above in forming the exemplary structure shown in FIGS. 2A-2D. Each patterned material stack has a fin pattern and the materials for the shallow trench isolation structure 18 and sacrificial gate structures 20 have also been described above. As illustrated, the vertical dielectric pillar has a bottommost portion that extends beneath a topmost surface of the semiconductor substrate 10 and is flanked on both sides by the shallow trench isolation structure 18.

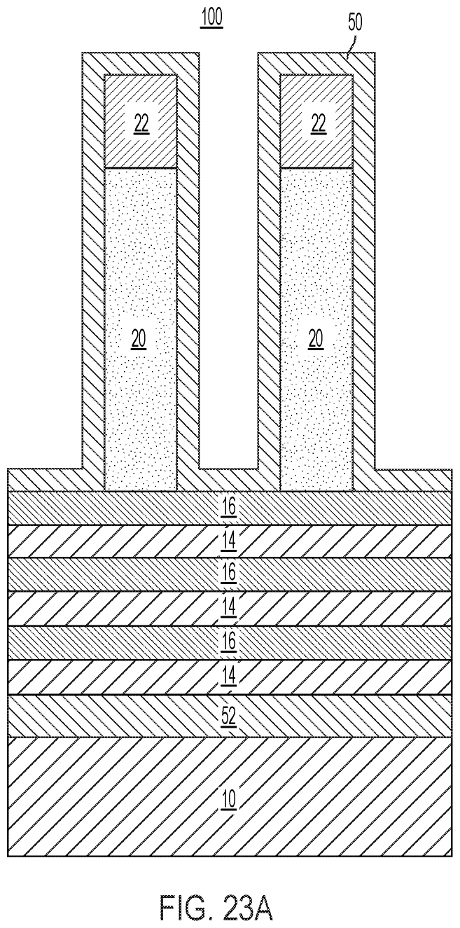

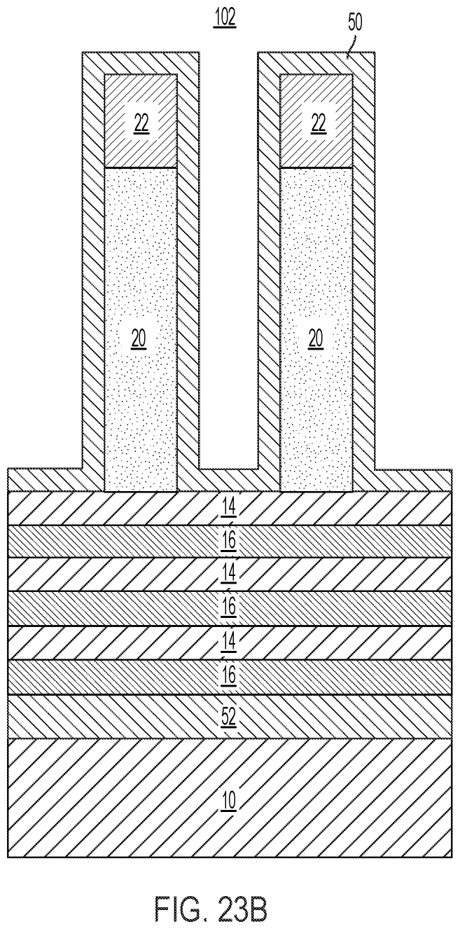

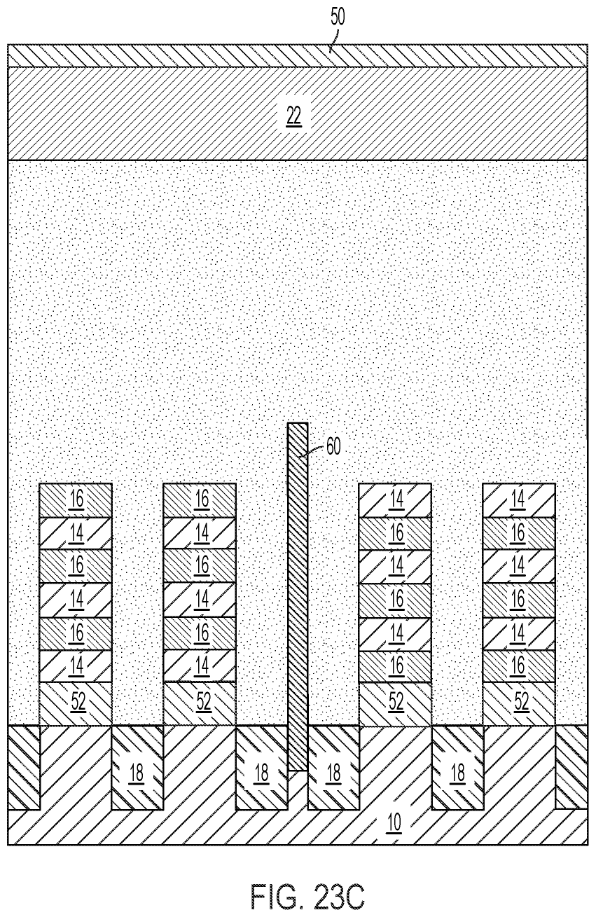

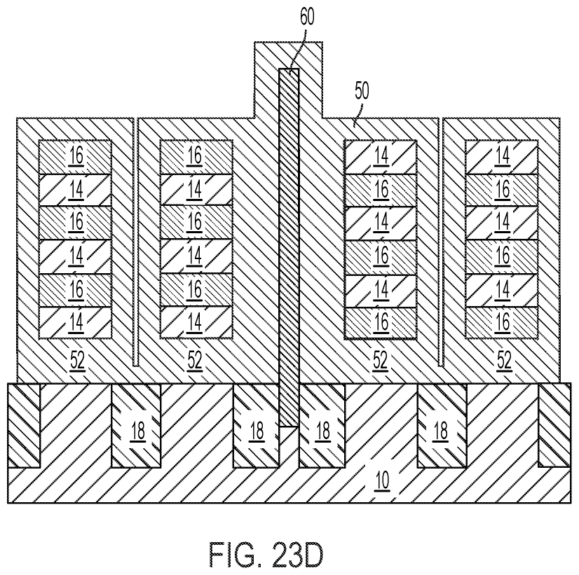

Referring now to FIGS. 23A, 23B, 23C and 23D, there are illustrated the exemplary structure shown in FIGS. 22A, 22B, 22C and 22D, respectively, after forming a gate dielectric spacer layer 50 and a bottom dielectric isolation structure 52. In this embodiment of the present application, the gate dielectric spacer layer 50 and a bottom dielectric isolation structure 52 are composed of a same dielectric material, and are formed at the same time by first removing the placeholder material layer 12 in both device regions forming a gap beneath each respective patterned material stack, and thereafter a dielectric material is deposited providing gate dielectric spacer layer 50 and bottom dielectric isolation structure 52. The dielectric material used in this embodiment is the same as that mentioned above for forming gate dielectric spacer 50 in a previous embodiment of the present application. Note that in FIGS. 23A-23D, the gate dielectric spacer layer 50 is present along the sidewalls and topmost surface of each of the first patterned material stack, the second patterned material stack and the vertical dielectric material pillar 60, while the bottom dielectric isolation structure 52 is located beneath the first and second patterned material stacks.

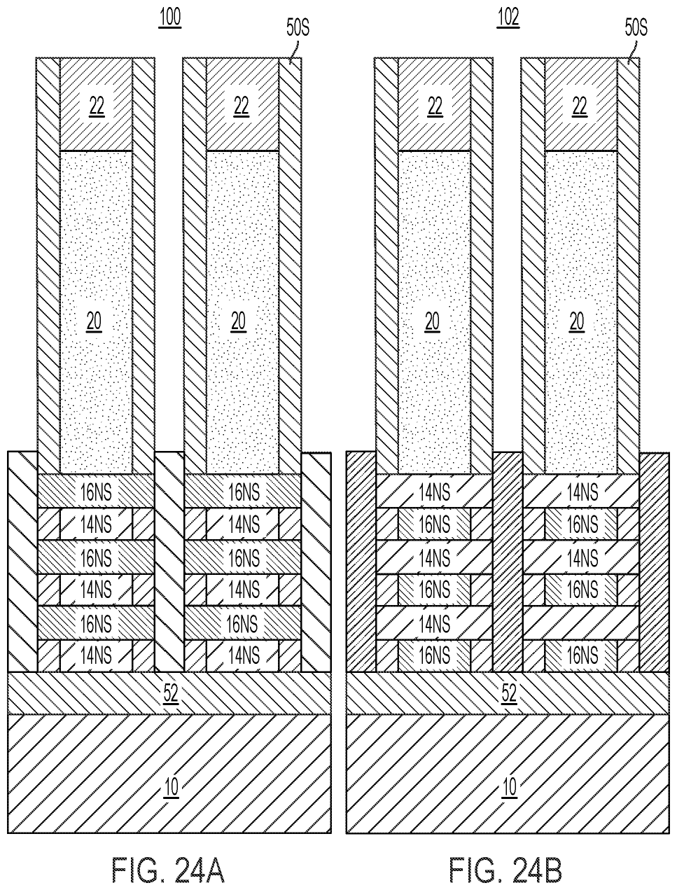

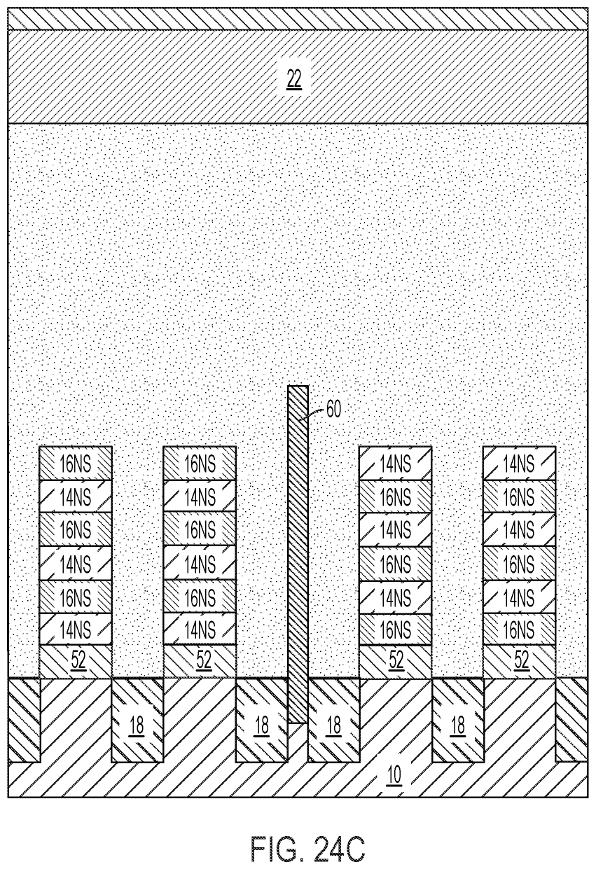

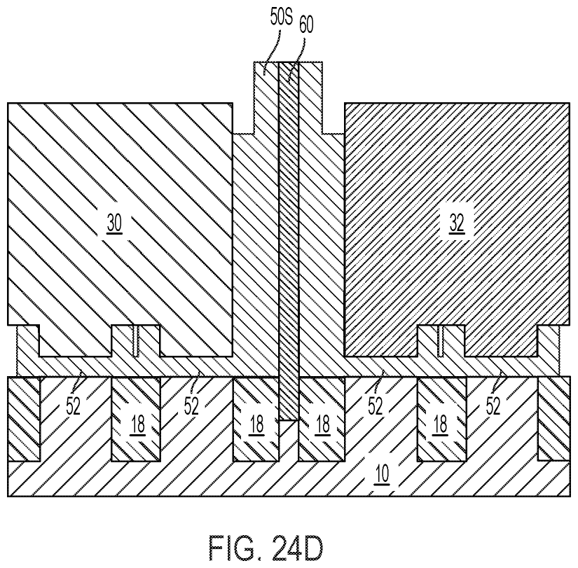

Referring now to FIGS. 24A, 24B, 24C and 24D, there are illustrated the exemplary structure shown in FIGS. 23A, 23B, 23C and 23D, respectively, after performing nanosheet stack formation processing steps in each of the pFET device region and the nFET device region. Notably, the nanosheet stack formation processing is performed separately in each of the device regions, and includes etching the gate dielectric spacer layer 50 to provide gate dielectric spacers 50S, utilizing the gate dielectric spacers 50S and the sacrificial gate structures as a combined etch mask to convert the respective patterned material stack into a nanosheet-containing stack, inner spacer 28 formation, and source/drain (e.g., first source/drain region 30 and second source/drain region 32, as mentioned above) formation. All these steps and the materials used in forming the inner spacer and source/drain regions have been previously described herein above. In this embodiment, gate dielectric spacers 50S can be present between each of the first and second source/drain regions 30, 32 and the vertical dielectric pillar 60. In other embodiments, each of the first and second source/drain regions 30, 32 is in direct physical contact with a sidewall of the vertical dielectric pillar 60.

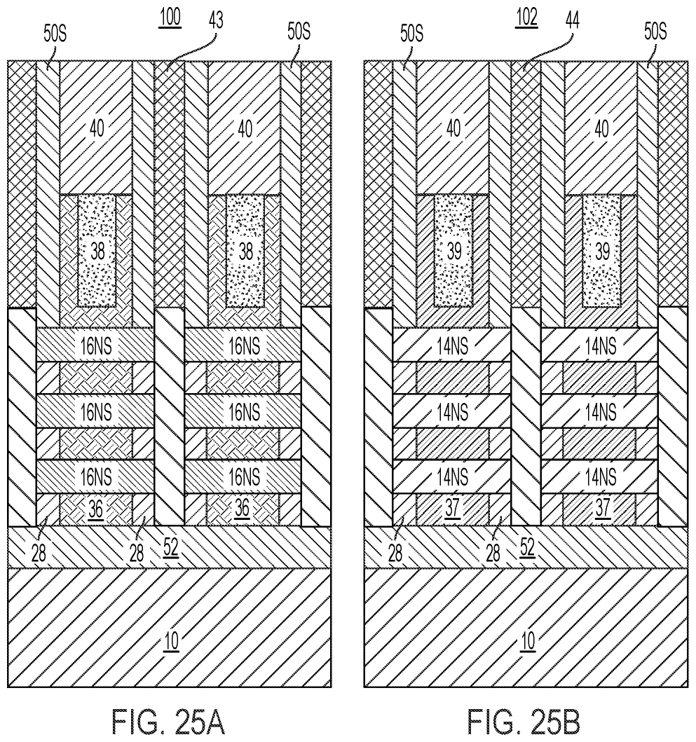

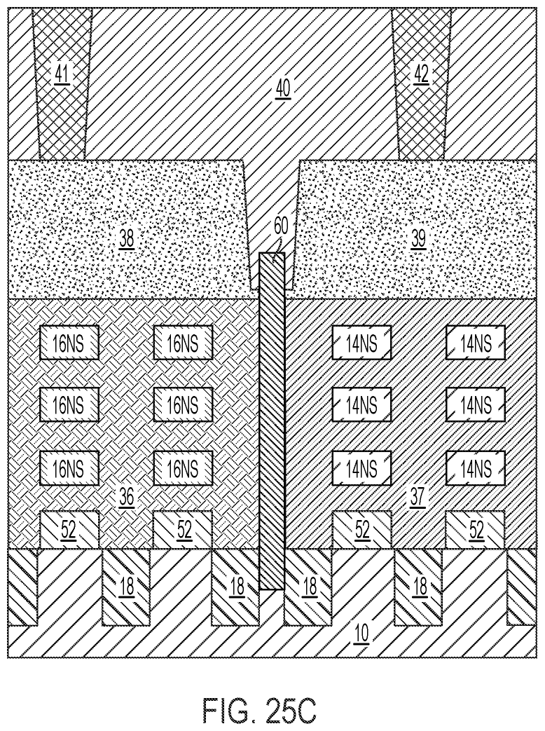

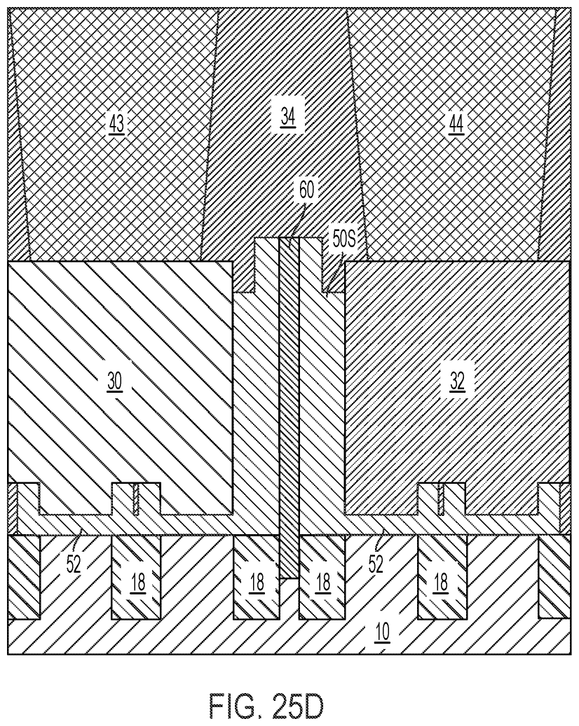

Referring now to FIGS. 25A, 25B, 25C and 25D, there are illustrated the exemplary structure shown in FIGS. 24A, 24B, 24C and 24D, respectively, after suspending appropriate semiconductor channel material nanosheets in each of the pFET device region and the nFET device region, forming functional gate structures, GS1 and GS2 in each of the device regions, and forming various contact structures 41, 42, 43 and 44. The processing steps and materials/components used in this embodiment of the present application have been previously described in the present application. The illustrated embodiment includes a gate cut region (not specifically labeled). In embodiments, the vertical dielectric pillar 60 has a vertical height that is located between a topmost surface of both the first functional gate structure GS1 and the second functional gate structure GS2 and a topmost surface of a topmost pFET semiconductor channel material nanosheet 16NS of the plurality of pFET semiconductor channel material nanosheets and a topmost nFET semiconductor channel material nanosheet 14NS of the plurality of nFET semiconductor channel material nanosheets. In the illustrated embodiment, a gate cut region located on top of the vertical dielectric pillar 60 such that the first functional gate structure GS1 is entirely spaced apart from the second functional gate structure GS2.

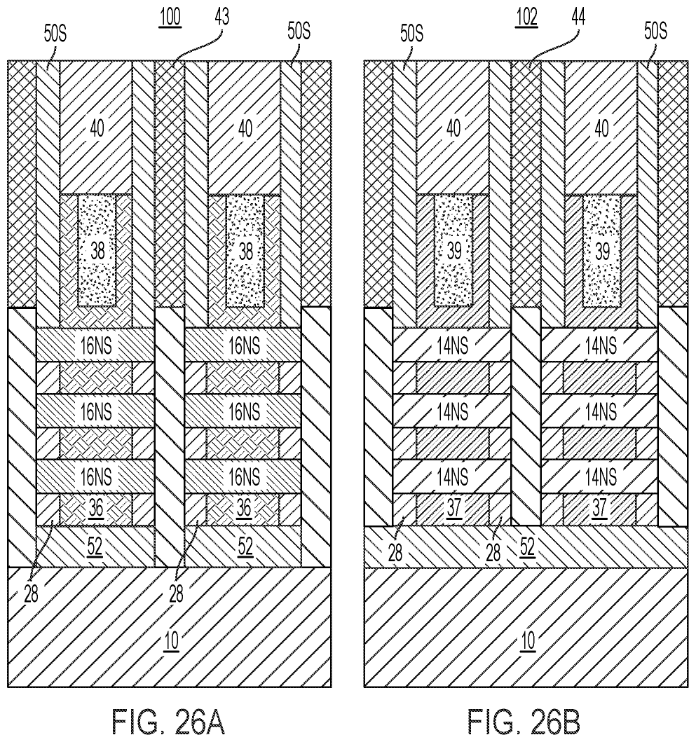

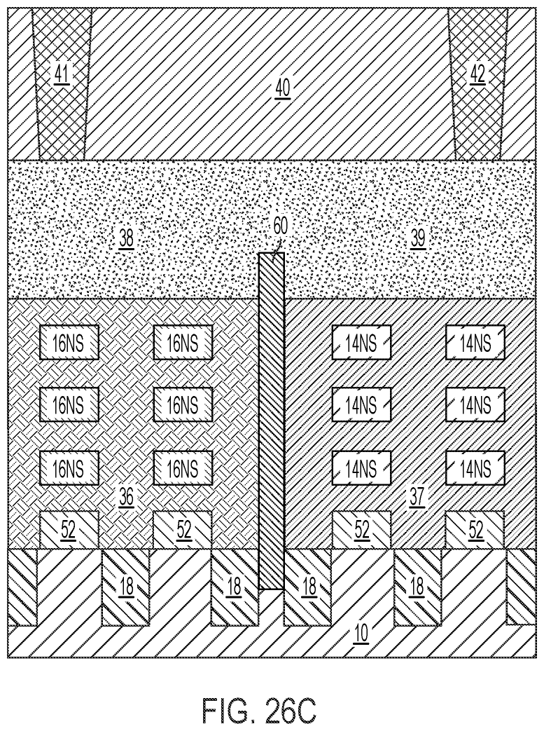

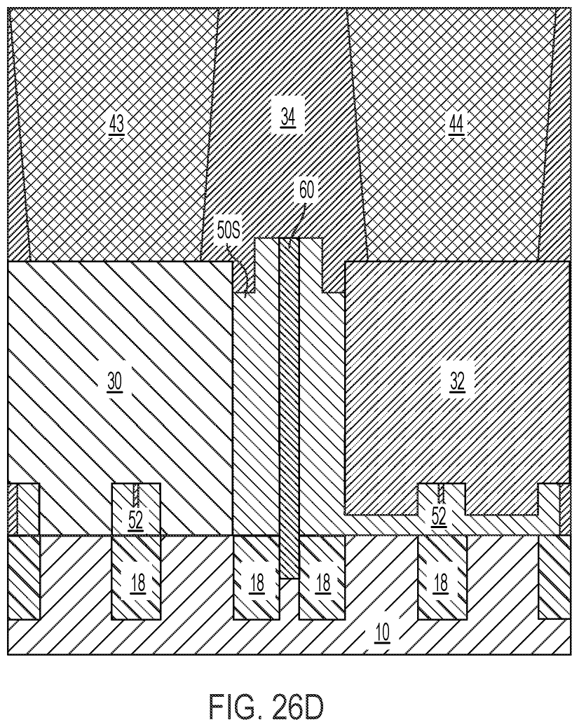

Referring now to FIGS. 26A, 26B, 26C and 26D, there are illustrated another structure that can be formed utilizing the structure shown in FIGS. 22A, 22B, 22C and 22D. The illustrated embodiment can be formed utilizing the same processing steps mentioned above in forming the exemplary structure shown in FIGS. 25A-25D except that a shared gate electrode is provided. In this embodiment, a portion of the shared gate electrode is located above the vertical dielectric material pillar 60. Also, and in this embodiment, the bottom dielectric isolation layer 52 is punched in the pFET device region 100 (by an etching step) to re-expose the semiconductor substrate 10. The re-exposed portion of the semiconductor substrate 10 can provide enhanced first (i.e., pFET) source/drain regions 30 and can favor strain engineering for the pFET.

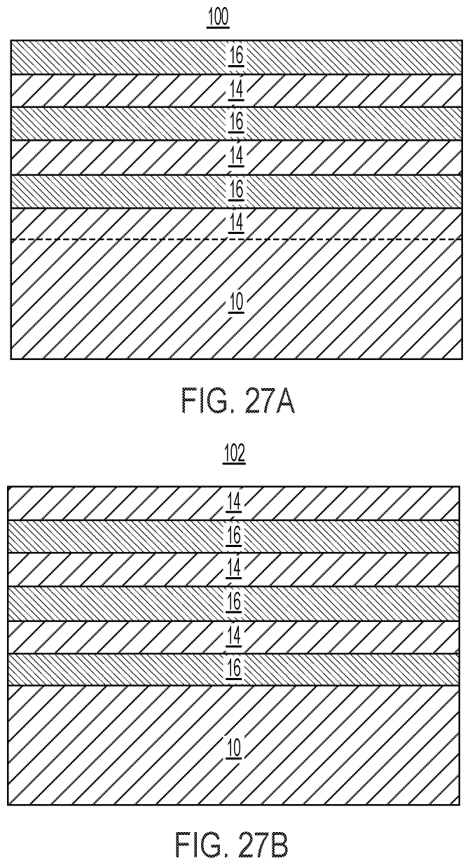

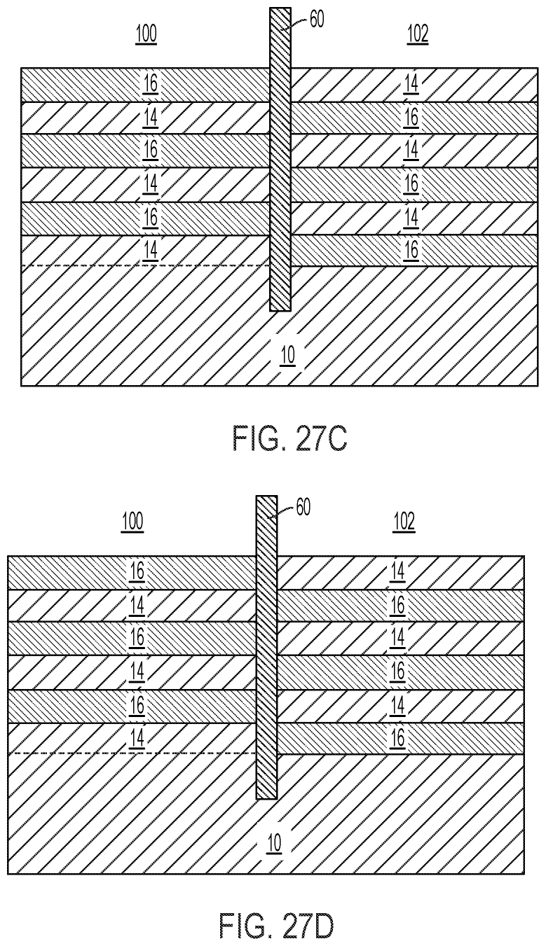

Referring now to FIGS. 27A, 27B, 27C and 27D, there are illustrated an exemplary structure that can be employed in the present application. The exemplary structure includes a semiconductor substrate having a pFET device region and an nFET device region, a first material stack of alternating nFET semiconductor channel material layers 14 and pFET semiconductor channel material layers 16 located in the pFET device region, and a second material stack of alternating pFET semiconductor channel material layers 14 and nFET semiconductor channel material layers 16 located in the nFET device region, wherein a vertical dielectric pillar 60 separates two material stacks from each other. In this embodiment, the first material stack may be referred to as pFET device material stack, and the second material stack can be referred to as an nFET device material stack. The structure shown in FIGS. 27A-27D can be formed utilizing the technique mentioned above in forming the structure shown in FIGS. 21A-21D. Note that in this embodiment however no placeholder material is used thus no bottom dielectric isolation structure will be subsequently formed.

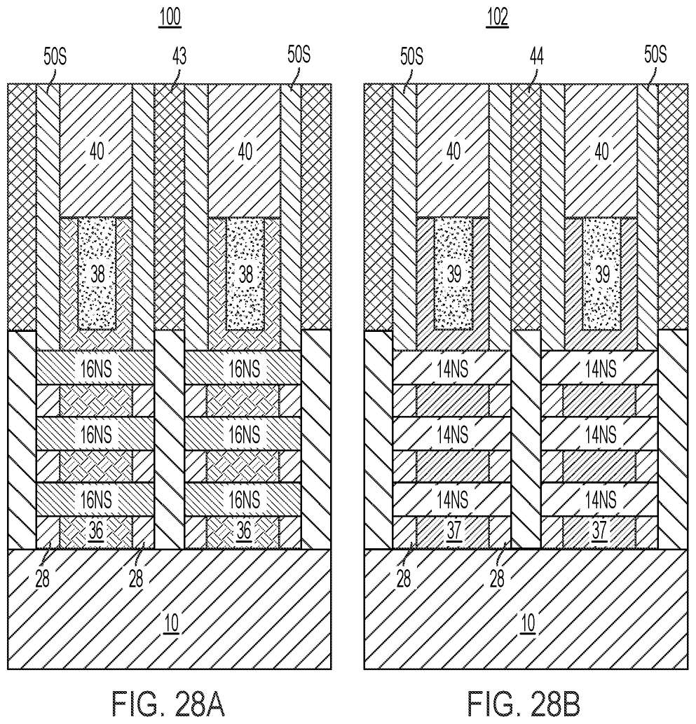

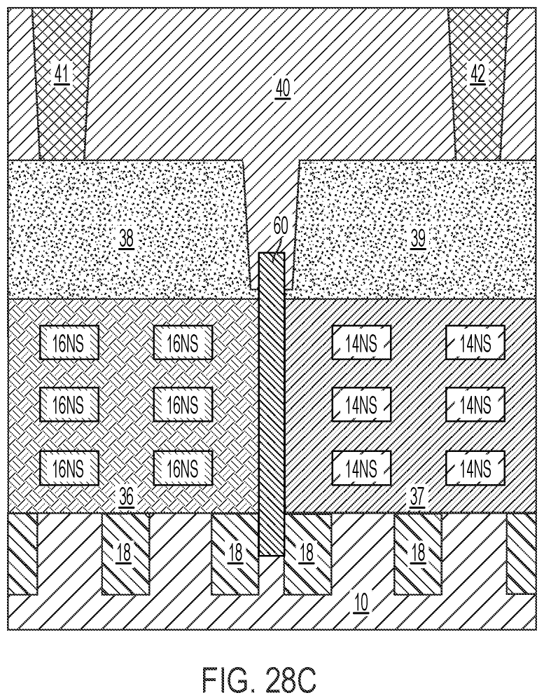

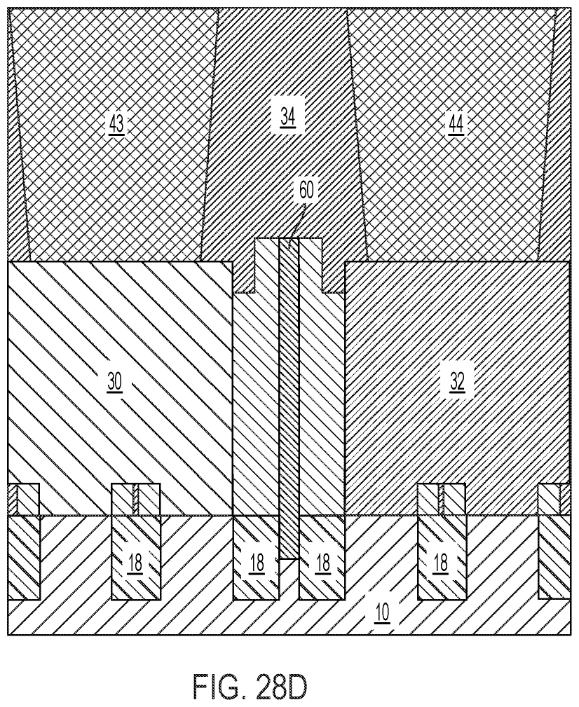

Referring now to FIGS. 28A, 28B, 28C and 28D, there are illustrated the exemplary structure shown in FIGS. 27A, 27B, 27C and 27D, respectively, after performing nanosheet device processing steps as can be derived from the present application. The nanosheet device processing includes gate dielectric spacer 50S formation, nanosheet-containing stack formation, inner spacer 28 formation, source/drain region formation, sacrificial gate structure 22 removal, suspending the appropriate semiconductor channel material nanosheet, and functional gate structure, GS1 and GS21, formation. Although a gate cut region is shown, this embodiment contemplates forming a shared gate electrode. In this embodiment, each of the first functional gate structure GS1 and the second functional gate structure GS2 is in direct physical contact with the semiconductor substrate 10.

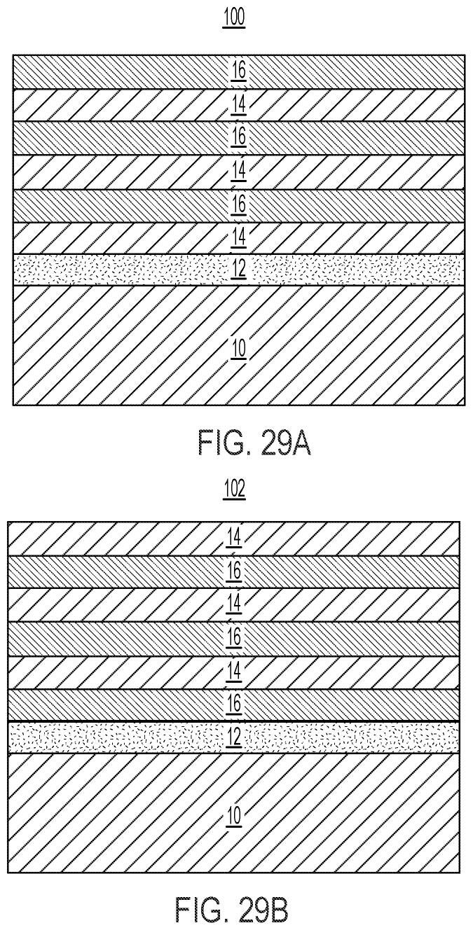

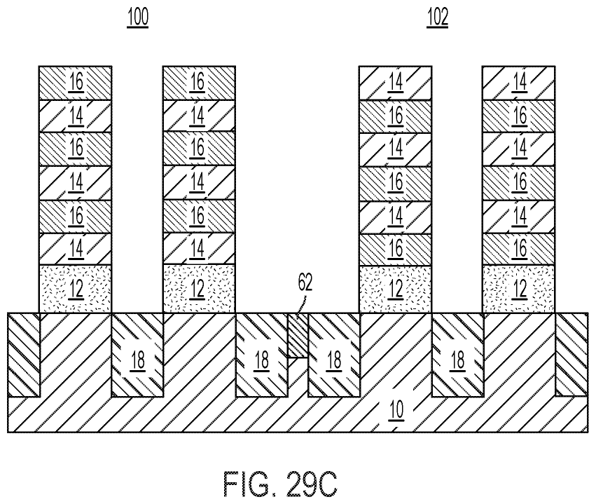

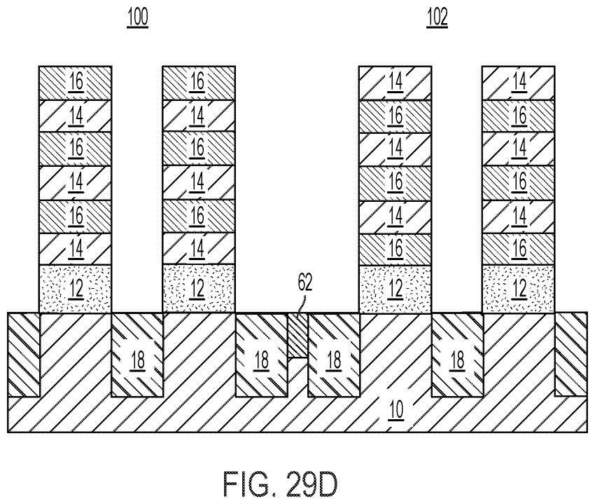

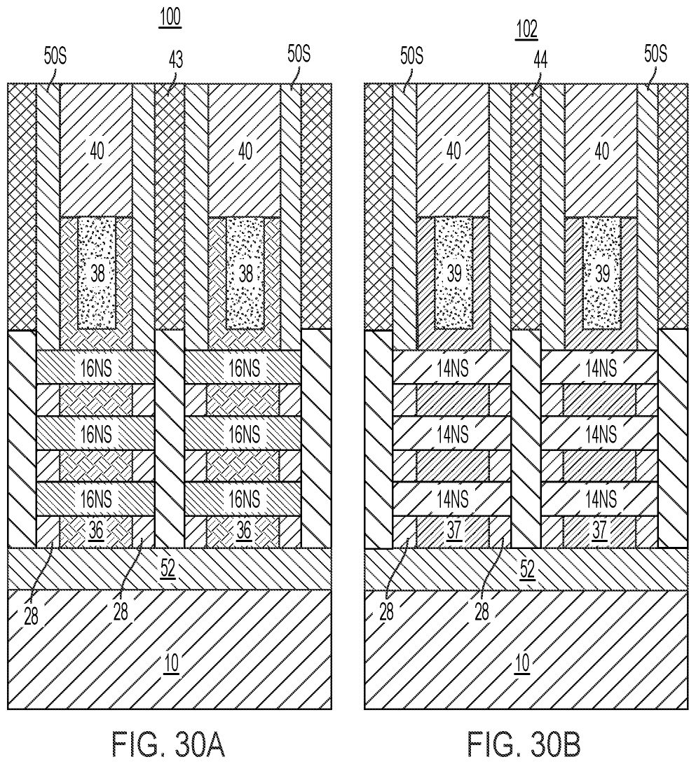

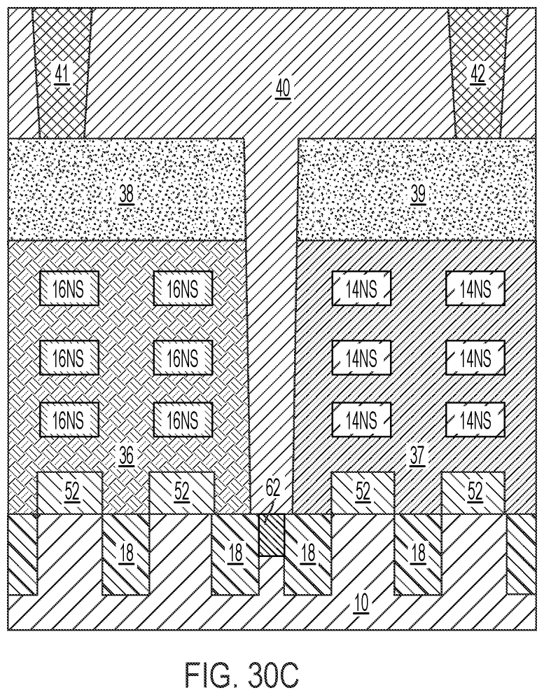

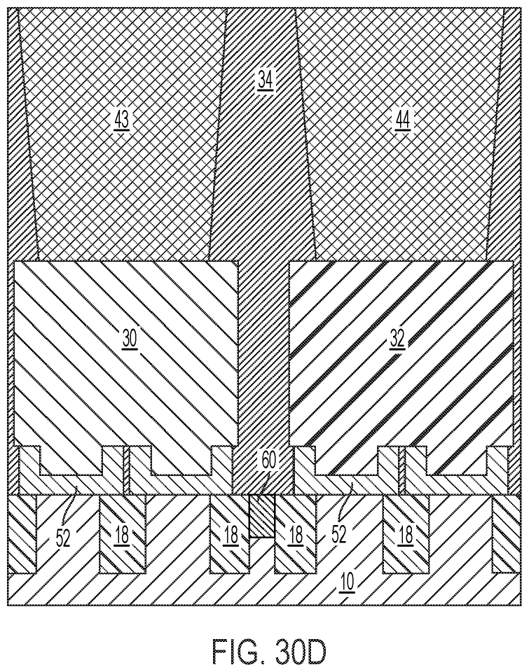

Referring now to FIGS. 29A, 29B, 29C and 29D, there are illustrated an exemplary structure that can be employed in the present application. The exemplary structure includes a semiconductor substrate 10 having a pFET device region and an nFET device region, a placeholder material layer 12 on the semiconductor substrate 10, a first patterned material stack (i.e., pFET device patterned material stack) of alternating nFET semiconductor channel material layers 14 and pFET semiconductor channel materials 16 in the pFET device region, and a second patterned material stack (i.e., an nFET device patterned material stack) of alternating pFET semiconductor channel material layers 16 and nFET semiconductor channel material layers 14 in the nFET device region, wherein a vertical dielectric pillar 60 separates two device regions from each other. The structure shown in FIGS. 29A-29D can be formed utilizing the technique mentioned above in forming the structure shown in FIGS. 2A-22D minus sacrificial gate structure 20 formation (the sacrificial gate structure will be formed later in this embodiment and then removed to provide the structure shown in FIGS. 30A-30D. Note that in this embodiment the vertical dielectric pillar 60 is subjected to a recessed etch such that vertical dielectric pillar 60 is a continuous pillar that has a topmost surface that is coplanar with a topmost surface of the semiconductor substrate 10 and with a topmost surface of the shallow trench isolation structure 18. In this embodiment, the shallow trench isolation structure 16 is laterally adjacent to the vertical dielectric pillar 60. Stated in other terms, the vertical dielectric pillar is flanked on both sides by the shallow trench isolation structure 18.

Referring now to FIGS. 30A, 30B, 30C and 30D, there are illustrated the exemplary structure shown in FIGS. 29A, 29B, 29C and 29D, respectively, after performing nanosheet device processing steps as can be derived from the present application. Although FIGS. 30A-30D illustrate a gate cut region the gate cut region not need be formed allowing for a shared gate electrode between GS1 and GS2.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising;
a semiconductor substrate having a pFET device region and an nFET device region;
a pFET located in the pFET device region, wherein the pFET comprises a first functional gate structure wrapped around a plurality of pFET semiconductor channel material nanosheets;
an nFET located in the nFET device region, wherein the nFET comprises a second functional gate structure wrapped around a plurality of nFET semiconductor channel material nanosheets, wherein each pFET semiconductor channel material nanosheet of the plurality of pFET semiconductor channel material nanosheets is vertically offset from each nFET semiconductor channel material nanosheet of the plurality of pFET semiconductor channel material nanosheets; and
a bottom dielectric isolation structure located in both the pFET device region and the nFET device region, wherein the bottom dielectric isolation structure is located between the first functional gate structure and the semiconductor substrate and between the second functional gate structure and the semiconductor substrate, and wherein the second functional gate structure has a bottommost surface that extends beneath a topmost surface of the bottom dielectric isolation structure.

2. The semiconductor structure of claim 1, wherein the bottom dielectric isolation structure is a bottom dielectric isolation bilayer structure comprising a first dielectric material layer composed of a first dielectric material, and a second dielectric material layer composed of a second dielectric material that is compositionally different from the first dielectric material.

3. The semiconductor structure of claim 1, wherein the bottom dielectric isolation structure is a single layered structure.

4. The semiconductor structure of claim 1, wherein each pFET semiconductor channel material nanosheet of the plurality of pFET semiconductor channel material nanosheets is dumbbell shaped.

5. The semiconductor structure of claim 1, wherein each nFET semiconductor channel material nanosheet of the plurality of nFET semiconductor channel material nanosheets is dumbbell shaped.

6. The semiconductor structure of claim 1, wherein the first functional gate structure comprises a first gate dielectric material, a p-type work function metal, and a first gate electrode, and the second functional gate structure comprises a second gate dielectric material, an n-type work function metal, and a second gate electrode.

7. The semiconductor structure of claim 1, wherein the pFET further comprises a first source/drain region extending outward from each pFET semiconductor channel material nanosheet of the plurality of pFET semiconductor channel material nanosheets and present on both sides of the first functional gate structure, and wherein the nFET further comprises a second source/drain region extending outward from each nFET semiconductor channel material nanosheet of the plurality of nFET semiconductor channel material nanosheets and present on both sides of the second functional gate structure, and wherein the first source/drain region and the second source/drain region are both isolated from the semiconductor substrate by the bottom dielectric isolation structure.

8. The semiconductor structure of claim 1, wherein the bottom dielectric isolation structure in a gate region of both the nFET has a first thickness, and the bottom dielectric isolation structure in a source/drain region of the nFET has a second thickness that differs from the first thickness.

9. The semiconductor structure of claim 1, wherein the first functional gate structure and the second functional gate structure are independent gate structures that are spaced apart by a gate cut region.

10. The semiconductor structure of claim 1, wherein the first functional gate structure and the second functional gate structure comprise a shared gate electrode.

11. A semiconductor structure comprising:
a semiconductor substrate having a pFET device region and an nFET device region;
a pFET located in the pFET device region, wherein the pFET comprises a first functional gate structure wrapped around a plurality of pFET semiconductor channel material nanosheets;
an nFET located in the nFET device region, wherein the nFET comprises a second functional gate structure wrapped around a plurality of nFET semiconductor channel material nanosheets, wherein each pFET semiconductor channel material nanosheet of the plurality of pFET semiconductor channel material nanosheets is substantially aligned in a horizontal direction to each nFET semiconductor channel material nanosheet of the plurality of nFET semiconductor channel material nanosheets; and
a vertical dielectric pillar located between the nFET device region and the nFET device region, wherein the vertical dielectric pillar is a continuous pillar that separates the first functional gate structure from the second functional gate structure and separates first source/drain regions of the pFET from second source/drain regions of the nFET.

12. The semiconductor structure of claim 11, wherein the vertical dielectric pillar has a bottommost portion that extends beneath a topmost surface of the semiconductor substrate and is flanked on both sides by a shallow trench isolation structure.

13. The semiconductor structure of claim 11, wherein the vertical dielectric pillar has a vertical height that is located between a topmost surface of both the first functional gate structure and the second functional gate structure and a topmost surface of a topmost pFET semiconductor channel material nanosheet of the plurality of pFET semiconductor channel material nanosheets and a topmost nFET semiconductor channel material nanosheet of the plurality of nFET semiconductor channel material nanosheets.

14. The semiconductor structure of claim 13, wherein the first functional gate structure and the second functional gate structure comprise a shared gate electrode and wherein a portion of the shared gate electrode is located on top of the vertical dielectric pillar.

15. The semiconductor structure of claim 13, further comprising a gate cut region located on top of the vertical dielectric pillar such that the first functional gate structure is entirely spaced apart from the second functional gate structure.

16. The semiconductor structure of claim 11, further comprising a bottom dielectric isolation structure located on the semiconductor substrate and present beneath a gate region and a source/drain region of both the pFET and the nFET.

17. The semiconductor structure of claim 11, further comprising a bottom dielectric isolation structure located on the semiconductor substrate and present beneath a gate region of both the pFET and the nFET, and a source/drain region of each of the pFET and the nFET is in direct physical contact with the semiconductor substrate.

18. The semiconductor structure of claim 11, wherein a bottommost surface of each of the first functional gate structure and the second functional gate structure is in direct physical contact with the semiconductor substrate and a source/drain region of both the nFET and the pFET is in direct physical contact with the semiconductor substrate.

19. A semiconductor structure comprising:
a semiconductor substrate having a pFET device region and an nFET device region;
a pFET located in the pFET device region, wherein the pFET comprises a first functional gate structure wrapped around a plurality of pFET semiconductor channel material nanosheets;
an nFET located in the nFET device region, wherein the nFET comprises a second functional gate structure wrapped around a plurality of nFET semiconductor channel material nanosheets, wherein each pFET semiconductor channel material nanosheet of the plurality of pFET semiconductor channel material nanosheets is substantially aligned in a horizontal direction to each nFET semiconductor channel material nanosheet of the plurality of nFET semiconductor channel material nanosheets;
a vertical dielectric pillar located between the nFET device region and the pFET device region; and
a shallow trench isolation structure present in the semiconductor substrate and located laterally adjacent to the vertical dielectric pillar, wherein the vertical dielectric pillar is a continuous pillar that has a topmost surface that is coplanar with a topmost surface of the semiconductor substrate and with a topmost surface of the shallow trench isolation structure.

20. The semiconductor structure of claim 19, wherein the vertical dielectric pillar is flanked on both sides by the shallow trench isolation structure.
